(19) United States
(12) Patent Application Publication
(10) Pub. No.: US 2023/0422615 A1
(43) Pub. Date: Dec. 28, 2023

(54) ORGANIC MOLECULES FOR OPTOELECTRONIC DEVICES

(71) Applicant: Samsung Display Co., Ltd., Yongin-si, Gyeonggi-do (KR)

(72) Inventor: Sebastian DÜCK, Heidelberg (DE)

(21) Appl. No.: 18/251,213

(22) PCT Filed: Nov. 3, 2021
(86) PCT No.: PCT/EP2021/080488

§ 371 Date: Apr. 28, 2023

(30) Foreign Application Priority Data
Nov. 4, 2020 (EP) 20205724.6

(51) Int. Cl. H10K 85/60; C07F 5/02; C09K 11/06

(52) U.S. Cl. CPC H10K 85/658; C07F 5/027; C09K 11/06; H10K 50/12

(57) ABSTRACT

The invention pertains to an organic molecule for use in optoelectronic devices. According to the invention, the organic molecule has:
a first chemical moiety with a structure of Formula I:

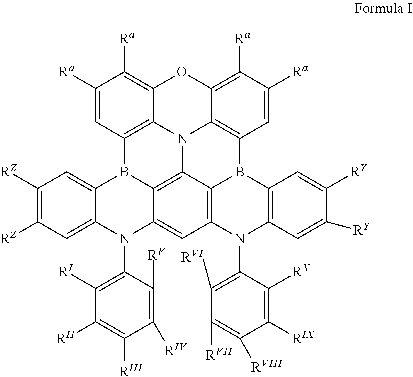

one or two second chemical moieties with a structure of Formula 11:

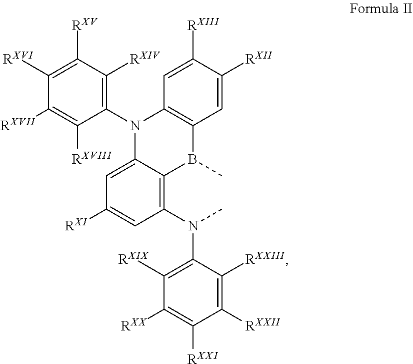

wherein
R^{Z} is the binding site of a single bond linking the first chemical moiety to the second moiety;
R^{Y} is the binding site of a single bond linking the first chemical moiety to the second moiety or R^{a}; and
the dashed lines “ [symbol] ” represent the binding sites of the first chemical moiety to the [symbol] second chemical moiety.

### CROSS-REFERENCE TO RELATED APPLICATIONS

This application is a U.S. National Phase patent application of International Patent Application Number PCT/EP2021/080488, filed on Nov. 3, 2021, which claims priority to European Patent Application Number 20205724.6, filed on Nov. 4, 2020, the entire content of each of which is incorporated herein by reference.

### BACKGROUND

The invention relates to light-emitting organic molecules and their use in organic light-emitting diodes (OLEDs) and in other optoelectronic devices.

### DESCRIPTION

The object of the present invention is to provide molecules which are suitable for use in optoelectronic devices.

This object is achieved by the invention which provides a new class of organic molecules.

Optoelectronic devices containing one or more light-emitting layers based on organics such as, e.g., organic light emitting diodes (OLEDs), light emitting electrochemical cells (LECs) and light-emitting transistors gain increasing importance. In particular, OLEDs are promising devices for electronic products such as screens, displays and illumination devices. In contrast to most electroluminescent devices essentially based on inorganics, organic optoelectronic devices based on organics are often rather flexible and producible in particularly thin layers. The OLED-based screens and displays already available today bear either good efficiencies and long lifetimes or good color purity and long lifetimes, but do not combine all three properties, i.e., good efficiency, long lifetime, and good color purity.

Thus, there is still an unmet technical need for optoelectronic devices which have a high quantum yield, a long lifetime, and good color purity.

The color purity or color point of an OLED is typically provided by CIEx and CIEy coordinates, whereas the color gamut for the next display generation is provided by so-called BT-2020 and DCPI3 values. Generally, in order to achieve these color coordinates, top emitting devices are needed to adjust the color coordinates by changing the cavity. In order to achieve high efficiency in top emitting devices while targeting this color gamut, a narrow emission spectrum in bottom emitting devices is required.

The organic molecules according to the invention exhibit emission maxima in the deep blue, sky blue, or green spectral range, preferably in the deep blue, and sky blue spectral range, and most preferably in the deep blue spectral range. The organic molecules exhibit in particular emission maxima between 420 nm and 520 nm, preferably between 440 nm and 495 nm, more preferably between 450 nm and 470 nm. The excited state lifetime is not more than 5 μs. Additionally, the molecules of the invention exhibit in particular a narrow—expressed by a small full width at half maximum (FWHM)—emission. The emission spectra of the organic molecules preferably show a full width at half maximum (FWHM) of less than or equal to 0.15 eV (≤0.15 eV), unless stated otherwise, measured with 1% by weight of emitter in poly(methyl methacrylate) PMMA at room temperature (i.e., approximately 25° C.). The excited state lifetime of the organic molecules according to the invention are, in particular, 5 μs or less.

The use of the molecules according to the invention in an optoelectronic device, for example, an organic light-emitting diode (OLED), leads to a narrow emission and high efficiency of the device. Corresponding OLEDs have a higher stability than OLEDs with known emitter materials and comparable color and/or by employing the molecules according to the invention in an OLED display, a more accurate reproduction of visible colors in nature, i.e., a higher resolution in the displayed image, is achieved. In particular, the molecules can be used in combination with an energy pump to achieve hyper-fluorescence or hyper-phosphorescence. In these cases, another species included in an organic electroluminescent device transfers energy to the organic molecules of the invention which then emit light.

The organic molecules according to the invention include or consist of:
a first chemical moiety including a structure of Formula I:

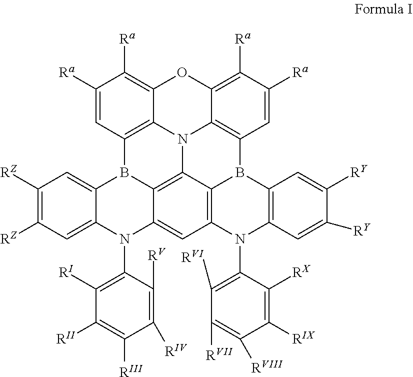

exactly one or exactly two second chemical moieties including a structure of Formula II:

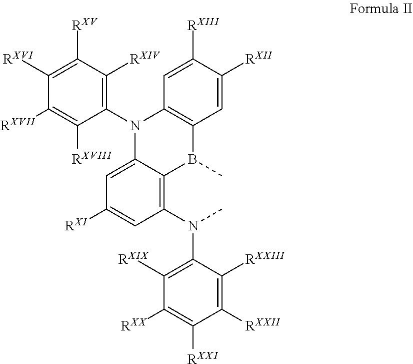

wherein R^{Z} is at each occurrence the binding site of a single bond linking the first chemical moiety to the second moiety;
R^{Y} is at each occurrence the binding site of a single bond linking the first chemical moiety to the second moiety or R^{a}.
the dashed lines “ [symbol] ” in Formula II represent the binding sites of the first chemical moiety to the second chemical moiety (at both R^{Z} and/or at both R^{Y}). In an embodiment of the organic molecule with only one second chemical moiety, it is bound at the positions R^{Z} and R^{Y} is R^{a}.

R^{a} is at each occurrence independently selected from the group consisting of:
hydrogen;
deuterium;
N(R⁵)₂;
OR⁵;
SR⁵;
CF₃;
CN;
halogen (F, Cl, Br, I);
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁴ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₃-C₅₇-heteroaryl,
which is optionally substituted with one or more substituents R⁵;
R⁵ is at each occurrence independently selected from the group consisting of:
hydrogen; deuterium; halogen;
C₁-C₁₂-alkyl,
wherein optionally one or more hydrogen atoms are independently substituted by R⁶;
C₆-C₁₈-aryl,
wherein optionally one or more hydrogen atoms are independently substituted by R⁶; and
C₃-C₁₅-heteroaryl,
wherein optionally one or more hydrogen atoms are independently substituted by R⁶;
R⁶ is at each occurrence independently selected from the group consisting of:
hydrogen; deuterium; halogen;
C₁-C₁₂-alkyl;
C₆-C₁₈-aryl,
wherein optionally one or more hydrogen atoms are independently substituted by C₁-C₁₈-alkyl substituents; and
C₃-C₁₅-heteroaryl,
wherein optionally one or more hydrogen atoms are independently substituted by C₁-C₅-alkyl substituents;
R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen;
deuterium;
N(R⁴)₂;
OR⁴,
SR⁴;
Si(R⁴)₃;
B(OR⁴)₂;
OSO₂R⁴;
CF₃;
CN;
halogen;
C₁-C₄₀-alkyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-alkoxy,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR₄;
C₂-C₄₀-thioalkoxy,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkenyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR₄;
C₂-C₄₀-alkynyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₆-C₆₀-aryl,
which is optionally substituted with one or more substituents R⁴; and
C₃-C₅₇-heteroaryl,
which is optionally substituted with one or more substituents R⁴;
R⁴ is at each occurrence independently from each other selected from the group consisting of:
hydrogen; deuterium; halogen; OPh (Ph=phenyl); SPh; CF₃; CN; Si(C₁-C₅-alkyl)₃; Si(Ph)₃;
C₁-C₅-alkyl,
wherein optionally one or more hydrogen atoms are independently substituted by deuterium, halogen, CN, or CF₃;
C₁-C₅-alkoxy,
wherein optionally one or more hydrogen atoms are independently substituted by deuterium, halogen, CN, or CF₃;
C₁-C₅-thioalkoxy,
wherein optionally one or more hydrogen atoms are independently substituted by deuterium, halogen, CN, or CF₃;
C₂-C₅-alkenyl,
wherein optionally one or more hydrogen atoms are independently substituted by deuterium, halogen, CN, or CF₃;
C₂-C₅-alkynyl,
wherein optionally one or more hydrogen atoms are independently substituted by deuterium, halogen, CN, or CF₃;
C₆-C₁₈-aryl,
which is optionally substituted with one or more substituents R⁵;
C₃-C₁₇-heteroaryl,
which is optionally substituted with one or more substituents R⁵;
N(C₆-C₁₈-aryl)₂;
   N(C₃-C₁₇-heteroaryl)₂; and

N(C₃-C₁₇-heteroaryl)(C₆-C₁₈-aryl),
wherein substituents R^{a} positioned adjacent to each other are optionally bonded to each other and form an aryl ring, which is optionally substituted with one or more C₁-C₅-alkyl substituents, deuterium, halogen, CN or CF₃.

In one embodiment of the invention, the organic molecules according to the invention include or consist of:
a first chemical moiety including a structure of Formula I and
two second chemical moieties including a structure of Formula II.

In one embodiment of the invention, R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In one embodiment of the invention R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph.

In one embodiment of the invention, R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, CN, CF₃, F, and
Ph, which is optionally substituted with one or more substituents independently from each other selected from the group consisting of Me, ⁱPr, ^{t}Bu, CN, CF₃, F and Ph.

In one embodiment of the invention, R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, F, and
Ph, which is optionally substituted with one or more substituents independently from each other selected from the group consisting of Me, ⁱPr, ^{t}Bu, CN, CF₃, F and Ph.

In one embodiment of the invention, R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, F, and
Ph, which is optionally substituted with one or more substituents independently from each other selected from the group consisting of Me, ⁱPr, ^{t}Bu, and Ph.

In one embodiment of the invention, R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, and
Ph, which is optionally substituted with one or more substituents independently from each other selected from the group consisting of Me, ⁱPr, ^{t}Bu, and Ph.

In a preferred embodiment of the invention, R^{XIII} and R^{XII} are hydrogen.

In a preferred embodiment of the invention, R^{XV} and R^{XIX} are hydrogen.

In a preferred embodiment of the invention, R^{I} and R^{X} are hydrogen.

In a certain embodiment of the invention, R^{I}, R^{V}, R^{XV} and R^{XIX} are hydrogen.

In a certain embodiment of the invention, R^{I}, R^{V}, R^{VI} and R^{X} are hydrogen.

In a certain embodiment of the invention, R^{I}, R^{V}, R^{VI}, R^{X}, R^{XV} and R^{XIX} are hydrogen.

In one embodiment of the invention, R^{XI} is independently selected from the group consisting of:
hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a preferred embodiment of the invention, R^{XI} is independently selected from the group consisting of:
hydrogen, Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.
In a more preferred embodiment of the invention, R^{XI} is independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In one embodiment of the invention, R^{XI} is independently selected from the group consisting of:
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a certain embodiment of the invention, R^{XI} is N(Ph)₂, which is optionally substituted with one or more substituents independently from each other selected from the group consisting of Me, ⁱPr, ^{t}Bu, and Ph.

In one embodiment of the invention, R^{XI} is N(Ph)₂.

In one embodiment of the invention, R^{Y} is the binding site of a single bond linking the first chemical moiety to the second moiety.

In one embodiment of the invention, R^{a} is at each occurrence independently selected from the group consisting of:
hydrogen,
Me, ⁱPr, ^{t}Bu, CN, CF₃, F,
aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a further embodiment of the invention, R^{a} is at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a further embodiment of the invention, R^{a} is at each occurrence independently selected from the group consisting of:
hydrogen,
Me, ⁱPr, ^{t}Bu, F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
   and
N(Ph)₂, which is optionally substituted with one or more substituents independently from each other selected from the group consisting of Me, ⁱPr, ^{t}Bu, F and Ph.

In a further embodiment of the invention, R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a further embodiment of the invention, R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a further embodiment of the invention, R^{a} is at each occurrence independently selected from the group consisting of:
hydrogen,
Me, ⁱPr, ^{t}Bu,
   and
Ph, which is optionally substituted with one or more substituents independently from each other selected from the group consisting of Me, ⁱPr, ^{t}Bu, and Ph.

In one embodiment of the invention, R^{a} is at each occurrence independently selected from the group consisting of:
hydrogen and Ph.

In one embodiment of the invention, R^{a} is at each occurrence hydrogen.

In a preferred embodiment of the invention, R^{V}=R^{X} and R^{I}=R^{VI}.

In one embodiment of the invention, R⁵ is at each occurrence independently selected from the group consisting of:
hydrogen,
Me, ⁱPr, ^{t}Bu,
   and
Ph, which is optionally substituted with one or more substituents independently from each other selected from the group consisting of Me, ⁱPr, ^{t}Bu, and Ph.

In one embodiment of the invention, R⁵ is at each occurrence independently selected from the group consisting of:
hydrogen and Ph.

In one embodiment of the invention, R⁵ is at each occurrence hydrogen.

In one embodiment of the invention, the organic molecules include or consist of a structure of Formula II-a, and Formula II-b:

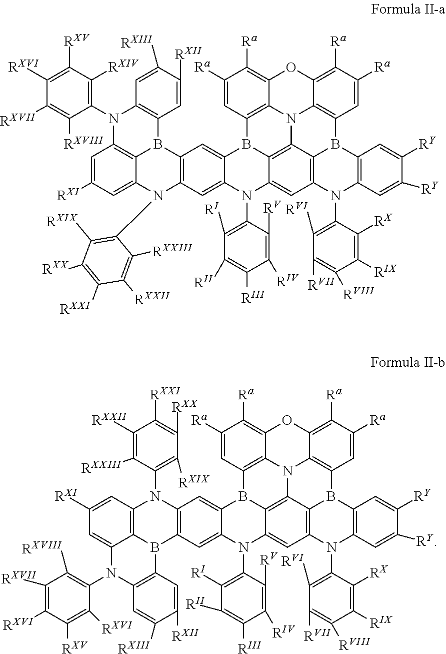

In one embodiment of the invention, the organic molecules include or consist of a structure according to any of Formulas II-a, II-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph, and
N(Ph)₂, which is optionally substituted with one or more substituents independently from each other selected from the group consisting of Me, ⁱPr, ^{t}Bu, F and Ph.

In one embodiment of the invention, the organic molecules include or consist of a structure according to any of Formulas II-a, II-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph, and
triazinyl, which is optionally substituted with one or more substituents independently from each other selected from the group consisting of Me, ⁱPr, ^{t}Bu, CN, CF₃, F and Ph.

In one embodiment of the invention, the organic molecules include or consist of a structure according to any of Formulas II-a, II-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu CN, CF₃, F, and
Ph, which is optionally substituted with one or more substituents independently from each other selected from the group consisting of Me, ⁱPr, ^{t}Bu, CN, CF₃, F and Ph.

In one embodiment of the invention, the organic molecules include or consist of a structure according to any of Formulas II-a, II-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, F, and
Ph, which is optionally substituted with one or more substituents independently from each other selected from the group consisting of Me, ⁱPr, ^{t}Bu, CN, CF₃, F and Ph.

In one embodiment of the invention, the organic molecules include or consist of a structure according to any of Formulas II-a, II-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, F, and
Ph, which is optionally substituted with one or more substituents independently from each other selected from the group consisting of Me, ⁱPr, ^{t}Bu, and Ph.

In one embodiment of the invention, the organic molecules include or consist of a structure according to any of Formulas II-a, II-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen, Me, ⁱPr, ^{t}Bu, and
Ph, which is optionally substituted with one or more substituents independently from each other selected from the group consisting of Me, ⁱPr, ^{t}Bu, and Ph.

In a preferred embodiment of the invention, the organic molecules include or consist of a structure according to any of Formulas II-a, II-b, wherein R^{I} and R^{X} are hydrogen.

In a certain embodiment of the invention, the organic molecules include or consist of a structure according to any of Formulas II-a, II-b, wherein R^{I}, R^{V}, R^{VI} and R^{X} are hydrogen.

In a preferred embodiment of the invention, the organic molecules include or consist of a structure according to any of Formulas II-a, II-b, wherein R^{XIII} and R^{XII} are hydrogen.

In a preferred embodiment of the invention, the organic molecules include or consist of a structure according to any of Formulas II-a, II-b, wherein R^{XV} and R^{XIX} are hydrogen.

In a preferred embodiment of the invention, the organic molecules include or consist of a structure according to any of Formulas II-a, II-b, wherein R^{I} and R^{X} are hydrogen.

In a preferred embodiment of the invention, the organic molecules include or consist of a structure according to any of Formulas II-a, II-b, wherein R^{I}, R^{V}, R^{XV} and R^{XIX} are hydrogen.

In a preferred embodiment of the invention, the organic molecules include or consist of a structure according to any of Formulas II-a, II-b, wherein R^{I}, R^{V}, R^{VI} and R^{X} are hydrogen.

In a preferred embodiment of the invention, the organic molecules include or consist of a structure according to any of Formulas II-a, II-b, wherein R^{I}, R^{V}, R^{VI}, R^{X}, R^{XV} and R^{XIX} are hydrogen.

In one embodiment of the invention, the organic molecules include or consist of a structure according to any of Formulas II-a, II-b, wherein R^{XI} is at each occurrence independently selected from the group consisting of:
hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a preferred embodiment of the invention, the organic molecules include or consist of a structure according to any of Formulas II-a, 1l-b, wherein R^{XI} is at each occurrence independently selected from the group consisting of:
hydrogen, Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In another preferred embodiment of the invention, the organic molecules include or consist of a structure according to any of Formulas wherein II-a, II-b, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In one embodiment of the invention, the organic molecules include or consist of a structure according to any of Formulas II-a, II-b, wherein R^{XI} is at each occurrence independently selected from the group consisting of:
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a certain embodiment of the invention, the organic molecules include or consist of a structure according to any of Formulas II-a, II-b, wherein R^{XI} is at each occurrence independently
N(Ph)₂, which is optionally substituted with one or more substituents independently from each other selected from the group consisting of Me, ⁱPr, ^{t}Bu, and Ph.

In one embodiment of the invention, the organic molecules include or consist of a structure according to any of Formulas II-a, II-b, wherein R^{XI} is at each occurrence independently N(Ph)₂.

In one embodiment of the invention, the organic molecules include or consist of a structure according to any of Formulas II-a, I-b, wherein R^{a} is at each occurrence independently selected from the group consisting of:
hydrogen,
Me, ⁱPr, ^{t}Bu, CN, CF₃, F,
aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a further embodiment of the invention, the organic molecules include or consist of a structure according to any of Formulas II-a, II-b, wherein R^{a} is at each occurrence independently selected from the group consisting of:
hydrogen, Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a further embodiment of the invention, the organic molecules include or consist of a structure according to any of Formulas II-a, II-b, wherein R^{a} is at each occurrence independently selected from the group consisting of:
hydrogen, Me, ⁱPr, ^{t}Bu F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
   and
N(Ph)₂, which is optionally substituted with one or more substituents independently from each other selected from the group consisting of Me, ⁱPr, ^{t}Bu, F and Ph.

In a further embodiment of the invention, the organic molecules include or consist of a structure according to any of Formulas II-a, II-b, wherein R^{a} is at each occurrence independently selected from the group consisting of:
hydrogen, Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a further embodiment of the invention, the organic molecules include or consist of a structure according to any of Formulas II-a, II-b, wherein R^{a} is at each occurrence independently selected from the group consisting of:
hydrogen, Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a further embodiment of the invention, the organic molecules include or consist of a structure according to any of Formulas II-a, II-b, wherein R^{a} is at each occurrence independently selected from the group consisting of:
hydrogen, Me, ⁱPr, ^{t}Bu, and
Ph, which is optionally substituted with one or more substituents independently from each other selected from the group consisting of Me, ⁱPr, ^{t}Bu, and Ph.

In a preferred embodiment of the invention, the organic molecules include or consist of a structure according to any of Formulas II-a, II-b, wherein R^{V}=R^{X} and R^{I}=R^{VI}.

In a preferred embodiment of the invention, the organic molecules include or consist of a structure of Formula IIa:

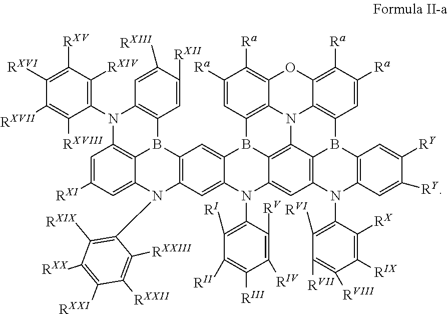

In a more preferred embodiment of the invention, the organic molecules include or consist of a structure of Formula II-a, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
   and

N(Ph)₂, which is optionally substituted with one or more substituents independently from each other selected from the group consisting of Me, ⁱPr, ^{t}Bu, F, and Ph.

In one embodiment of the invention, the organic molecules include or consist of a structure of Formula II-a, wherein R^{XI} is at each occurrence independently selected from the group consisting of:
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a certain embodiment of the invention, the organic molecules include or consist of a structure of Formula II-a, wherein R^{XI} is at each occurrence independently
N(Ph)₂, which is optionally substituted with one or more substituents independently from each other selected from the group consisting of Me, ⁱPr, ^{t}Bu, and Ph.

In one embodiment of the invention, the organic molecules include or consist of a structure of Formula II-a, wherein R^{XI} is at each occurrence independently N(Ph)₂.

In another embodiment of the invention, the organic molecules include or consist of a structure of Formula III-a and III-b:

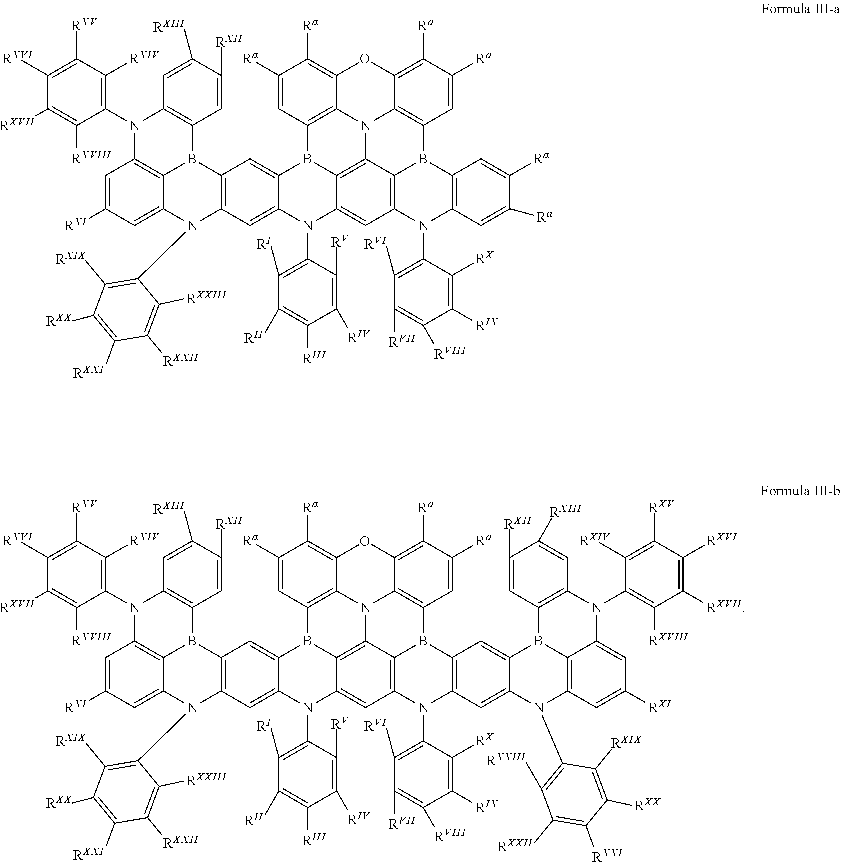

In one embodiment of the invention, the organic molecules include or consist of a structure according to any of Formulas III-a, and III-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In one embodiment of the invention, the organic molecules include or consist of a structure according to any of Formulas III-a, and III-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph, and
triazinyl, which is optionally substituted with one or more substituents independently from each other selected from the group consisting of Me, ⁱPr, ^{t}Bu, CN, CF₃, F and Ph.

In one embodiment of the invention, the organic molecules include or consist of a structure according to any of Formulas III-a, and III-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, CN, CF₃, F, and
Ph, which is optionally substituted with one or more substituents independently from each other selected from the group consisting of Me, ⁱPr, ^{t}Bu, CN, CF₃, F and Ph.

In one embodiment of the invention, the organic molecules include or consist of a structure according to any of Formulas III-a, and III-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, F, and
Ph, which is optionally substituted with one or more substituents independently from each other selected from the group consisting of Me, ⁱPr, ^{t}Bu, CN, CF₃, F and Ph.

In one embodiment of the invention, the organic molecules include or consist of a structure according to any of Formulas III-a, and III-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, F, and
Ph, which is optionally substituted with one or more substituents independently from each other selected from the group consisting of Me, ⁱPr, ^{t}Bu, and Ph.

In one embodiment of the invention, the organic molecules include or consist of a structure according to any of Formulas III-a, and III-b, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen,
Me, ⁱPr, ^{t}Bu, and
Ph, which is optionally substituted with one or more substituents independently from each other selected from the group consisting of Me, ⁱPr, ^{t}Bu, and Ph.

In a preferred embodiment of the invention, the organic molecules include or consist of a structure according to any of Formulas III-a, and III-b, wherein R^{I} and R^{X} are hydrogen.

In a certain embodiment of the invention, the organic molecules include or consist of a structure according to any of Formulas III-a, and III-b, wherein R^{I}, R^{V}, R^{VI} and R^{X} are hydrogen.

In a preferred embodiment of the invention, the organic molecules include or consist of a structure according to any of Formulas III-a, and III-b, wherein R^{XIII} and R^{XII} are hydrogen.

In a preferred embodiment of the invention, the organic molecules include or consist of a structure according to any of Formulas III-a, and III-b, wherein R^{XV} and R^{XIX} are hydrogen.

In a preferred embodiment of the invention, the organic molecules include or consist of a structure according to any of Formulas III-a, and III-b, wherein R^{I} and R^{X} are hydrogen.

In a preferred embodiment of the invention, the organic molecules include or consist of a structure according to any of Formulas III-a, and III-b, wherein R^{I}, R^{V}, R^{XV} and R^{XIX} are hydrogen.

In a preferred embodiment of the invention, the organic molecules include or consist of a structure according to any of Formulas III-a, and III-b, wherein R^{I}, R^{V}, R^{VI} and R^{X} are hydrogen.

In a preferred embodiment of the invention, the organic molecules include or consist of a structure according to any of Formulas III-a, and III-b, wherein R^{I}, R^{V}, R^{VI}, R^{X}, R^{XV} and R^{XIX} are hydrogen.

In one embodiment of the invention, the organic molecules include or consist of a structure according to any of Formulas III-a, and III-b, wherein R^{XI} is at each occurrence independently selected from the group consisting of:
hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a preferred embodiment of the invention, the organic molecules include or consist of a structure according to any of Formulas III-a, and III-b, wherein R^{XI} is at each occurrence independently selected from the group consisting of:
hydrogen, Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a more preferred embodiment of the invention, the organic molecules include or consist of a structure according to any of Formulas wherein III-a, and III-b, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In one embodiment of the invention, the organic molecules include or consist of a structure according to any of Formulas III-a, and III-b, wherein R^{XI} is at each occurrence independently selected from the group consisting of:
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a certain embodiment of the invention, the organic molecules include or consist of a structure according to any of Formulas III-a, and III-b, wherein R^{XI} is at each occurrence independently
N(Ph)₂, which is optionally substituted with one or more substituents independently from each other selected from the group consisting of Me, ⁱPr, ^{t}Bu, and Ph.

In one embodiment of the invention, the organic molecules include or consist of a structure according to any of Formulas III-a, and III-b, wherein R^{XI} is at each occurrence independently
N(Ph)₂.

In one embodiment of the invention, the organic molecules include or consist of a structure according to any of Formulas III-a, and III-b, wherein R^{a} is at each occurrence independently selected from the group consisting of:
hydrogen, Me, ⁱPr, ^{t}Bu, CN, CF₃, F,
aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph, and
N(Ph)₂, which is optionally substituted with one or more substituents independently from each other selected from the group consisting of Me, ⁱPr, ^{t}Bu, F and Ph.

In a further embodiment of the invention, the organic molecules include or consist of a structure according to any of Formulas III-a, and III-b, wherein R^{a} is at each occurrence independently selected from the group consisting of:
hydrogen, Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
   and
N(Ph)₂, which is optionally substituted with one or more substituents independently from each other selected from the group consisting of Me, ⁱPr, ^{t}Bu, F and Ph.

In a further embodiment of the invention, the organic molecules include or consist of a structure according to any of Formulas III-a, and III-b, wherein R^{a} is at each occurrence independently selected from the group consisting of:
hydrogen, Me, ⁱPr, ^{t}Bu, F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
   and
N(Ph)₂, which is optionally substituted with one or more substituents independently from each other selected from the group consisting of Me, ⁱPr, ^{t}Bu, F and Ph.

In a further embodiment of the invention, the organic molecules include or consist of a structure according to any of Formulas III-a, and III-b, wherein R^{a} is at each occurrence independently selected from the group consisting of:
hydrogen, Me, ⁱPr, ^{t}Bu
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a further embodiment of the invention, the organic molecules include or consist of a structure according to any of Formulas III-a, and III-b, wherein R^{a} is at each occurrence independently selected from the group consisting of:
hydrogen, Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a further embodiment of the invention, the organic molecules include or consist of a structure according to any of Formulas III-a, and III-b, wherein R^{a} is at each occurrence independently selected from the group consisting of:
hydrogen, Me, ⁱPr, ^{t}Bu
   and
Ph, which is optionally substituted with one or more substituents independently from each other selected from the group consisting of Me, ⁱPr, ¹Bu, and Ph.

In a preferred embodiment of the invention, the organic molecules include or consist of a structure according to any of Formulas III-a, and III-b, wherein R^{V}=R^{X} and R^{I}=R^{VI}

In another embodiment of the invention, the organic molecules include or consist of a structure of Formula III-b:

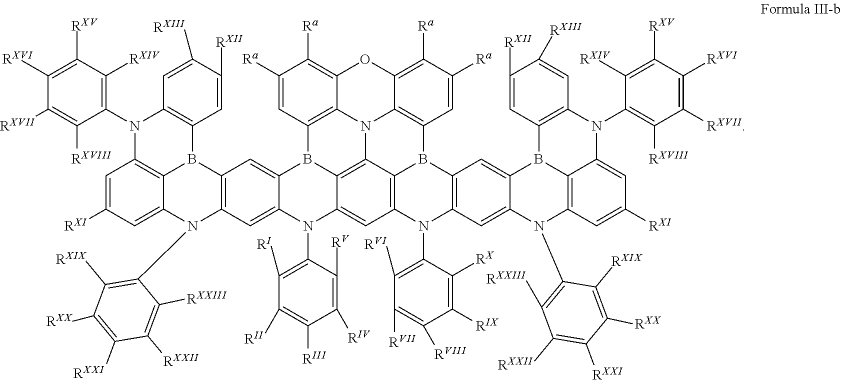

In a preferred embodiment of the invention, the second chemical moiety consist of a structure of Formula II-0a, Formula II-0b or Formula II-0c:

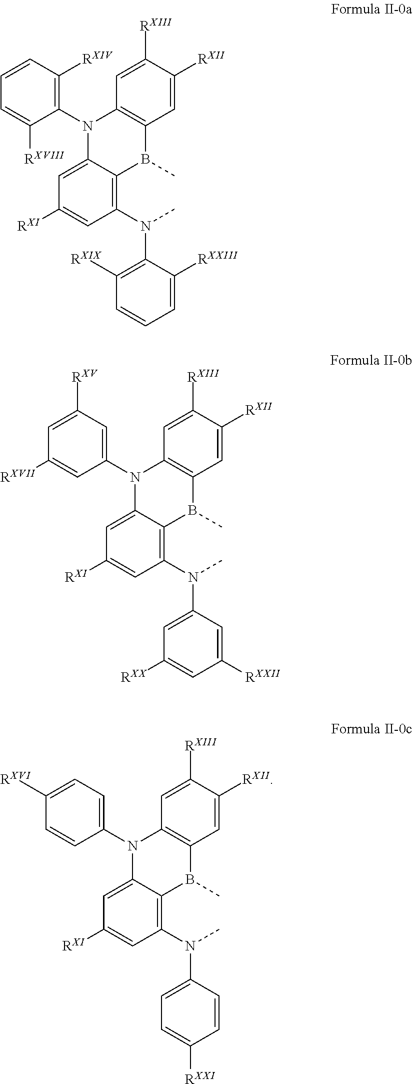

In a more preferred embodiment of the invention, the organic molecules include or consist of a structure of Formula II-0a, Formula II-0b and Formula II-0c, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, F, and Ph.

In one embodiment of the invention, the organic molecules include or consist of a structure of Formula II-0a, Formula II-0b and Formula II-0c, wherein R^{XI} is at each occurrence independently selected from the group consisting of:
Ph, which is optionally substituted with one or more substituents independently from each other selected from the group consisting of Me, ⁱPr, ^{t}Bu, and Ph,
   and
N(Ph)₂, which is optionally substituted with one or more substituents independently from each other selected from the group consisting of Me, ⁱPr, ^{t}Bu, and Ph.

In a certain embodiment of the invention, the organic molecules include or consist of a structure of Formula II-0a, Formula II-0b and Formula II-0c, wherein R^{XI} is at each occurrence independently
N(Ph)₂, which is optionally substituted with one or more substituents independently from each other selected from the group consisting of Me, ⁱPr, ^{t}Bu, and Ph.

In one embodiment of the invention, the organic molecules include or consist of a structure of Formula II-0a, Formula II-0b and Formula II-0c, wherein R^{XI} is N(Ph)₂.

In one embodiment of the invention, the organic molecules include or consist of a structure of Formula II-0a, Formula II-0b and Formula II-0c, wherein R^{XIII} is at each occurrence hydrogen.

In one embodiment of the invention, the organic molecules include or consist of a structure of Formula II-0a, Formula II-0b and Formula II-0c, wherein R^{XII} is at each occurrence hydrogen.

In one embodiment of the invention, the organic molecules include or consist of a structure of Formula II-0a, Formula II-0b and Formula II-0c, wherein R^{XIII} and R^{XII} are at each occurrence hydrogen.

In a preferred embodiment of the invention, the second chemical moiety consists of a structure of Formula II-I:

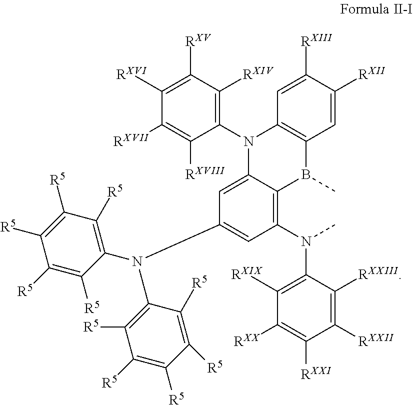

In a preferred embodiment of the invention, the second chemical moiety consists of a structure of Formula II-II:

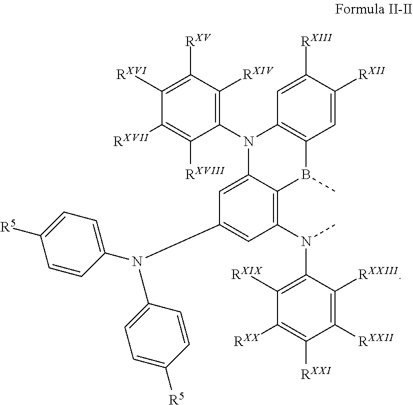

As used throughout the present application, the term “cyclic group” may be understood in the broadest sense as any mono-, bi- or polycyclic moieties.

As used throughout the present application, the terms “ring” and “ring system” may be understood in the broadest sense as any mono-, bi- or polycyclic moieties.

As used throughout the present application, the term “carbocycle” may be understood in the broadest sense as any cyclic group in which the cyclic core structure includes only carbon atoms that may of course be substituted with hydrogen or any other substituents defined in the specific embodiments of the invention. It is understood that the term “carbocyclic” as adjective refers to cyclic groups in which the cyclic core structure includes only carbon atoms that may of course be substituted with hydrogen or any other substituents defined in the specific embodiments of the invention.

As used throughout the present application, the term “heterocycle” may be understood in the broadest sense as any cyclic group in which the cyclic core structure includes not just carbon atoms, but also at least one heteroatom. It is understood that the term “heterocyclic” as adjective refers to cyclic groups in which the cyclic core structure includes not just carbon atoms, but also at least one heteroatom. The heteroatoms may, unless stated otherwise in specific embodiments, at each occurrence be the same or different and be individually selected from the group consisting of N, O, S, and Se. All carbon atoms or heteroatoms included in a heterocycle in the context of the invention may of course be substituted with hydrogen or any other substituents defined in the specific embodiments of the invention.

As used throughout the present application, the term “aromatic ring system” may be understood in the broadest sense as any bi- or polycyclic aromatic moiety.

As used throughout the present application, the term “heteroaromatic ring system” may be understood in the broadest sense as any bi- or polycyclic heteroaromatic moiety.

As used throughout the present application, the term “fused” when referring to aromatic or heteroaromatic ring systems means that the aromatic or heteroaromatic rings that are “fused” share at least one bond that is part of both ring systems. For example, naphthalene (or naphthyl when referred to as substituent) or benzothiophene (or benzothiophenyl when referred to as substituent) are considered fused aromatic ring systems in the context of the present invention, in which two benzene rings (for naphthalene) or a thiophene and a benzene (for benzothiophene) share one bond. It is also understood that sharing a bond in this context includes sharing the two atoms that build up the respective bond and that fused aromatic or heteroaromatic ring systems can be understood as one aromatic or heteroaromatic system. Additionally, it is understood, that more than one bond may be shared by the aromatic or heteroaromatic rings building up a fused aromatic or heteroaromatic ring system (e.g., in pyrene). Furthermore, it will be understood that aliphatic ring systems may also be fused and that this has the same meaning as for aromatic or heteroaromatic ring systems, with the exception of course, that fused aliphatic ring systems are not aromatic.

As used throughout the present application, the terms “aryl” and “aromatic” may be understood in the broadest sense as any mono-, bi- or polycyclic aromatic moieties. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. In particular, the heteroaromatic ring includes one to three heteroatoms. Again, the terms “heteroaryl” and “heteroaromatic” may be understood in the broadest sense as any mono-, bi- or polycyclic hetero-aromatic moieties that include at least one heteroatom. The heteroatoms may, unless stated otherwise in specific embodiments, at each occurrence be the same or different and be individually selected from the group consisting of N, O, S, and Se. Accordingly, the term “arylene” refers to a divalent substituent that bears two binding sites to other molecular structures and thereby serving as a linker structure. In case, a group in the exemplary embodiments is defined differently from the definitions given here, for example, the number of aromatic ring atoms or number of heteroatoms differs from the given definition, the definition in the exemplary embodiments is to be applied. According to the invention, a condensed (annulated) aromatic or heteroaromatic polycycle is built of two or more single aromatic or heteroaromatic cycles, which formed the polycycle via a condensation reaction.

In particular, as used throughout the present application the term “aryl group” or “heteroaryl group” includes groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, selenophene, benzoselenophene, isobenzoselenophene, dibenzoselenophene; pyrrole, indole, isoindole, carbazole, indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazole, phenanthroxazole, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole or combinations of the abovementioned groups.

As used throughout the present application, the term “aliphatic” when referring to ring systems may be understood in the broadest sense and means that none of the rings that build up the ring system is an aromatic or heteroaromatic ring. It is understood that such an aliphatic ring system may be fused to one or more aromatic rings so that some (but not all) carbon- or heteroatoms included in the core structure of the aliphatic ring system are part of an attached aromatic ring.

As used above and herein, the term “alkyl group” may be understood in the broadest sense as any linear, branched, or cyclic alkyl substituent. In particular, the term alkyl includes the substituents methyl (Me), ethyl (Et), n-propyl (ⁿPr), i-propyl (ⁱPr), cyclopropyl, n-butyl (ⁿBu), i-butyl (^{t}Bu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl.

As used above and herein, the term “alkenyl” includes linear, branched, and cyclic alkenyl substituents. The term alkenyl group exemplarily includes the substituents ethenyl, propenyl, butenyl, pentenyl, cyclopentenyl, hexenyl, cyclohexenyl, heptenyl, cycloheptenyl, octenyl, cyclooctenyl or cyclooctadienyl.

As used above and herein, the term “alkynyl” includes linear, branched, and cyclic alkynyl substituents. The term alkynyl group exemplarily includes ethynyl, propynyl, butynyl, pentynyl, hexynyl, heptynyl or octynyl.

As used above and herein, the term “alkoxy” includes linear, branched, and cyclic alkoxy substituents. The term alkoxy group exemplarily includes methoxy, ethoxy, n-propoxy, i-propoxy, n-butoxy, i-butoxy, s-butoxy, t-butoxy and 2-methylbutoxy.

As used above and herein, the term “thioalkoxy” includes linear, branched, and cyclic thioalkoxy substituents, in which the O of the exemplarily alkoxy groups is replaced by S.

As used above and herein, the terms “halogen” and “halo” may be understood in the broadest sense as being preferably fluorine, chlorine, bromine or iodine.

It is understood that when a molecular fragment is described as being a substituent or otherwise attached to another moiety, its name may be written as if it were a fragment (e.g., naphthyl, dibenzofuryl) or as if it were the whole molecule (e.g., naphthalene, dibenzofuran). As used herein, these different ways of designating a substituent or attached fragment are considered to be equivalent.

All hydrogen atoms (H) included in any structure referred to herein may at each occurrence independently of each other, and without this being indicated specifically, be replaced by deuterium (D). The replacement of hydrogen by deuterium is common practice and obvious for the person skilled in the art. Thus, there are numerous known methods by which this can be achieved and several review articles describing them (see for example: A. Michelotti, M. Roche, Synthesis 2019, 51(06), 1319-1328, DOI: 10.1055/s-0037-1610405; J. Atzrodt, V. Derdau, T. Fey, J. Zimmermann, Angew. Chem. Int. Ed. 2007, 46(15), 7744-7765. DOI: 10.1002/anie.200700039; Y. Sawama, Y. Monguchi, H. Sajiki, Synlett 2012, 23(7), 959-972, DOI: 10.1055/s-0031-1289696).

The excited state lifetime consists of multiple components. For example, in case for TADF emitters it consists of prompt fluorescence which usually lies in the order of magnitude of nanoseconds and delayed fluorescence which usually lies in the order of magnitude of microseconds. Since the delayed fluorescence is three orders of magnitude larger, the prompt fluorescence is insignificant which implies that the excited state lifetime can be estimated by the lifetime of the delayed fluorescence.

In one embodiment, the organic molecules according to the invention have an excited state lifetime of not more than 10 μs, of not more than 8 μs, in particular of not more than 6 μs, more preferably of not more than 5 μs or not more than 4 μs, even more preferably of not more than 3 μs or not more than 2 μs in a film of poly(methyl methacrylate) (PMMA) with 1-5% by weight, in particular with 1% by weight organic molecule at room temperature (i.e., approximately 25° C.).

In one embodiment of the invention, the organic molecules according to the invention represent thermally-activated delayed fluorescence (TADF) emitters, which exhibit a ΔEsT value, which corresponds to the energy difference between the first excited singlet state (S1) and the first excited triplet state (T1), of less than 5000 cm⁻¹, preferably less than 3000 cm⁻¹, more preferably less than 1500 cm⁻¹, even more preferably less than 1000 cm⁻¹ or even less than 500 cm⁻¹.

In a further embodiment, the organic molecules according to the invention have an excited state lifetime of not more than 10 μs, of not more than 8 μs, in particular of not more than 6 μs, more preferably of not more than 5 μs or not more than 4 μs, even more preferably of not more than 3 μs or not more than 2 μs, with a full width at half maximum of less than 0.23 eV, preferably less than 0.20 eV, more preferably less than 0.19 eV, even more preferably less than 0.15 eV or even less than 0.12 eV in a film of poly(methyl methacrylate) (PMMA) with 1-5% by weight, in particular with 1% by weight of organic molecule at room temperature (i.e., approximately 25° C.).

In one embodiment, the organic molecules according to the invention have an excited state lifetime of not more than 10 μs, of not more than 7 μs, in particular of not more than 5 μs, more preferably of not more than 2 μs or not more than 1 μs in a film of poly(methyl methacrylate) (PMMA) with 1% by weight of organic molecule at room temperature.

If not stated otherwise, excited state lifetime in the context of the organic molecules according to the invention is equal to and/or is determined by the delayed fluorescence lifetime or delayed fluorescence decay time.

In a further embodiment of the invention, the organic molecules according to the invention have an emission peak in the visible or nearest ultraviolet range, i.e., in the range of a wavelength of from 380 nm to 800 nm, with a full width at half maximum of less than 0.23 eV, preferably less than 0.20 eV, more preferably less than 0.19 eV, even more preferably less than 0.15 eV or even less than 0.12 eV in a film of poly(methyl methacrylate) (PMMA) with 1% by weight of organic molecule at room temperature.

Orbital and excited state energies can be determined either by means of experimental methods or by calculations employing quantum-chemical methods, in particular density functional theory calculations. The energy of the highest occupied molecular orbital E^{HOMO} is determined by methods known to the person skilled in the art from cyclic voltammetry measurements with an accuracy of 0.1 eV. The energy of the lowest unoccupied molecular orbital E^{LUMO} is determined as the onset of the absorption spectrum.

The onset of an absorption spectrum is determined by computing the intersection of the tangent to the absorption spectrum with the x-axis. The tangent to the absorption spectrum is set at the low-energy side of the absorption band and at the point at half maximum of the maximum intensity of the absorption spectrum.

Unless stated otherwise, the energy of the first excited triplet state T1 is determined from the onset the phosphorescence spectrum at 77K (steady-state spectrum; film of 2% by weight of emitter in PMMA).

Unless stated otherwise, the energy of the first excited singlet state S1 is determined from the onset the fluorescence spectrum at room temperature (i.e., approx. 25° C.; steady-state spectrum; film of 2% by weight of emitter in PMMA).

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

The ΔE_{ST} value, which corresponds to the energy difference between the first excited singlet state (S1) and the first excited triplet state (T1), is determined based on the first excited singlet state energy and the first excited triplet state energy, which were determined as stated above.

A further aspect of the invention relates to the use of an organic molecule according to the invention as a luminescent emitter or as an absorber, and/or as host material and/or as electron transport material, and/or as hole injection material, and/or as hole blocking material in an optoelectronic device.

The optoelectronic device may be understood in the broadest sense as any device based on organic materials that is suitable for emitting light in the visible or nearest ultraviolet (UV) range, i.e., in the wavelength range from 380 nm to 800 nm. More preferably, the optoelectronic device may be able to emit light in the visible range, i.e., of from 400 nm to 800 nm.

In the context of such use, the optoelectronic device is more particularly selected from the group consisting of:
organic light-emitting diodes (OLEDs),
light-emitting electrochemical cells,
OLED sensors, in particular in gas and vapor sensors not hermetically shielded to the outside,
organic diodes,
organic solar cells,
organic transistors,
organic field-effect transistors,
organic lasers, and
down-conversion elements.

A light-emitting electrochemical cell includes three layers, namely a cathode, an anode, and an active layer, which contains the organic molecule according to the invention.

In a preferred embodiment in the context of such use, the optoelectronic device is a device selected from the group consisting of an organic light emitting diode (OLED), a light emitting electrochemical cell (LEC), an organic laser, and a light-emitting transistor.

In one embodiment, the light-emitting layer of an organic light-emitting diode includes the organic molecules according to the invention.

In one embodiment, the light-emitting layer of an organic light-emitting diode includes not only the organic molecules according to the invention but also a host material whose triplet (T1) and singlet (S1) energy levels are energetically higher than the triplet (T1) and singlet (S1) energy levels of the organic molecule.

A further aspect of the invention relates to a composition including or consisting of:
(a) the organic molecule of the invention, in particular in the form of an emitter and/or a host, and
(b) one or more emitter and/or host materials, which differ from the organic molecule of the invention, and
(c) optionally, one or more dyes and/or one or more solvents.

In a further embodiment of the invention, the composition has a photoluminescence quantum yield (PLQY) of more than 5%, preferably more than 10%, preferably more than 20%, more preferably more than 40%, even more preferably more than 60% or even more than 70% at room temperature.

Compositions with at Least One Further Emitter

One embodiment of the invention relates to a composition including or consisting of:
(i) 1-50% by weight, preferably 5-40% by weight, in particular 10-30% by weight, of the organic molecule according to the invention;
(ii) 5-98% by weight, preferably 30-93.9% by weight, in particular 40-88% by weight, of one host compound H;
(iii) 1-30% by weight, in particular 1-20% by weight, preferably 1-5% by weight, of at least one further emitter molecule F with a structure differing from the structure of the molecules according to the invention; and
(iv) optionally 0-94% by weight, preferably 0.1-65% by weight, in particular 1-50% by weight, of at least one further host compound D with a structure differing from the structure of the molecules according to the invention; and
(v) optionally 0-94% by weight, preferably 0-65% by weight, in particular 0-50% by weight, of a solvent.

The components or the compositions are chosen such that the sum of the weight of the components add up to 100%.

In a further embodiment of the invention, the composition has an emission peak in the visible or nearest ultraviolet range, i.e., in the range of a wavelength of from 380 to 800 nm.

In one embodiment of the invention, the at least one further emitter molecule F is a purely organic emitter.

In one embodiment of the invention, the at least one further emitter molecule F is a purely organic TADF emitter. Purely organic TADF emitters are known from the state of the art, e.g., Wong and Zysman-Colman (“Purely Organic Thermally Activated Delayed Fluorescence Materials for Organic Light-Emitting Diodes”, Adv. Mater 2017, 29(22), 1605444-1605498, DOI: 10.1002/adma.201605444).

In one embodiment of the invention, the at least one further emitter molecule F is a fluorescence emitter, in particular a blue, a green, a yellow or a red fluorescence emitter.

In a further embodiment of the invention, the composition, containing the at least one further emitter molecule F shows an emission peak in the visible or nearest ultraviolet range, i.e., in the range of a wavelength of from 380 to 800 nm, with a full width at half maximum of less than 0.30 eV, in particular less than 0.25 eV, preferably less than 0.22 eV, more preferably less than 0.19 eV or even less than 0.17 eV at room temperature, with a lower limit of 0.05 eV.

Composition wherein the at least one further emitter molecule F is a green fluorescence emitter

In a further embodiment of the invention, the at least one further emitter molecule F is a fluorescence emitter, in particular a green fluorescence emitter.

In one embodiment, the at least one further emitter molecule F is a fluorescence emitter selected from the following group:

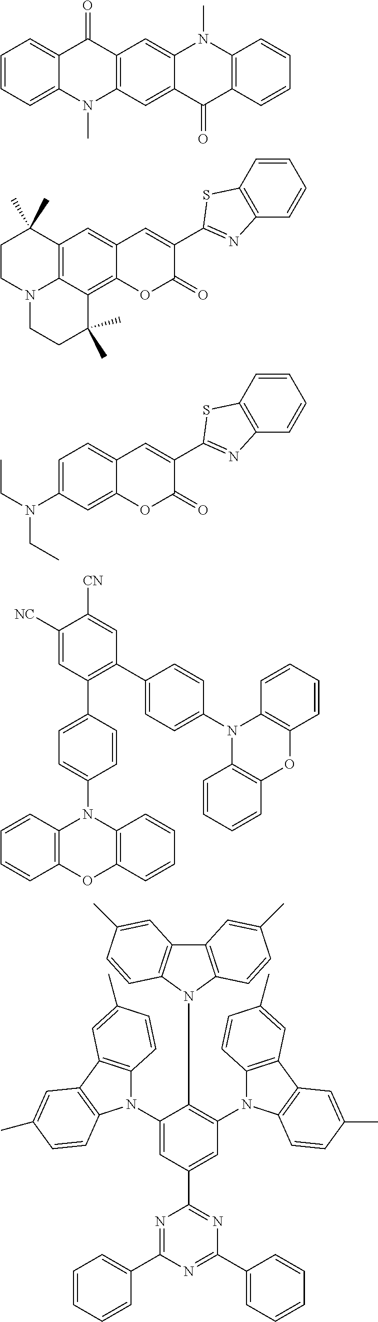

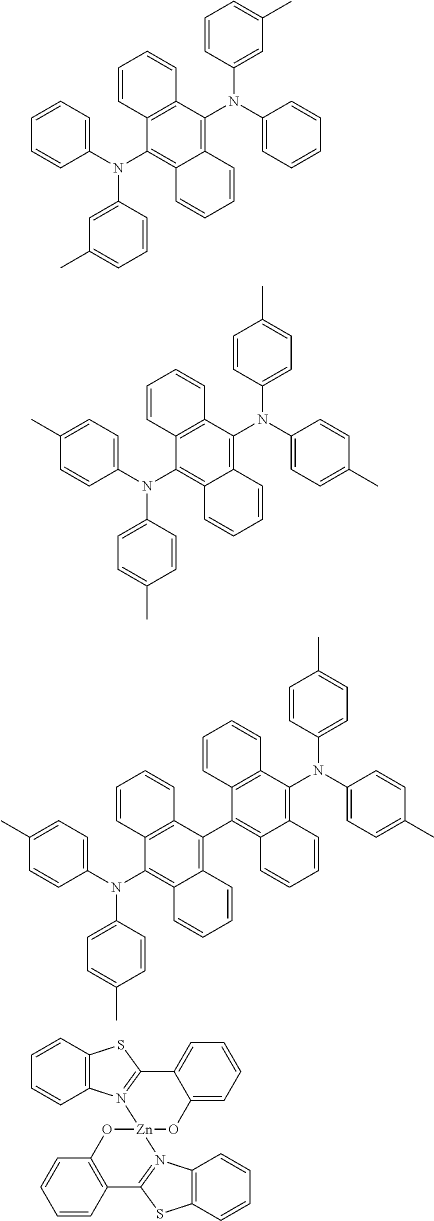

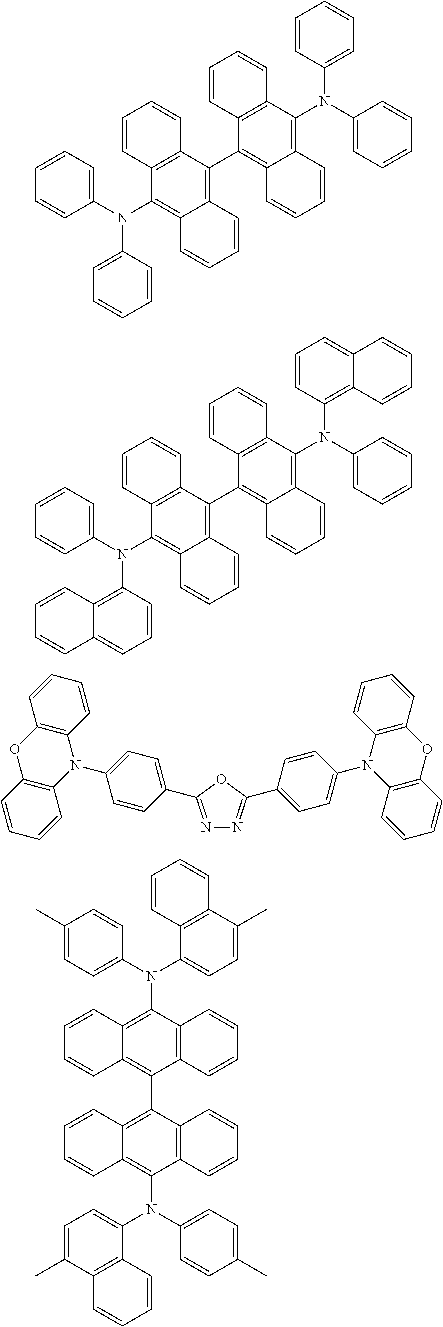

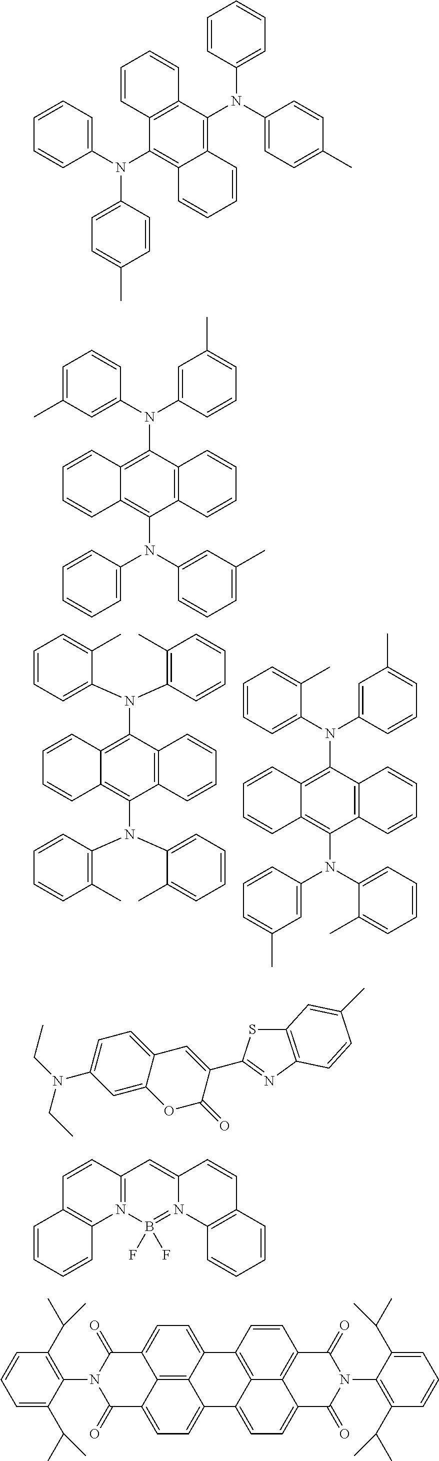

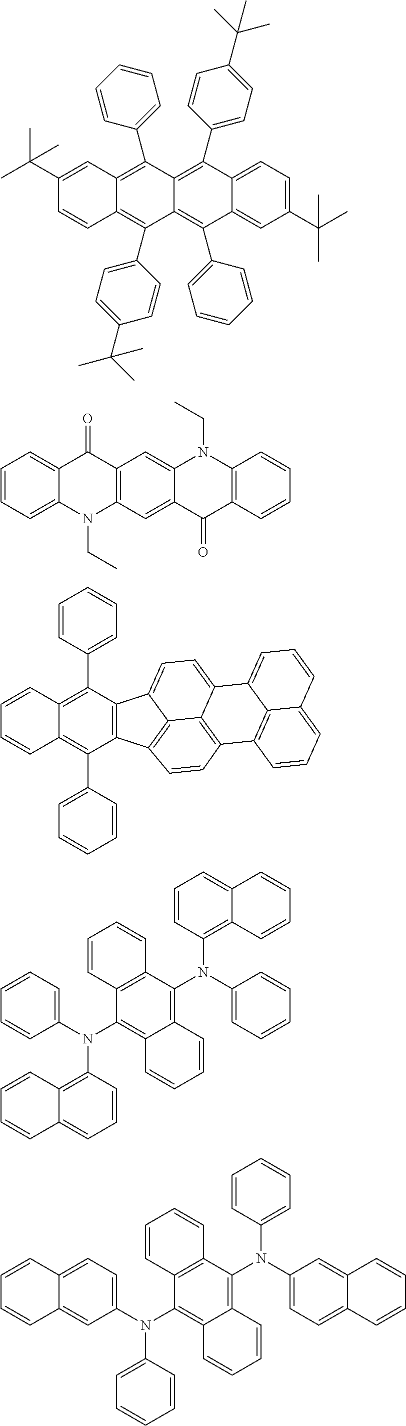

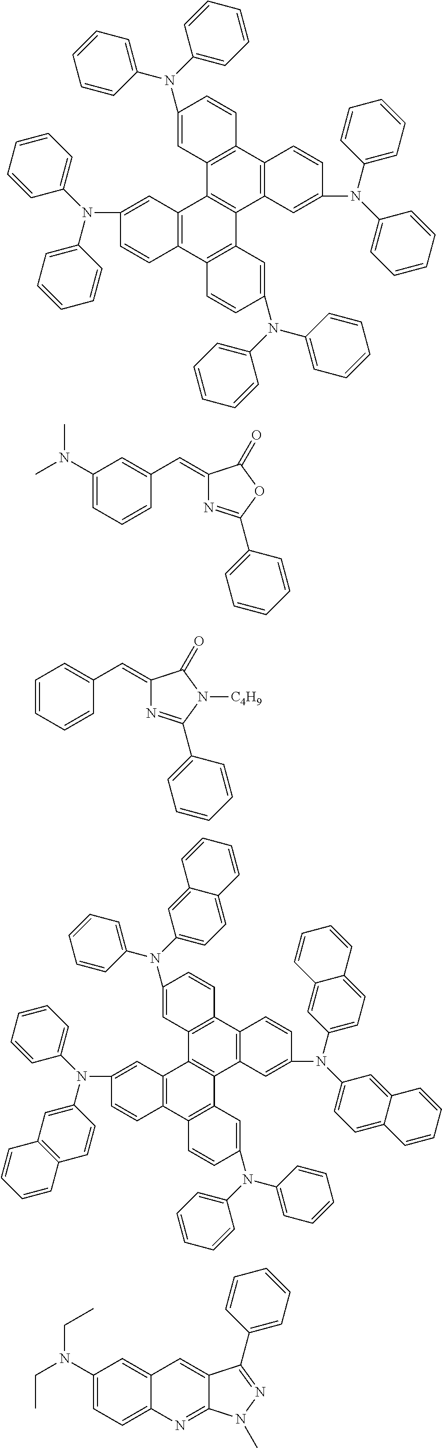

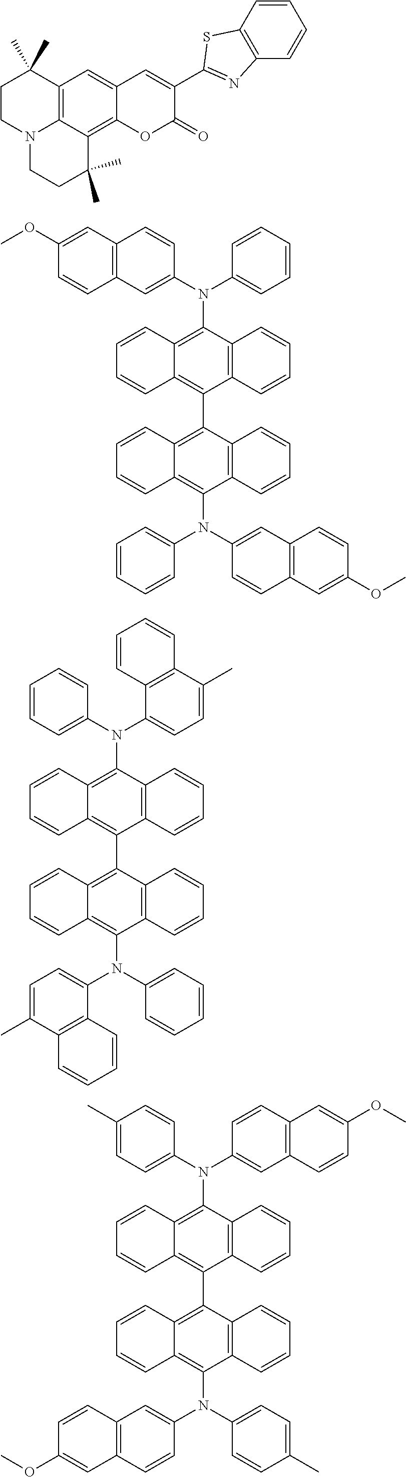

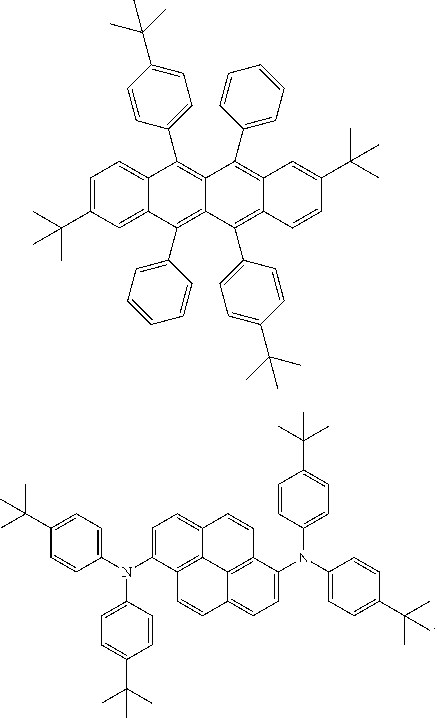

In a further embodiment of the invention, the composition has an emission peak in the visible or nearest ultraviolet range, i.e., in the range of a wavelength of from 380 to 800 nm, in particular between 485 nm and 590 nm, preferably between 505 nm and 565 nm, even more preferably between 515 nm and 545 nm.

Composition wherein the at least one further emitter molecule F; is a red fluorescence emitter

In a further embodiment of the invention, the at least one further emitter molecule F is a fluorescence emitter, in particular a red fluorescence emitter.

In one embodiment, the at least one further emitter molecule F is a fluorescence emitter selected from the following group:

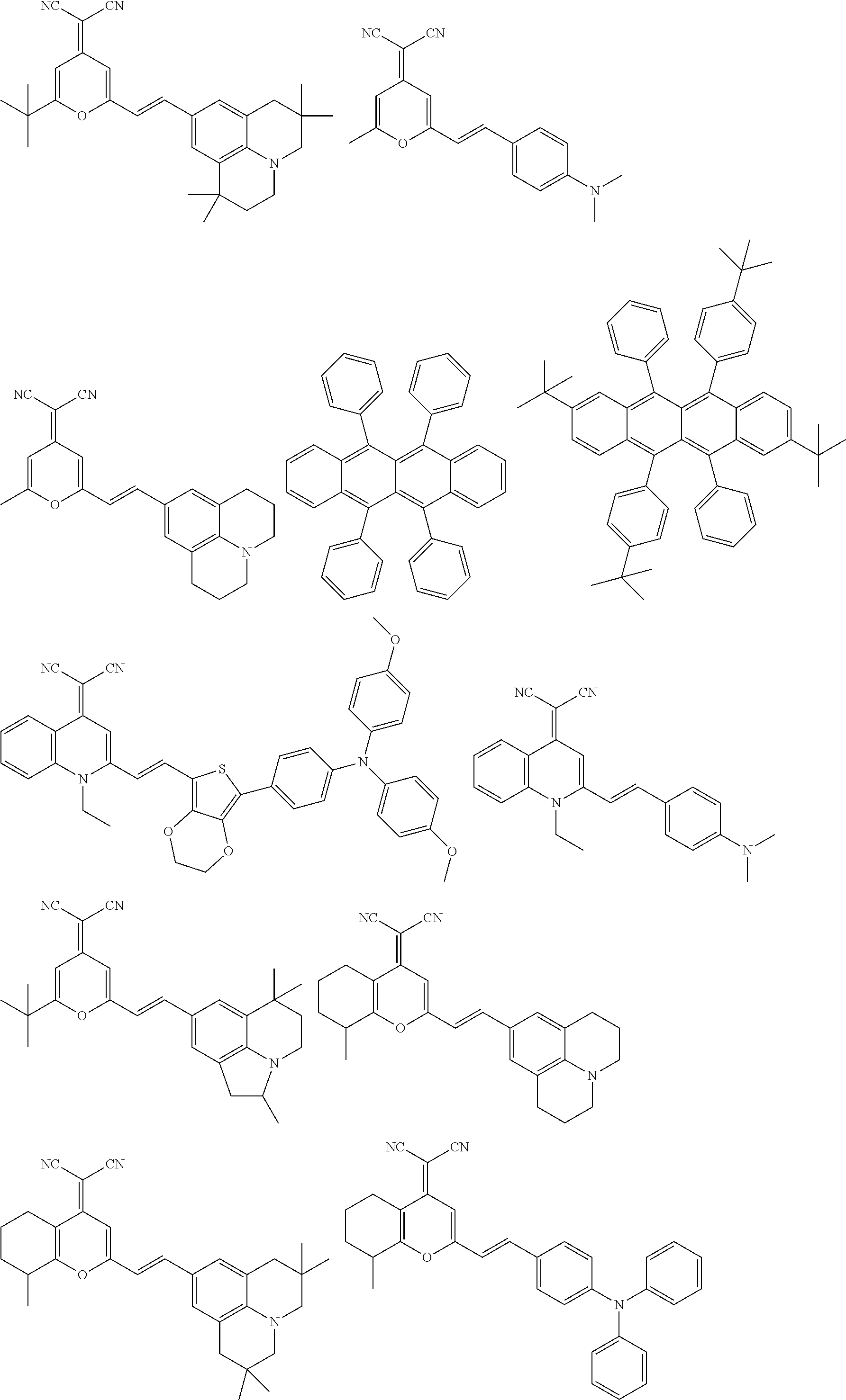

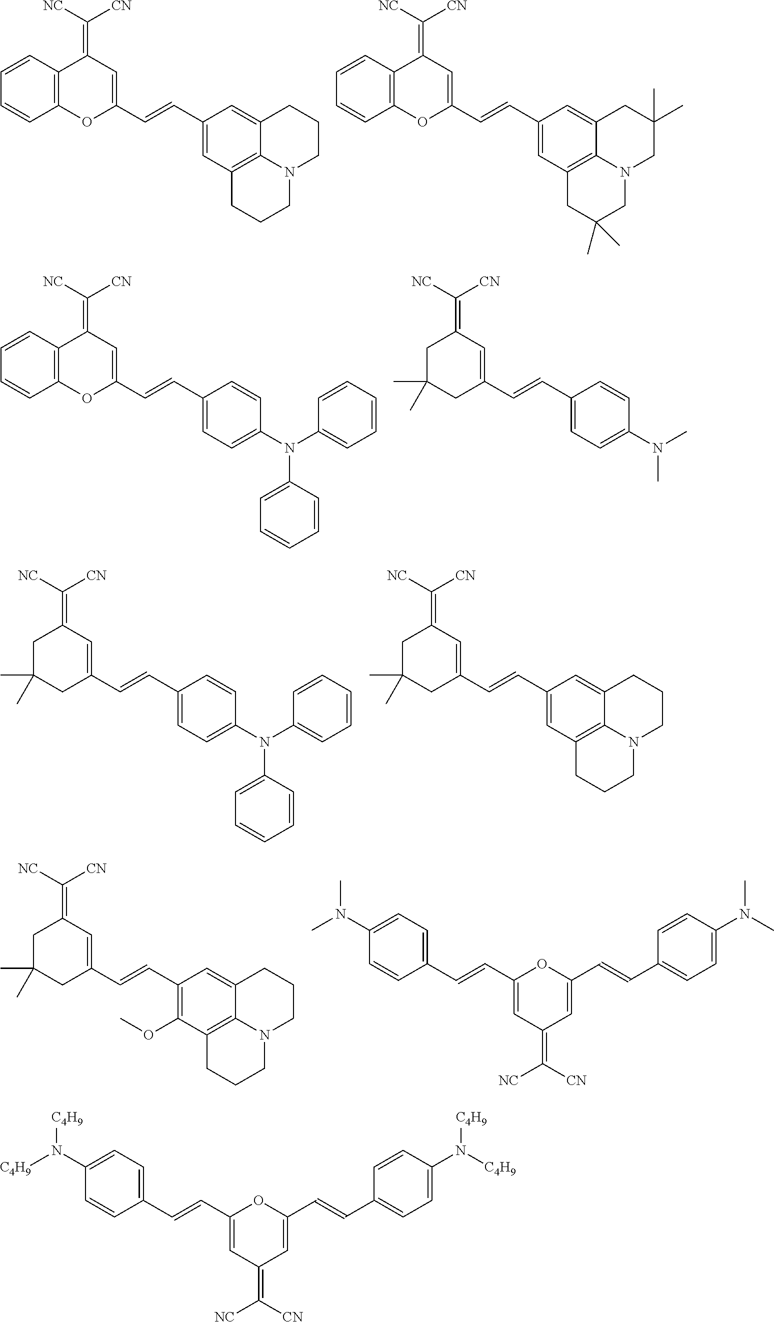

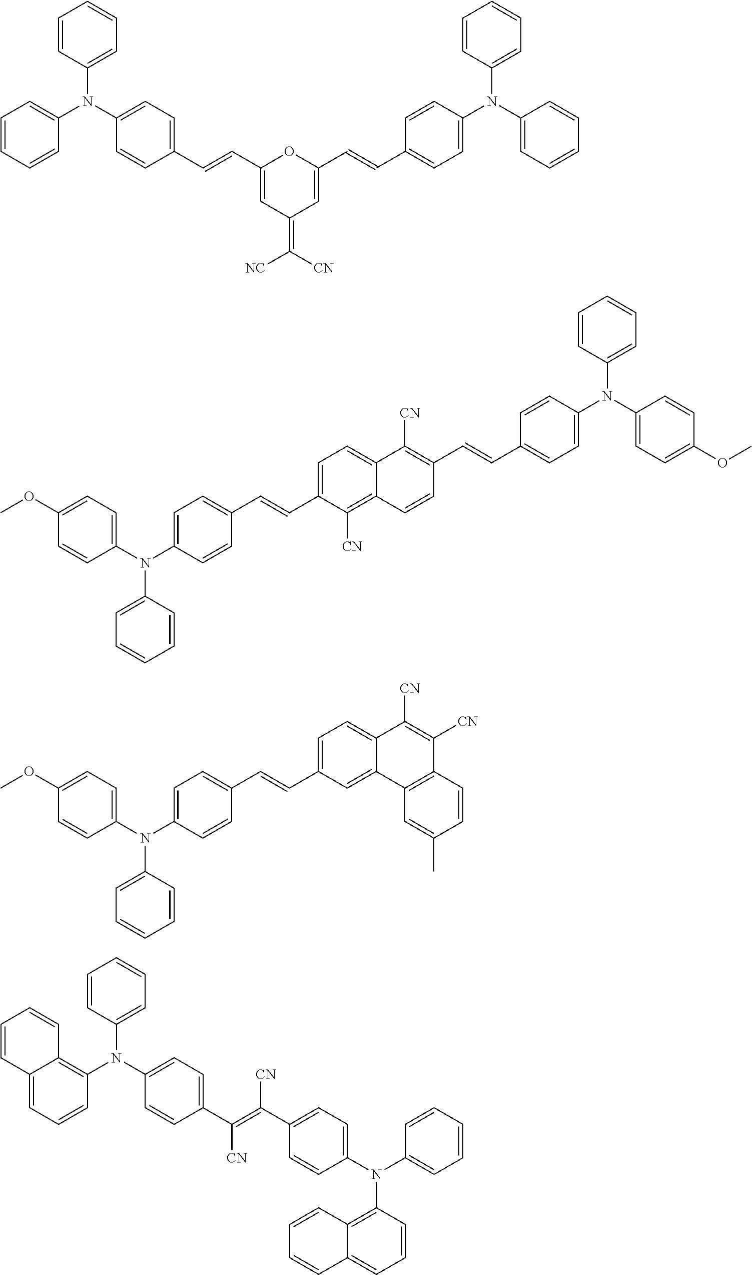

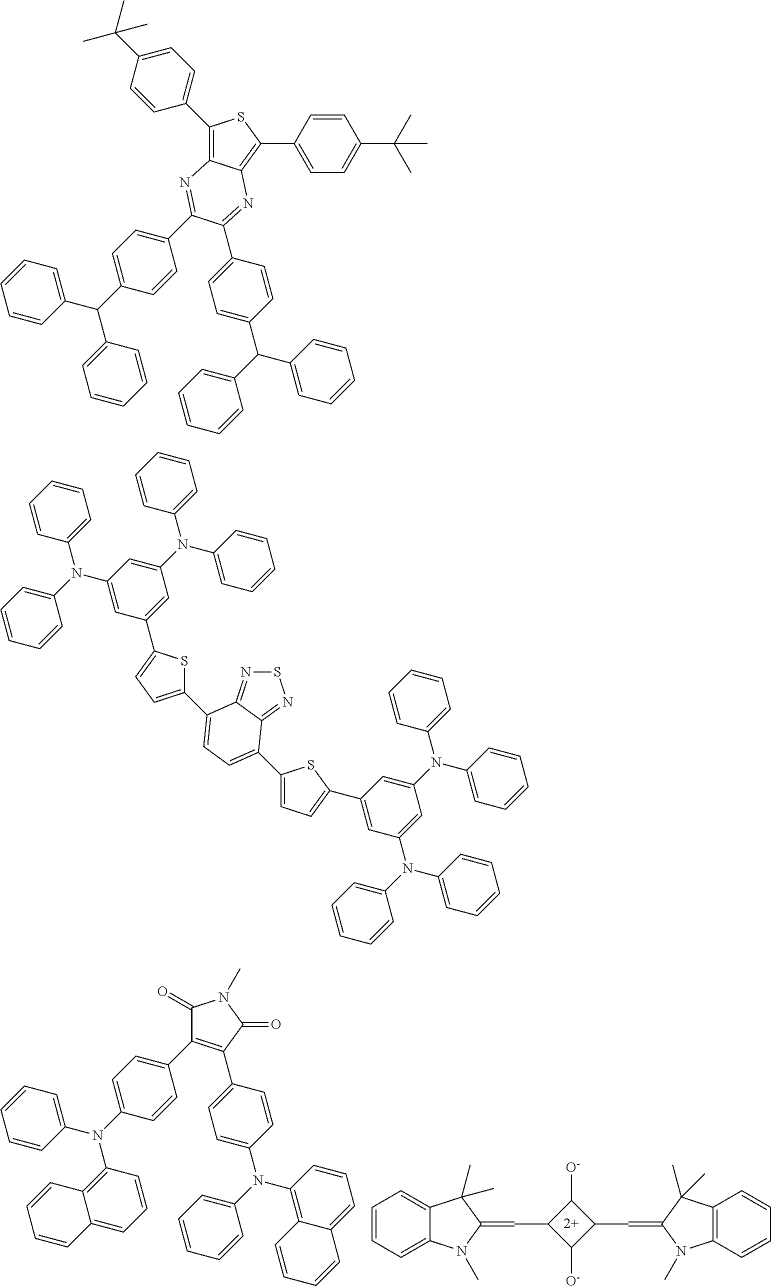

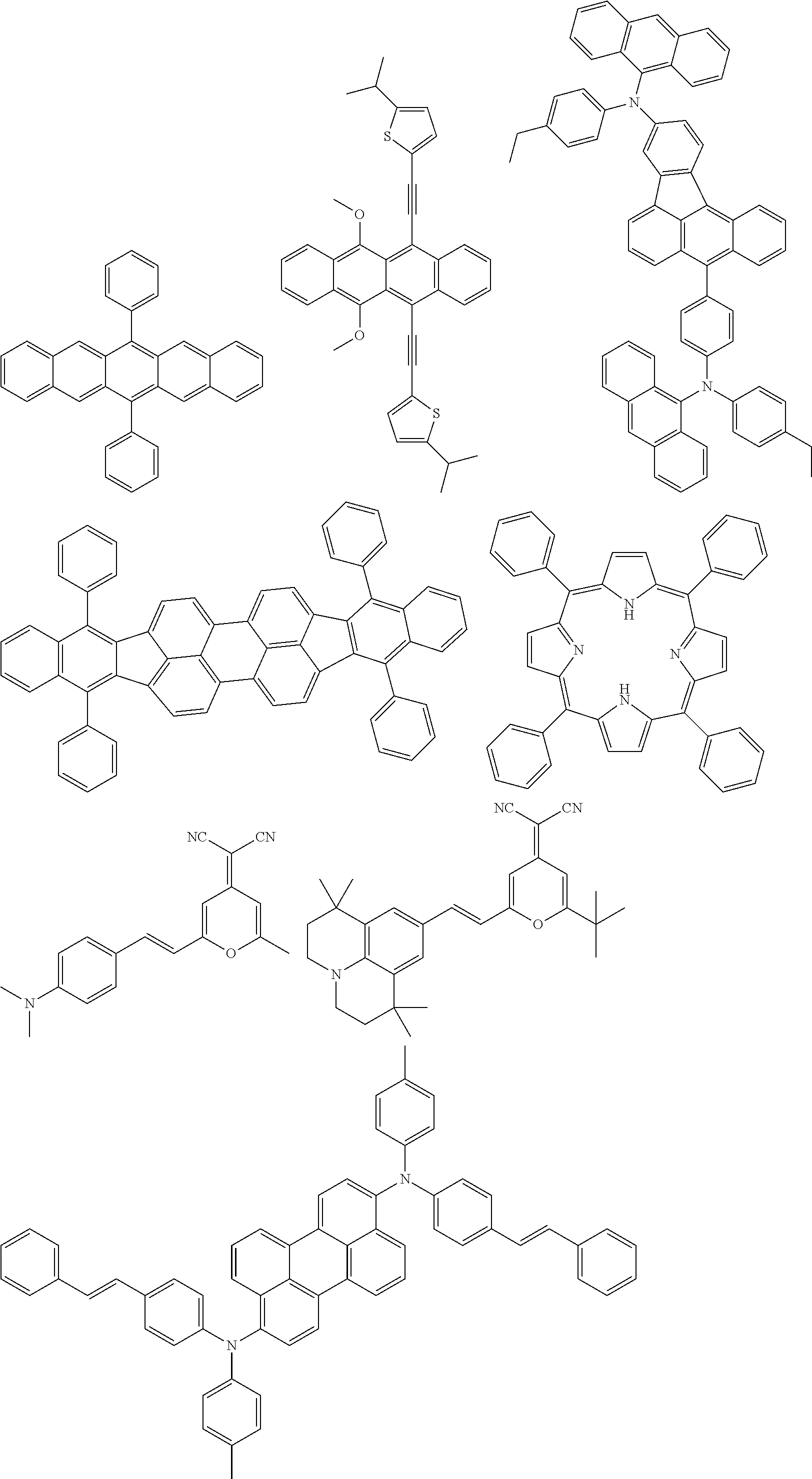

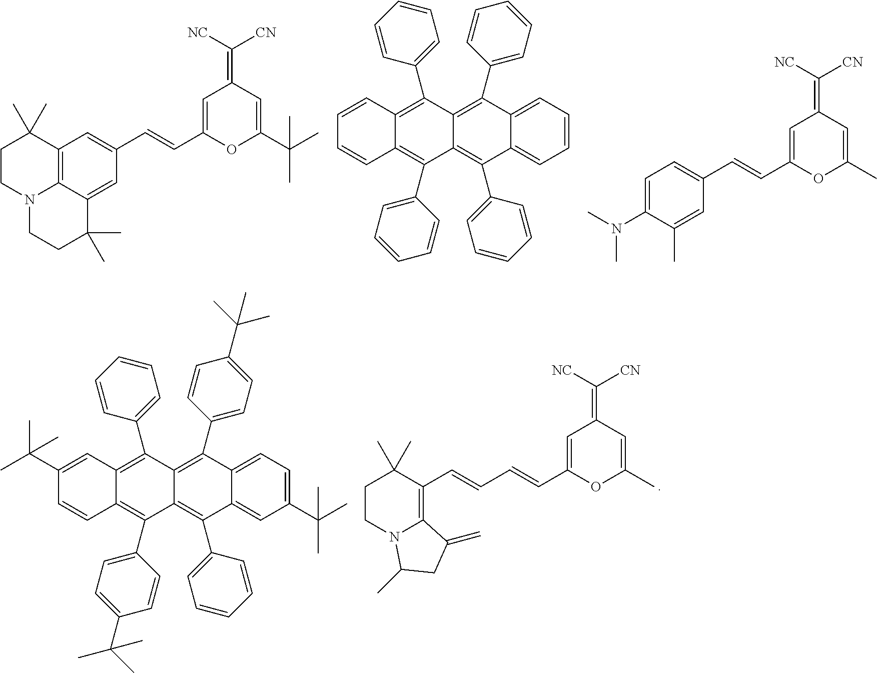

In a further embodiment of the invention, the composition has an emission peak in the visible or nearest ultraviolet range, i.e., in the range of a wavelength of from 310 to 800 nm, in particular between 590 nm and 690 nm, preferably between 610 nm and 665 nm, even more preferably between 620 nm and 640 nm.

### Light-Emitting Layer EML

In one embodiment, the light-emitting layer EML of an organic light-emitting diode of the invention includes (or essentially consists of) a composition including or consisting of:
(i) 1-50% by weight, preferably 5-40% by weight, in particular 10-30% by weight, of one or more organic molecules according to the invention;
(ii) 5-99% by weight, preferably 30-94.9% by weight, in particular 40-89% by weight, of at least one host compound H; and
(iii) optionally 0-94% by weight, preferably 0.1-65% by weight, in particular 1-50% by weight, of at least one further host compound D with a structure differing from the structure of the molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the molecules according to the invention.

Preferably, energy can be transferred from the host compound H to the one or more organic molecules of the invention, in particular transferred from the first excited triplet state T1 (H) of the host compound H to the first excited triplet state T1(E) of the one or more organic molecules according to the invention and/or from the first excited singlet state S1 (H) of the host compound H to the first excited singlet state S1(E) of the one or more organic molecules according to the invention.

In one embodiment, the host compound H has a highest occupied molecular orbital HOMO(H) having an energy E^{HOMO}(H) in the range of from −5 eV to −6.5 eV and one organic molecule according to the invention E has a highest occupied molecular orbital HOMO(E) having an energy E^{HOMO}(E), wherein E^{HOMO}(H)>E^{HOMO}(E).

In a further embodiment, the host compound H has a lowest unoccupied molecular orbital LUMO(H) having an energy E^{LUMO}(H) and the one organic molecule according to the invention E has a lowest unoccupied molecular orbital LUMO(E) having an energy E^{LUMO}(E), wherein E^{LUMO}(H)>E^{LUMO}(E).

### Light-Emitting Layer EML Including at Least One Further Host Compound D

In a further embodiment, the light-emitting layer EML of an organic light-emitting diode of the invention includes (or essentially consists of) a composition including or consisting of:
(i) 1-50% by weight, preferably 5-40% by weight, in particular 10-30% by weight, of one organic molecule according to the invention;
(ii) 5-99% by weight, preferably 30-94.9% by weight, in particular 40-89% by weight, of one host compound H; and
(iii) 0-94% by weight, preferably 0.1-65% by weight, in particular 1-50% by weight, of at least one further host compound D with a structure differing from the structure of the molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the molecules according to the invention.

In one embodiment of the organic light-emitting diode of the invention, the host compound H has a highest occupied molecular orbital HOMO(H) having an energy E^{HOMO}(H) in the range of from −5 eV to −6.5 eV and the at least one further host compound D has a highest occupied molecular orbital HOMO(D) having an energy E^{HOMO}(D), wherein E^{HOMO}(H)>E^{HOMO}(D). The relation E^{HOMO}(H)>E^{HOMO}(D) favors an efficient hole transport.

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D). The relation E^{LUMO}(H)>E^{LUMO}(D) favors an efficient electron transport.

In one embodiment of the organic light-emitting diode of the invention, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D),
the organic molecule E of the invention has a highest occupied molecular orbital HOMO(E) having an energy E^{HOMO}(E) and a lowest unoccupied molecular orbital LUMO(E) having an energy E^{LUMO}(E),
wherein
E^{HOMO}(H)>E^{HOMO}(D) and the difference between the energy level of the highest occupied molecular orbital HOMO(E) of organic molecule according to the invention (E^{HOMO}(E)) and the energy level of the highest occupied molecular orbital HOMO(H) of the host compound H (E^{HOMO}(H)) is between 0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(D) and the difference between the energy level of the lowest unoccupied molecular orbital LUMO(E) of organic molecule according to the invention (E^{LUMO}(E)) and the lowest unoccupied molecular orbital LUMO(D) of the at least one further host compound D (E^{LUMO}(D)) is between −0.5 eV and 0.5 eV, more preferably between −0.3 eV and 0.3 eV, even more preferably between −0.2 eV and 0.2 eV or even between −0.1 eV and 0.1 eV.

### Light-Emitting Layer EML Including at Least One Further Emitter Molecule F

In a further embodiment, the light-emitting layer EML includes (or (essentially) consists of) a composition including or consisting of:
(i) 1-50% by weight, preferably 5-40% by weight, in particular 10-30% by weight, of one organic molecule according to the invention:
(ii) 5-98% by weight, preferably 30-93.9% by weight, in particular 40-88% by weight, of one host compound H;
(iii) 1-30% by weight, in particular 1-20% by weight, preferably 1-5% by weight, of at least one further emitter molecule F with a structure differing from the structure of the molecules according to the invention; and
(iv) optionally 0-94% by weight, preferably 0.1-65% by weight, in particular 1-50% by weight, of at least one further host compound D with a structure differing from the structure of the molecules according to the invention; and
(v) optionally 0-94% by weight, preferably 0-65% by weight, in particular 0-50% by weight, of a solvent.

In a further embodiment, the light-emitting layer EML includes (or (essentially) consists of) a composition as described in Compositions with at least one further emitter, with the at least one further emitter molecule F as defined in Composition wherein the at least one further emitter molecule F is a green fluorescence emitter.

In a further embodiment, the light-emitting layer EML includes (or (essentially) consists of) a composition as described in Compositions with at least one further emitter, with the at least one further emitter molecule F as defined in Composition wherein the at least one further emitter molecule F is a red fluorescence emitter.

In one embodiment of the light-emitting layer EML including at least one further emitter molecule F, energy can be transferred from the one or more organic molecules of the invention E to the at least one further emitter molecule F, in particular transferred from the first excited singlet state S1(E) of one or more organic molecules of the invention E to the first excited singlet state S1(F) of the at least one further emitter molecule F.

In one embodiment, the first excited singlet state S1(H) of one host compound H of the light-emitting layer is higher in energy than the first excited singlet state S1(E) of the one or more organic molecules of the invention E: S1(H)>S1(E), and the first excited singlet state S1(H) of one host compound H is higher in energy than the first excited singlet state S1(F) of the at least one emitter molecule F: S1(H)>S1(F).

In one embodiment, the first excited triplet state T1(H) of one host compound H is higher in energy than the first excited triplet state T1 (E) of the one or more organic molecules of the invention E: T1 (H)>T1 (E), and the first excited triplet state T1 (H) of one host compound H is higher in energy than the first excited triplet state T1 (F) of the at least one emitter molecule F: T1(H)>T1(F).

In one embodiment, the first excited singlet state S1(E) of the one or more organic molecules of the invention E is higher in energy than the first excited singlet state S1(F) of the at least one emitter molecule F: S1(E)>S1(F).

In one embodiment, the first excited triplet state T1(E) of the one or more organic molecules E of the invention is higher in energy than the first excited singlet state T1(F) of the at least one emitter molecule F: T1(E)>T1(F).

In one embodiment, the first excited triplet state T1(E) of the one or more organic molecules E of the invention is higher in energy than the first excited singlet state T1(F) of the at least one emitter molecule F: T1(E)>T1(F), wherein the absolute value of the energy difference between T1(E) and T1 (F) is larger than 0.3 eV, preferably larger than 0.4 eV, or even larger than 0.5 eV.

In one embodiment, the host compound H has a highest occupied molecular orbital HOMO(H) having an energy E^{HOMO}(H) in the range of from −5 to −6.5 eV and the at least one further host compound D has a highest occupied molecular orbital HOMO(D) having an energy E^{HOMO}(D), wherein E^{HOMO}(H)>E^{HOMO}(D).

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D).

In one embodiment, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D),
the organic molecule according to the invention E has a highest occupied molecular orbital HOMO(E) having an energy E^{HOMO}(E) and a lowest unoccupied molecular orbital LUMO(E) having an energy E^{LUMO}(E),
wherein
E^{HOMO}(H)>E^{HOMO}(D) and the difference between the energy level of the highest occupied molecular orbital HOMO(E) of the organic molecule according to the invention E (E^{HOMO}(E)) and the energy level of the highest occupied molecular orbital HOMO(H) of the host compound H (E^{HOMO}(H)) is between −0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(D) and the difference between the energy level of the lowest unoccupied molecular orbital LUMO(E) of the organic molecule according to the invention E (E^{LUMO}(E)) and the lowest unoccupied molecular orbital LUMO(D) of the at least one further host compound D (E^{LUMO}(D)) is between −0.5 eV and 0.5 eV, more preferably between −0.3 eV and 0.3 eV, even more preferably between −0.2 eV and 0.2 eV or even between −0.1 eV and 0.1 eV.

In one embodiment of the invention the host compound D and/or the host compound H is a thermally-activated delayed fluorescence (TADF)-material. TADF materials exhibit a ΔE_{ST} value, which corresponds to the energy difference between the first excited singlet state (S1) and the first excited triplet state (T1), of less than 2500 cm⁻¹. Preferably the TADF material exhibits a ΔE_{ST} value of less than 3000 cm⁻¹, more preferably less than 1500 cm⁻¹, even more preferably less than 1000 cm⁻¹ or even less than 500 cm⁻¹.

In one embodiment, the host compound D is a TADF material and the host compound H exhibits a ΔE_{ST} value of more than 2500 cm⁻¹. In a particular embodiment, the host compound D is a TADF material and the host compound H is selected from group consisting of CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole.

In one embodiment, the host compound H is a TADF material and the host compound D exhibits a ΔE_{ST} value of more than 2500 cm⁻¹. In a particular embodiment, the host compound H is a TADF material and the host compound D is selected from group consisting of T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine).

In a further aspect, the invention relates to an optoelectronic device including an organic molecule or a composition of the type described here, more particularly in the form of a device selected from the group consisting of organic light-emitting diode (OLED), light-emitting electrochemical cell, OLED sensor, more particularly gas and vapour sensors not hermetically externally shielded, organic diode, organic solar cell, organic transistor, organic field-effect transistor, organic laser and down-conversion element.

In a preferred embodiment, the optoelectronic device is a device selected from the group consisting of an organic light emitting diode (OLED), a light emitting electrochemical cell (LEC), and a light-emitting transistor.

In one embodiment of the optoelectronic device of the invention, the organic molecule according to the invention E is used as emission material in a light-emitting layer EML.

In one embodiment of the optoelectronic device of the invention, the light-emitting layer EML consists of the composition according to the invention described here.

When the optoelectronic device is an OLED, it may, for example, have the following layer structure:
1. substrate
2. anode layer A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer,
wherein the OLED includes each layer selected from the group of HIL, HTL, EBL, HBL, ETL, and EIL only optionally, different layers may be merged and the OLED may include more than one layer of each layer type defined above.

Furthermore, the optoelectronic device may, in one embodiment, include one or more protective layers protecting the device from damaging exposure to harmful species in the environment including, for example, moisture, vapor and/or gases.

In one embodiment of the invention, the optoelectronic device is an OLED, with the following inverted layer structure:
1. substrate
2. cathode layer
3. electron injection layer, EIL
4. electron transport layer, ETL
5. hole blocking layer, HBL
6. emitting layer, B
7. electron blocking layer, EBL
8. hole transport layer, HTL
9. hole injection layer, HIL
10. anode layer A
wherein the OLED includes each layer selected from the group of HIL, HTL, EBL, HBL, ETL, and EIL only optionally, different layers may be merged and the OLED may include more than one layer of each layer types defined above.

In one embodiment of the invention, the optoelectronic device is an OLED, which may have a stacked architecture. In this architecture, contrary to the typical arrangement in which the OLEDs are placed side by side, the individual units are stacked on top of each other. Blended light may be generated with OLEDs exhibiting a stacked architecture, in particular white light may be generated by stacking blue, green and red OLEDs. Furthermore, the OLED exhibiting a stacked architecture may include a charge generation layer (CGL), which is typically located between two OLED subunits and typically consists of a n-doped and p-doped layer with the n-doped layer of one CGL being typically located closer to the anode layer.

In one embodiment of the invention, the optoelectronic device is an OLED, which includes two or more emission layers between anode and cathode. In particular, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers.

In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver or aluminum films) or plastic films or slides may be used. This may allow for a higher degree of flexibility. The anode layer A is mostly composed of materials allowing to obtain an (essentially) transparent film. As at least one of both electrodes should be (essentially) transparent in order to allow light emission from the OLED, either the anode layer A or the cathode layer C is transparent. Preferably, the anode layer A includes a large content or even consists of transparent conductive oxides (TCOs). Such anode layer A may, for example, include indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrole and/or doped polythiophene.

The anode layer A (essentially) may consist of indium tin oxide (ITO) (e.g., (In₂O₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC or CuI, in particular a mixture of PEDOT and PSS. The hole injection layer (HIL) may also prevent the diffusion of metals from the anode layer A into the hole transport layer (HTL). The HIL may, for example, include PEDOT:PSS (poly-3,4-ethylenedioxy thiophene: polystyrene sulfonate), PEDOT (poly-3,4-ethylenedioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-bis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to the anode layer A or hole injection layer (HIL), a hole transport layer (HTL) is typically located. Herein, any hole transport compound may be used. For example, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). Preferably, hole transport compounds bear comparably high energy levels of their triplet states T1. For example, the hole transport layer (HTL) may include a star-shaped heterocycle such as tris(4-carbazol-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide or tungsten oxide may, for example, be used as inorganic dopant. Tetrafluorotetracyanoquinodimethane (F₄-TCNQ), copper-pentafluorobenzoate (Cu(I)pFBz) or transition metal complexes may, for example, be used as organic dopant.

The EBL may, for example, include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-Butylphenyl)-3,6-bis(triphenylsilyl)-9H-carbazole), and/or DCB (N,N′-dicarbazolyl-1,4-dimethylbenzene).

Adjacent to the hole transport layer (HTL), the light-emitting layer EML is typically located. The light-emitting layer EML includes at least one light emitting molecule. Particularly, the EML includes at least one light emitting molecule according to the invention E. In one embodiment, the light-emitting layer includes only the organic molecules according to the invention. Typically, the EML additionally includes one or more host materials H. For example, the host material H is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material H typically should be selected to exhibit first triplet (T1) and first singlet (S1) energy levels, which are energetically higher than the first triplet (T1) and first singlet (S1) energy levels of the organic molecule.

Alternatively, the EML additionally includes one or more host materials H, wherein the host is a triplet-triplet annihilation (TTA) material. A TTA material may convert energy from first excited triplet states T1 to first excited singlet state S1 by triplet-triplet annihilation. A TTA material should be selected that twice the energy of the lowermost excited triplet state energy level T1 of the TTA material is larger than the energy of the lowermost excited singlet state energy level of the light emitting molecule according to the invention, i.e., 2T1(TTA material)>S1 (light emitting molecule according to the invention).

In one embodiment of the invention, the EML includes a so-called mixed-host system with at least one hole-dominant host and one electron-dominant host. In a particular embodiment, the EML includes exactly one light emitting organic molecule according to the invention and a mixed-host system including T2T as electron-dominant host and a host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as hole-dominant host. In a further embodiment the EML includes 50-80% by weight, preferably 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, preferably 15-30% by weight of T2T and 5-40% by weight, preferably 10-30% by weight of light emitting molecule according to the invention.

Adjacent to the light-emitting layer EML, an electron transport layer (ETL) may be located. Herein, any electron transporter may be used. Exemplarily, electron-poor compounds such as, e.g., benzimidazoles, pyridines, triazoles, oxadiazoles (e.g., 1,3,4-oxadiazole), phosphine oxides and sulfone, may be used. An electron transporter may also be a star-shaped heterocycle such as 1,3,5-tri(1-phenyl-1H-benzo[d]imidazol-2-yl)phenyl (TPBi). The ETL may include NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphine oxide), BPyTP2 (2,7-di(2,2′-bipyridin-5-yl)triphenylene), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced.

The HBL may, for example, include BCP (2,9-dimethyl-4,7-diphenyl-1,10-phenanthroline=Bathocuproine), BAlq (bis(8-hydroxy-2-methylquinoline)-(4-phenylphenoxy)aluminum), NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphine oxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzene/1,3,5-tris(carbazol-9-yl) benzene).

Adjacent to the electron transport layer (ETL), a cathode layer C may be located. The cathode layer C may, for example, include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) intransparent metals such as Mg, Ca or Al. Alternatively or additionally, the cathode layer C may also include graphite and or carbon nanotubes (CNTs). Alternatively, the cathode layer C may also consist of nanoscale silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, the electron transport layer (ETL) and/or a hole blocking layer (HBL) may also include one or more host compounds H.

In order to modify the emission spectrum and/or the absorption spectrum of the light-emitting layer EML further, the light-emitting layer EML may further include one or more further emitter molecules F. Such an emitter molecule F may be any emitter molecule known in the art. Preferably such an emitter molecule F is a molecule with a structure differing from the structure of the molecules according to the invention E. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. Exemplarily, the triplet and/or singlet excitons may be transferred from the organic emitter molecule according to the invention to the emitter molecule F before relaxing to the ground state S0 by emitting light typically red-shifted in comparison to the light emitted by an organic molecule. Optionally, the emitter molecule F may also provoke two-photon effects (i.e., the absorption of two photons of half the energy of the absorption maximum).

Optionally, an optoelectronic device (e.g., an OLED) may, for example, be an essentially white optoelectronic device. For example, such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm:
green: wavelength range of >500-560 nm;
yellow wavelength range of >560-580 nm;
orange: wavelength range of >580-620 nm;
red: wavelength range of >620-800 nm.

With respect to emitter molecules, such colors refer to the emission maximum. Therefore, for example, a deep blue emitter has an emission maximum in the range of from >420 to 480 nm, a sky blue emitter has an emission maximum in the range of from >480 to 500 nm, a green emitter has an emission maximum in a range of from >500 to 560 nm, a red emitter has an emission maximum in a range of from >620 to 800 nm.

A deep blue emitter may preferably have an emission maximum of below 480 nm, more preferably below 470 nm, even more preferably below 465 nm or even below 460 nm. It will typically be above 420 nm, preferably above 430 nm, more preferably above 440 nm or even above 450 nm.

Accordingly, a further aspect of the present invention relates to an OLED, which exhibits an external quantum efficiency at 1000 cd/m² of more than 8%, more preferably of more than 10%, more preferably of more than 13%, even more preferably of more than 15% or even more than 20% and/or exhibits an emission maximum between 420 nm and 500 nm, preferably between 430 nm and 490 nm, more preferably between 440 nm and 480 nm, even more preferably between 450 nm and 470 nm and/or exhibits a LT80 value at 500 cd/M² of more than 100 h, preferably more than 200 h, more preferably more than 400 h, even more preferably more than 750 h or even more than 1000 h. Accordingly, a further aspect of the present invention relates to an OLED, whose emission exhibits a CIEy color coordinate of less than 0.45, preferably less than 0.30, more preferably less than 0.20 or even more preferably less than 0.15 or even less than 0.10.

A further aspect of the present invention relates to an OLED, which emits light at a distinct color point. According to the present invention, the OLED emits light with a narrow emission band (small full width at half maximum (FWHM)). In one aspect, the OLED according to the invention emits light with a FWHM of the main emission peak of less than 0.30 eV, preferably less than 0.25 eV, more preferably less than 0.18 eV, even more preferably less than 0.15 eV or even less than 0.12 eV.

A further aspect of the present invention relates to an OLED, which emits light at a distinct color point. According to the present invention, the OLED emits light with a narrow emission band (small full width at half maximum (FWHM)). In one aspect, the OLED according to the invention emits light with a FWHM of the main emission peak of less than 0.30 eV, preferably less than 0.25 eV, more preferably less than 0.18 eV, even more preferably less than 0.15 eV or even less than 0.12 eV with an excited state lifetime of not more than 10 μs, of not more than 8 μs, in particular of not more than 6 μs, more preferably of not more than 5 μs or not more than 4 μs, even more preferably of not more than 3 μs or not more than 2 μs.

A further aspect of the present invention relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g., UHD-TVs. Accordingly, a further aspect of the present invention relates to an OLED, whose emission exhibits a CIEx color coordinate of between 0.02 and 0.30, preferably between 0.03 and 0.25, more preferably between 0.05 and 0.20 or even more preferably between 0.08 and 0.18 or even between 0.10 and 0.15 and/or a CIEy color coordinate of between 0.00 and 0.45, preferably between 0.01 and 0.30, more preferably between 0.02 and 0.20 or even more preferably between 0.03 and 0.15 or even between 0.04 and 0.10.

In a further aspect, the invention relates to a method for producing an optoelectronic component. In this case an organic molecule of the invention is used.

The optoelectronic device, in particular the OLED according to the present invention can be fabricated by any means of vapor deposition and/or liquid processing. Accordingly, at least one layer is
prepared by means of a sublimation process,
prepared by means of an organic vapor phase deposition process,
prepared by means of a carrier gas sublimation process,
solution processed or printed.

The methods used to fabricate the optoelectronic device, in particular the OLED according to the present invention are known in the art. The different layers are individually and successively deposited on a suitable substrate by means of subsequent deposition processes. The individual layers may be deposited using the same or differing deposition methods.

Vapor deposition processes, for example, include thermal (co)evaporation, chemical vapor deposition and physical vapor deposition. For active matrix OLED display, an AMOLED backplane is used as substrate. The individual layer may be processed from solutions or dispersions employing adequate solvents. Solution deposition process, for example, include spin coating, dip coating and jet printing. Liquid processing may optionally be carried out in an inert atmosphere (e.g., in a nitrogen atmosphere) and the solvent may be completely or partially removed by means known in the state of the art.

### EXAMPLES

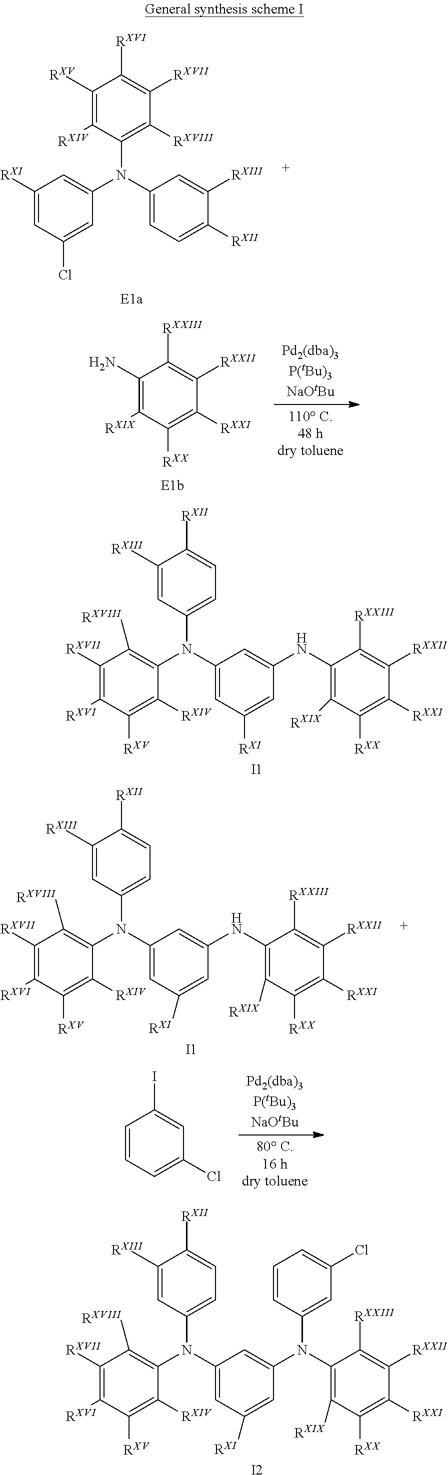

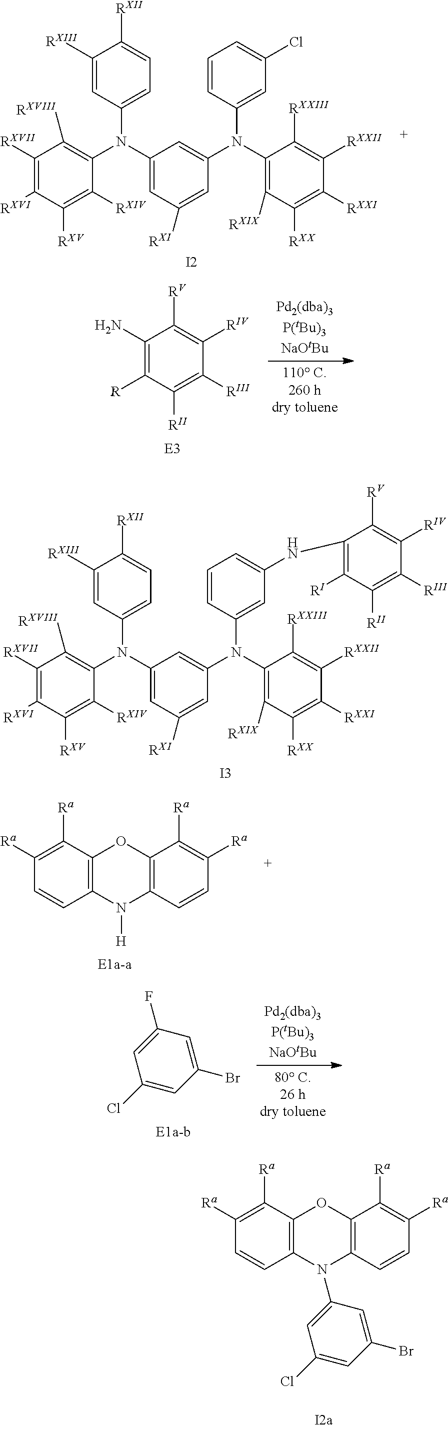

### General Procedure for Synthesis AAV1:

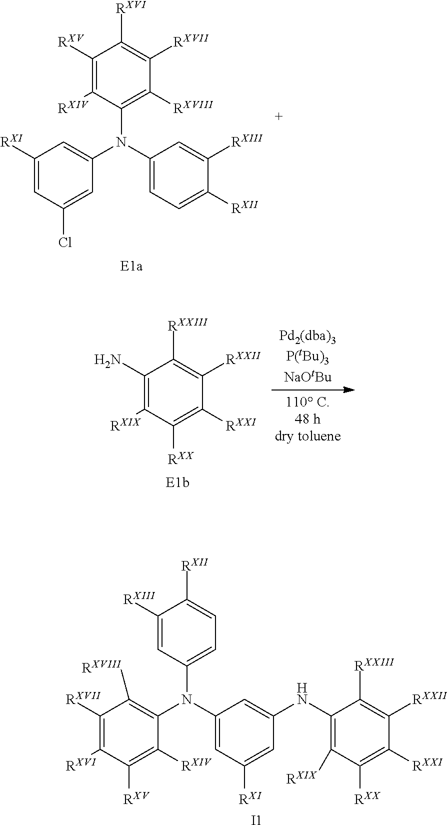

E1a (1.00 equivalents), E1b (1.50 equivalents), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.08 equivalents) and sodium tert-butoxide (NaO^{t}Bu; 3.00 equivalents) are stirred under nitrogen atmosphere in toluene at 110° C. for 48 h. After cooling down to room temperature (rt) the reaction mixture is extracted with ethyl acetate and brine and the phases are separated. The combined organic layers are dried over MgSO₄ and then the solvent is removed under reduced pressure. The crude product obtained is purified by recrystallization or column chromatography and I1 is obtained as solid.

### General Procedure for Synthesis AAV2:

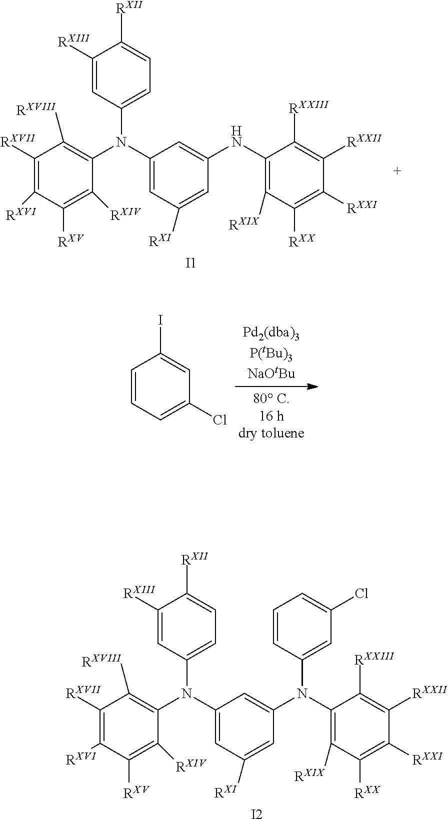

I1 (1.00 equivalents), 3-Chloroiodobenzene (1.20 equivalents; CAS: 625-99-0), tris(dibenzylideneacetone)dipalladium Pd₂(dba)₃ (0.02 equivalents; CAS. 51364-51-3), tri-tert-butyl-phosphine (P(^{t}Bu)₃, CAS: 13716-12-6, 0.08 equivalents) and sodium tert-butoxide (NaO^{t}Bu; 2.00 equivalents) are stirred under nitrogen atmosphere in toluene at 110° C. for 260 h. After cooling down to room temperature (rt) the reaction mixture is extracted with ethyl acetate and brine and the phases are separated. The combined organic layers are dried over MgSO₄ and then the solvent is removed under reduced pressure. The crude product obtained is purified by recrystallization or column chromatography and I2 is obtained as solid.

### General Procedure for Synthesis AAV3:

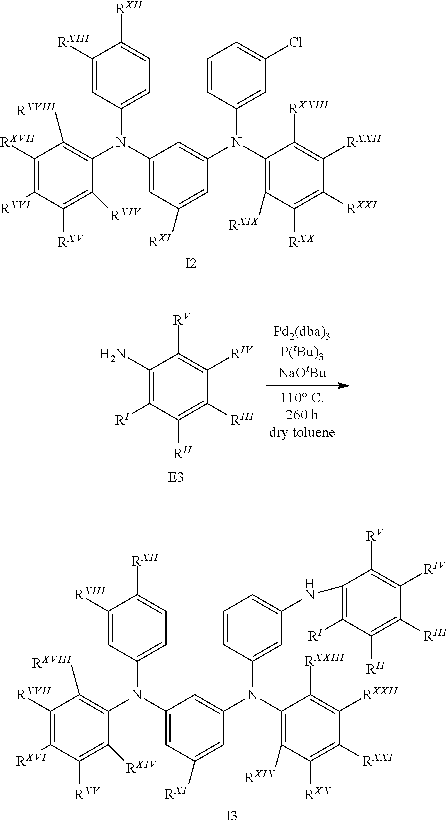

I2 (100 equivalents), E3 (2.00 equivalents), tris(dibenzylideneacetone)dipalladium Pd₂(dba)₃ (0.02 equivalents: GAS: 51364-51-3), tri-tert-butyl-phosphine (P(^{t}Bu)₃, GAS: 13716-12-6, 0.08 equivalents) and sodium tert-butoxide (NaO^{t}Bu; 2.00 equivalents) are stirred under nitrogen atmosphere in toluene at 110° C. for 260 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I3 is obtained as solid.

### General Procedure for Synthesis AAV2a:

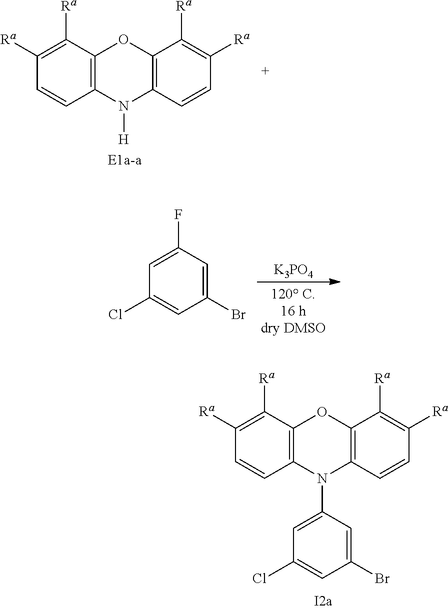

E1a-a (1.00 equivalents), 1-Bromo-3-chloro-5-fluorobenzene (1.20 equivalents; CAS: 33863-76-2) and potassium phosphate tribasic (2.5 equivalents; CAS: 7778-53-2) are stirred under nitrogen atmosphere in dimethylsulfoxide DMSO at 120° C. for 16 h. After cooling down to room temperature (rt) the reaction mixture is poured into water. The precipitate is filtered. The crude product obtained is purified by recrystallization or column chromatography and I2a is obtained as solid.

### General Procedure for Synthesis AAV3a:

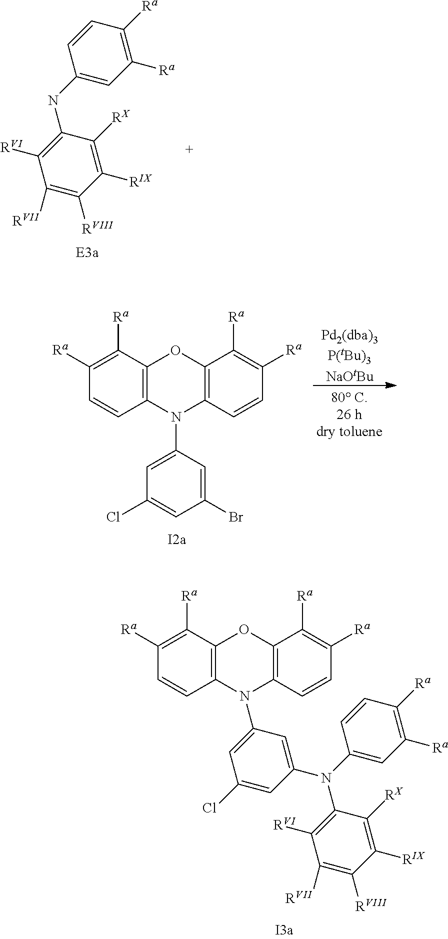

E3a (1.00 equivalents), I2a (1.00 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 5.00 equivalents) are stirred under nitrogen atmosphere in toluene at 80° C. for 26 h. After cooling down to room temperature (rt) the reaction mixture is extracted with ethyl acetate and brine and the phases are separated. The combined organic layers are dried over MgSO₄ and then the solvent is removed under reduced pressure. The crude product obtained is purified by recrystallization or column chromatography and I3a is obtained as solid.

### General Procedure for Synthesis AAV4:

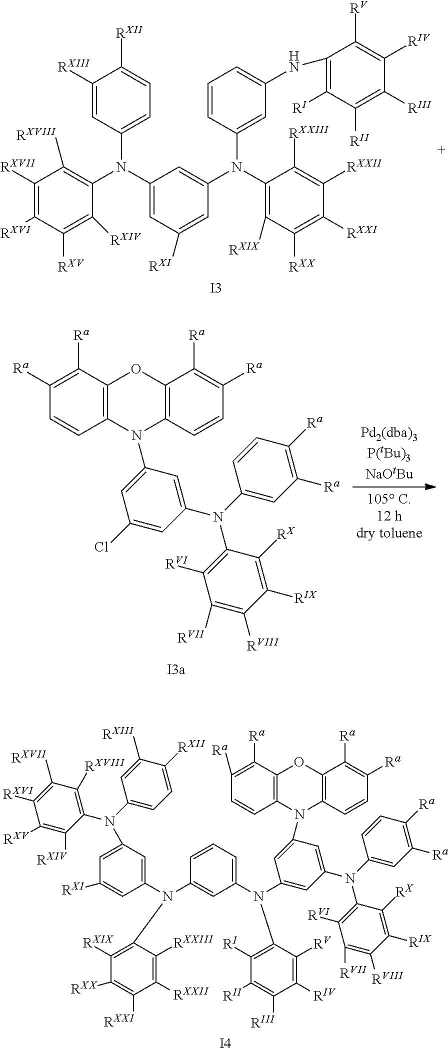

I3 (1.00 equivalents), I3a (1.00 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 2.00 equivalents) are stirred under nitrogen atmosphere in toluene at 105° C. for 12 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I4 is obtained as solid.

General procedure for synthesis AAV5:

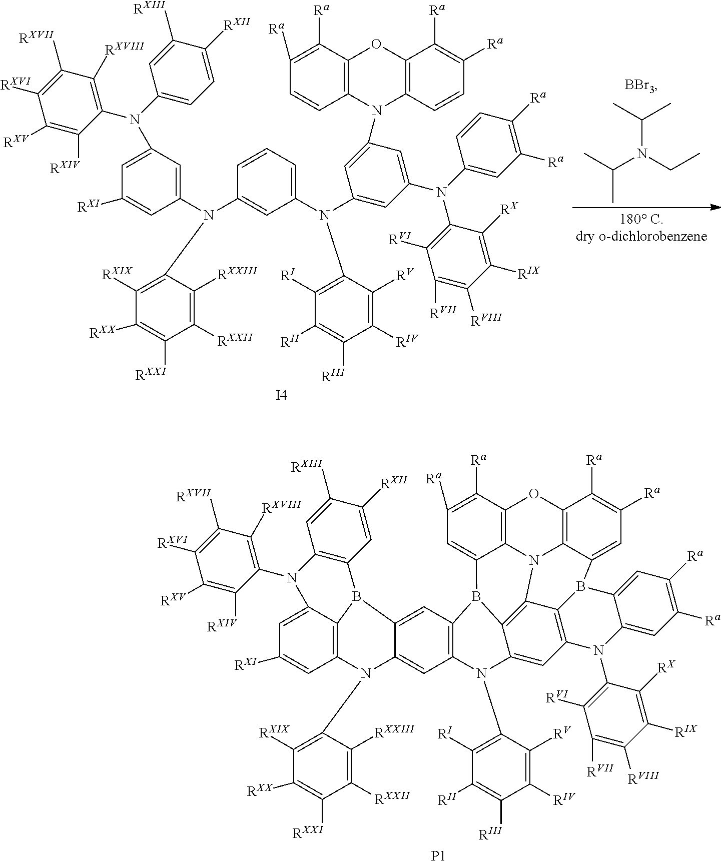

Under nitrogen atmosphere, boron tribromide (CAS 10294-33-4, 6.00 equiv.) is slowly added to a solution of I4 (1.00 equiv.) in o-dichlorobenzene. The reaction mixture is stirred at 180° C. overnight and, upon cooling to room temperature, quenched by the addition of N,N-Diisopropylethylamine (CAS 7087-68-5; 16.0 equivalents). The reaction mixture is extracted with dichloromethane and water and the phases are separated. The combined organic layers are dried over MgSO₄ and then the solvent is removed under reduced pressure. The crude product obtained is purified by recrystallization or column chromatography and P1 is obtained as a solid.

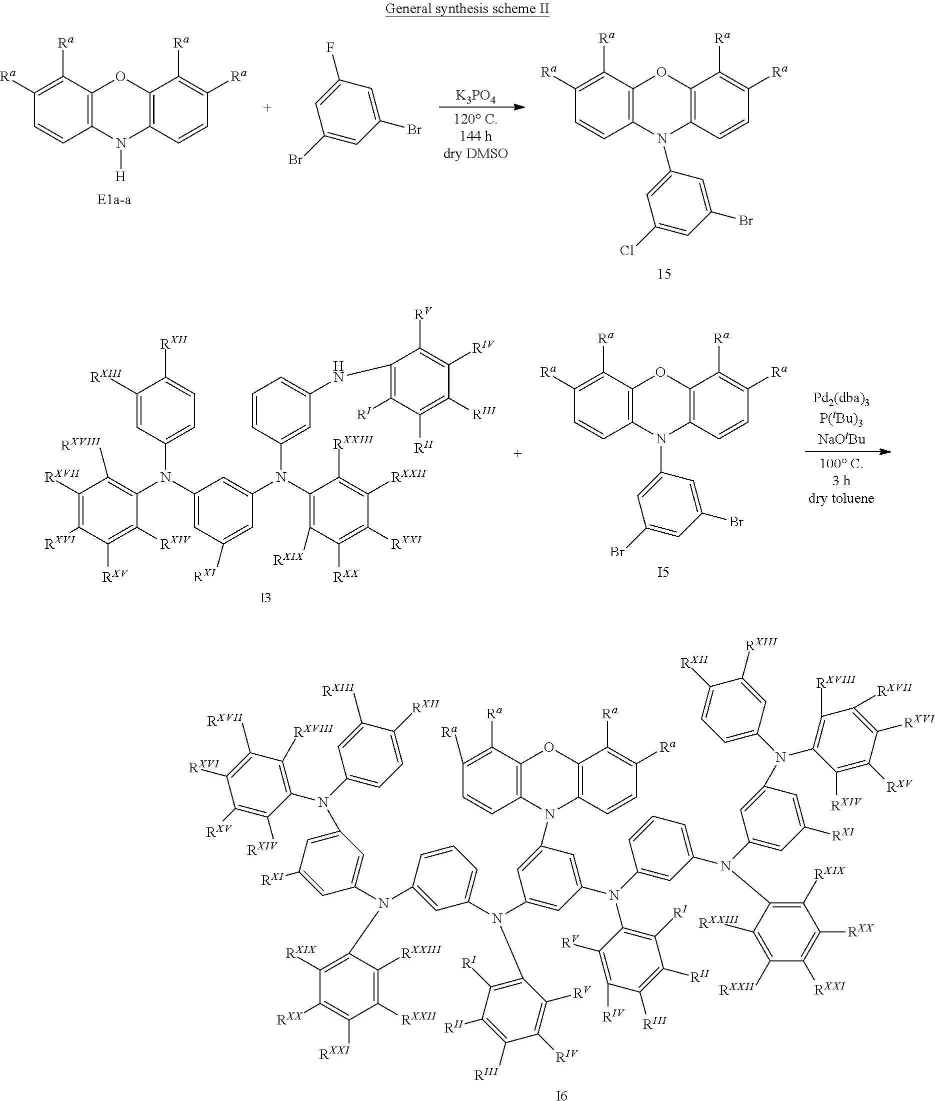

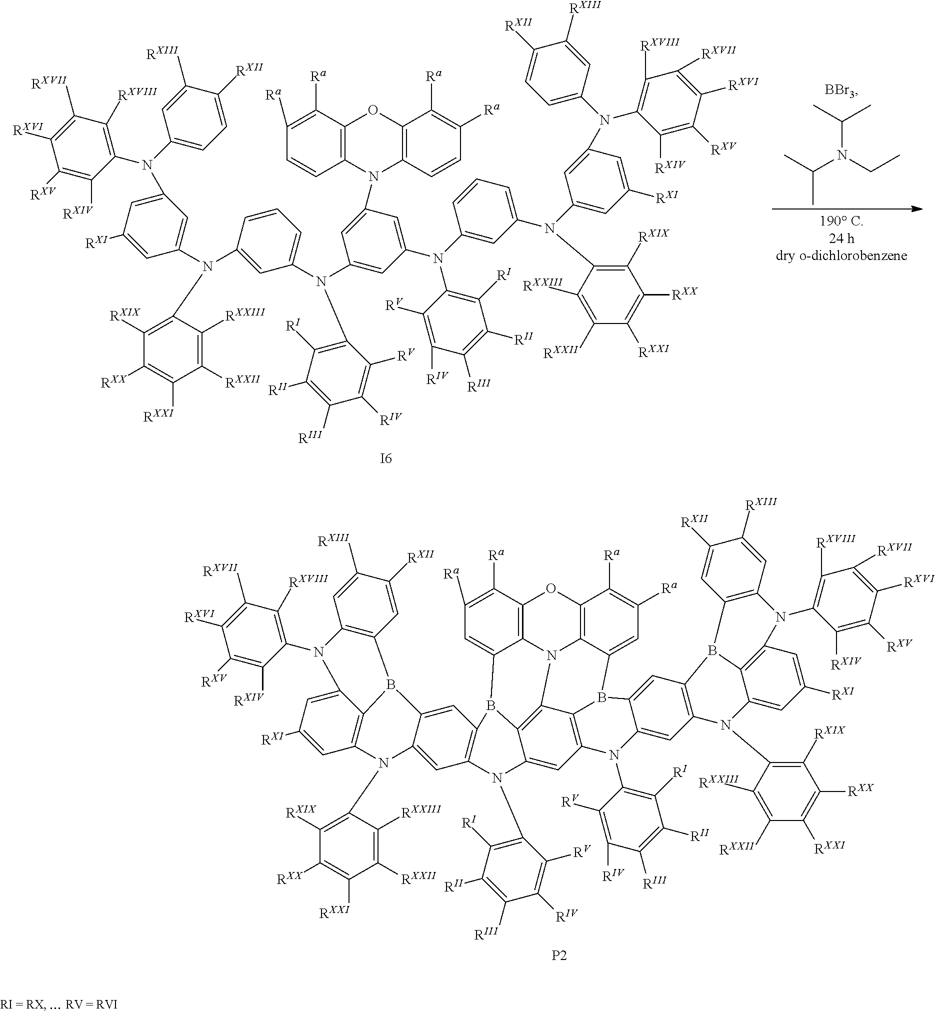

### General Procedure for Synthesis AAV6:

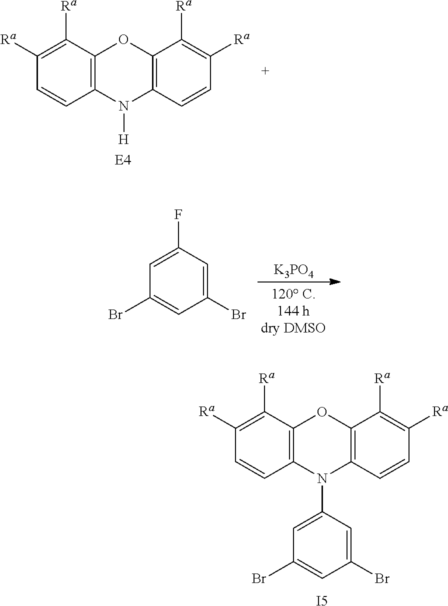

E4 (1.00 equivalents), 1,3-Dibromo-5-fluorobenzene (1.20 equivalents: CAS: 135-67-1) and potassium phosphate tribasic (2.5 equivalents; CAS: 7778-53-2) are stirred under nitrogen atmosphere in dimethylsulfoxide DMO at 120° C. for 144 h. After cooling down to room temperature (rt) the reaction mixture is poured into water. The precipitate is filtered. The crude product obtained is purified by recrystallization or column chromatography and I5 is obtained as solid.

### General Procedure for Synthesis AAV7:

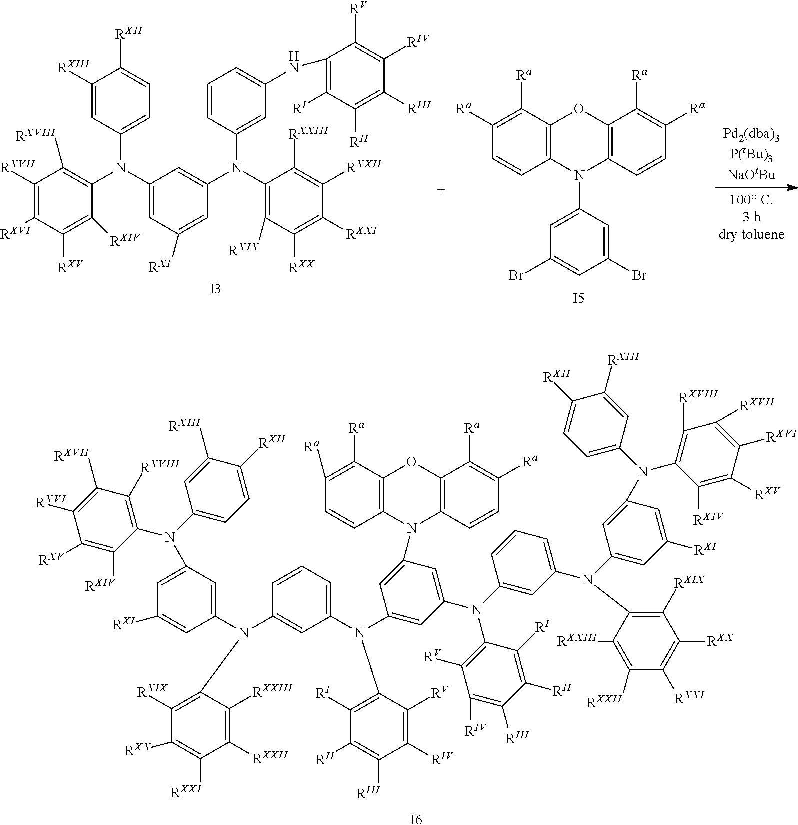

I3 (2.00 equivalents), I5 (1.00 equivalents), tris(dibenzylideneacetone)dipalladium Pd₂(dba)₃ (0.01 equivalents; CAS: 51364-51-3), tri-tert-butyl-phosphine (P(^{t}Bu)₃, CAS 13716-12-6, 0.04 equivalents) and sodium tert-butoxide (NaO^{t}Bu; 5.00 equivalents) are stirred under nitrogen atmosphere in toluene at 100° C. for 3 h. After cooling down to room temperature (rt) the reaction mixture is extracted with ethyl acetate and brine and the phases are separated. The combined organic layers are dried over MgSO₄ and then the solvent is removed under reduced pressure. The crude product obtained is purified by recrystallization or column chromatography and I6 is obtained as solid.

### General Procedure for Synthesis AAV8:

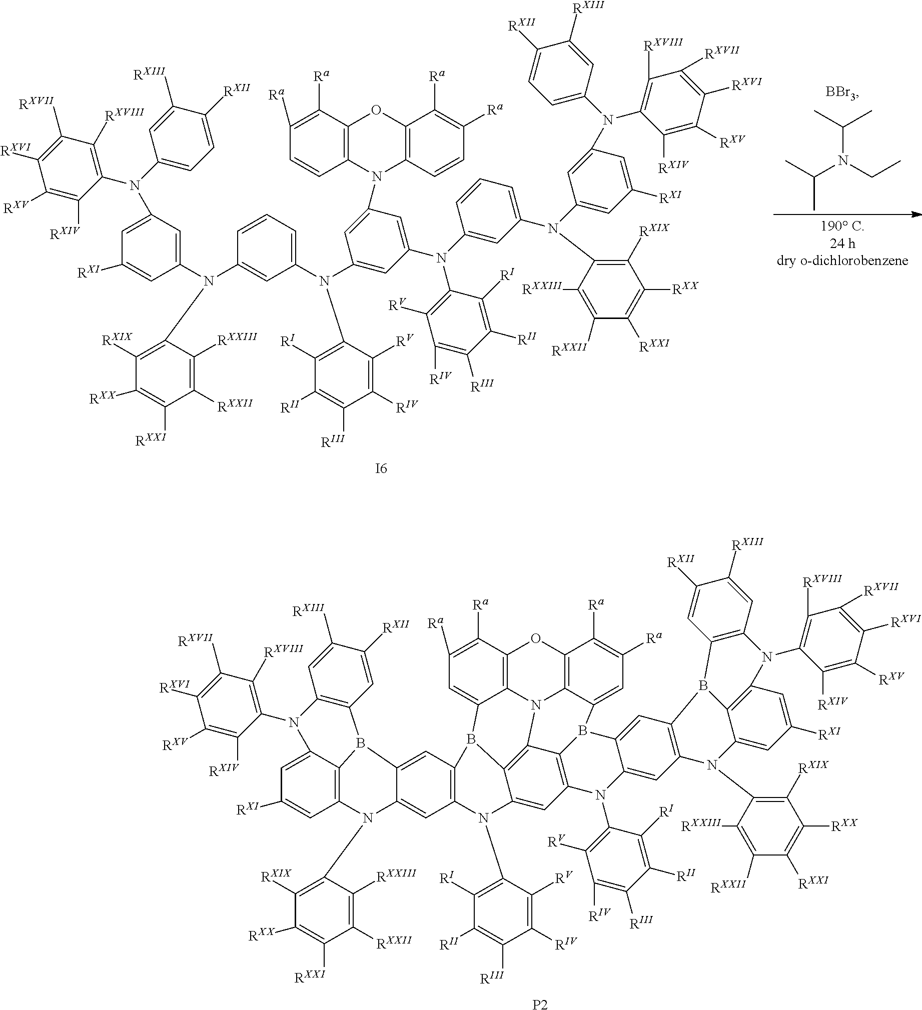

Under nitrogen atmosphere, boron tribromide (CAS 10294-33-4, 8.00 equiv.) is slowly added to a solution of I6 (1.00 equiv.) in o-dichlorobenzene. The reaction mixture is stirred at 190° C. for 24 h and, upon cooling to room temperature, quenched by the addition of N,N-Diisopropylethylamine (CAS 7087-68-5; 16.0 equivalents). The reaction mixture is extracted with dichloromethane and water and the phases are separated. The combined organic layers are dried over MgSO₄ and then the solvent is removed under reduced pressure. The crude product obtained is purified by recrystallization or column chromatography and P2 is obtained as a solid.

### Cyclic Voltammetry

Cyclic voltammograms are measured from solutions having concentration of 10³ mol/L of the organic molecules in dichloromethane or a suitable solvent and a suitable supporting electrolyte (e.g., 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures are optimized employing the BP86 functional and the resolution of identity approach (RI). Excitation energies are calculated using the (BP86) optimized structures employing Time-Dependent DFT (TD-DFT) methods. Orbital and excited state energies are calculated with the B3LYP functional. Def2-SVP basis sets (and a m4-grid for numerical integration are used. The Turbomole program package is used for all calculations.

### Photophysical Measurements

### Sample Pretreatment: Spin-Coating

Apparatus: Spin150, SPS euro.

The sample concentration is 0.2 mg/ml, dissolved in Toluene/DCM a suitable solvent.

Program: 7; 30 sec. at 2000 U/min. After coating, the films are dried at 70° C. for 1 min.

Photoluminescence spectroscopy and TCSPC (Time-correlated single-photon counting)

Steady-state emission spectroscopy is recorded using a Horiba Scientific, Modell FluoroMax-4 equipped with a 150 W Xenon-Arc lamp, excitation- and emissions monochromators and a Hamamatsu R928 photomultiplier and a time-correlated single-photon counting option. Emissions and excitation spectra are corrected using standard correction fits.

Excited state lifetimes are determined employing the same system using the TCSPC method with FM-2013 equipment and a Horiba Yvon TCSPC hub.

### Excitation Sources:

NanoLED 370 (wavelength: 371 nm, pulse duration: 1.1 ns)
NanoLED 290 (wavelength: 294 nm, pulse duration: <1 ns)
SpectraLED 310 (wavelength: 314 nm)
SpectraLED 355 (wavelength: 355 nm).

Data analysis (exponential fit) was done using the software suite DataStation and DAS6 analysis software. The fit is specified using the chi-squared-test.

Time-Resolved PL Spectroscopy in the μs-Range and ns-Range (FS5)

Time-resolved PL measurements were performed on a FS5 fluorescence spectrometer from Edinburgh Instruments. Compared to measurements on the HORIBA setup, better light gathering allows for an optimized signal to noise ratio, which favors the FS5 system especially for transient PL measurements of delayed fluorescence characteristics. The continuous light source is a 150W xenon arc lamp, selected wavelengths are chosen by a Czerny-Turner monochromator, which is also used to set specific emission wavelengths. The sample emission is directed towards a sensitive R928P photomultiplier tube (PMT), allowing the detection of single photons with a peak quantum efficiency of up to 25% in the spectral range between 200 nm to 870 nm. The detector is a temperature stabilized PMT, providing dark counts below 300 cps (counts per second). Finally, to determine the transient decay lifetime of the delayed fluorescence, a tail fit using three exponential functions is applied. By weighting the specific lifetimes τᵢ with their corresponding amplitudes Aᵢ,

$${τ}_{DF} = {\sum }_{i = 1}^{3} \frac{{A}_{i} {τ}_{i}}{{A}_{i}}$$

the delayed fluorescence lifetime τ_{DF} is determined.

### Photoluminescence Quantum Yield Measurements

For photoluminescence quantum yield (PLQY) measurements an Absolute PL Quantum Yield Measurement C9920-03G system (Hamamatsu Photonics) is used.

Quantum yields and CIE coordinates are determined using the software U6039-05 version 3.6.0.

Emission maxima are given in nm, quantum yields ϕ in % and CIE coordinates as x,y values.

### PLQY is Determined Using the Following Protocol:

Quality assurance: Anthracene in ethanol (known concentration) is used as

### REFERENCE

Excitation wavelength: the absorption maximum of the organic molecule is determined and the molecule is excited using this wavelength

Measurement

Quantum yields are measured for sample of films (2% by weight of the emitter in PMMA) under nitrogen atmosphere. The yield is calculated using the equation:

$${Φ}_{PL} = \frac{{n}_{photon} , emitted}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ} ,$$

wherein nₚₕₒₜₒₙ denotes the photon count and Int. the intensity.

Production and Characterization of Optoelectronic Devices

Optoelectronic devices, such as OLED devices, including organic molecules according to the invention can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The (not fully optimized) OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements are performed (e.g., applying increased current densities). Exemplarily LT80 values at 500 cd/M² are determined using the following equation:

$$LT 80 ( 500 \frac{cd}{{m}^{2}} ) = LT 80 ( {L}_{0} ) {( \frac{{L}_{0}}{500 \frac{cd}{{m}^{2}}} )}^{1.6}$$

wherein L₀ denotes the initial luminance at the applied current density.

The values correspond to the average of several pixels (typically two to eight), the standard deviation between these pixels is given.

### HPLC-MS

HPLC-MS analysis is performed on an HPLC by Agilent (1260 series) with MS-detector (Thermo LTQ XL).

For example, a typical HPLC method is as follows: a reverse phase column 3.0 mm×100 mm, particle size 2.7 μm from Agilent (Poroshell 120EC-C18, 3.0×100 mm, 2.7 μm HPLC column) is used in the HPLC. The HPLC-MS measurements are performed at room temperature (rt) following gradients

| Flow rate [ml/min] | Time [min] | A[%] | B[%] | C[%] |
|---|---|---|---|---|
| 1.5 | 30 | 40 | 40 | 30 |
| 1.5 | 45 | 10 | 10 | 80 |
| 1.5 | 50 | 40 | 10 | 80 |
| 1.5 | 51 | 30 | 40 | 30 |
| 1.5 | 55 | 30 | 10 | 30 |

using the following solvent mixtures containing 0.1% formic acid:

| | | |
|---|---|---|
| Solvent A: | H₂O (10%) | MeCN (90%) |
| Solvent B: | H₂O (90%) | MeCN (10%) |
| Solvent C: | THF (50%) | MeCN (50%) |

An injection volume of 2 μL from a solution with a concentration of 0.5 mg/mL of the analyte is taken for the measurements.

Ionization of the probe is performed using an atmospheric pressure chemical ionization (APCI) source either in positive (APCI+) or negative (APCI−) ionization mode or an atmospheric pressure photoionization (APPI) source.

### Example 1

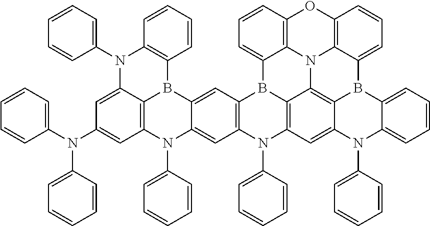 [SMILES: c1ccc(N(c2ccccc2)c2cc3c4c(c2)N(c2ccccc2)c2cc5c(cc2B4c2ccccc2N3c2ccccc2)B2c3cccc4c3N3c6c(cccc6B6c7ccccc7N(c7ccccc7)c7cc(c2c3c76)N5c2ccccc2)O4)cc1]

Example 1 was synthesized according to

AAV (77% yield), wherein 5-Chloro-N1,N1,N3,N3-tetraphenyl-1,3-benzenediamine [1630850-28-0] was used as compound E1a and Aniline [62-53-3]was used as compound E1b; MS (HPLC-MS): m/z (retention time)=504.4 (4.04 min).

AAV2 (80% yield); MS (HPLC-MS): m/z (retention time)=614 (5.1 min).

AAV3 (46% yield), wherein Aniline [62-53-3] was used as compound E3: MS (HPLC-MS): m/z (retention time)=671.6 (4.68 min).

AAV2a (54% yield), wherein Phenoxazine [135-67-1] was used as compound E1a-a; MS (GC-MS): m/z (retention time)=373 (8.6 min).

AAV3a (49% yield), wherein Diphenylamine [122-39-4] was used as compound E3a; MS (GC-MS): m/z (retention time)=460 (11.95 min).

AAV4 (50% yield); MS (HPLC-MS): m/z (retention time)=1096 (7.20 min).

AAV5 (8% yield). MS (HPLC-MS): m/z (retention time)=1120 (8.47 min).

The emission maximum of example 1 (1% by weight in PMMA) is at 475 nm, the full width at half maximum (FWHM) is 0.15 eV (28 nm), the CIE_{X} and CIE_{Y} coordinates are 0.12, and 0.23, respectively, the excited state lifetime is 4.7 μs.

### Example 2

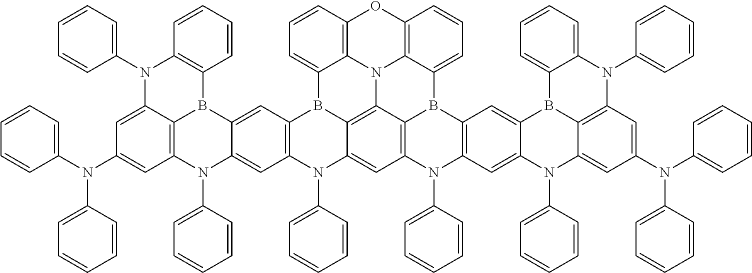 [SMILES: c1ccc(N(c2ccccc2)c2cc3c4c(c2)N(c2ccccc2)c2cc5c(cc2B4c2ccccc2N3c2ccccc2)B2c3cccc4c3N3c6c(cccc6B6c7cc8c(cc7N(c7ccccc7)c7cc(c2c3c76)N5c2ccccc2)N(c2ccccc2)c2cc(N(c3ccccc3)c3ccccc3)cc3c2B8c2ccccc2N3c2ccccc2)O4)cc1]

Example 2 was synthesized according to

AAV1 (77% yield), wherein 5-Chloro-N1,N1,N3,N3-tetraphenyl-1,3-benzenediamine [1630850-28-0] was used as compound E1a and Aniline [62-53-3]was used as compound E1b; MS (HPLC-MS): m/z (retention time)=504.4 (4.05 min).

AAV2 (80% yield); MS (HPLC-MS): m/z (retention time)=615 (5.12 min).

AAV3 (46% yield), wherein Aniline [62-53-3] was used as compound E3; MS (HPLC-MS): m/z (retention time)=671.9 (4.76 min).

AAV6 (25% yield), wherein Phenoxazine [135-67-1] was used as compound E4; MS (GC-MS): m/z (retention time)=417 (9.04 min).

AAV7 (80% yield); MS (HPLC-MS): m/z (retention time)=1598.5 (8.27 min).

AAV8(1% yield). MS (HPLC-MS): m/z (retention time)=1629 (9.32 min).

The emission maximum of example 2 (1% by weight in PMMA) is at 480 nm, the full width at half maximum (FWHM) is 0.13 eV (24 nm), the CIE_{X} and CIE_{Y} coordinates are 0.16, and 0.36, respectively, the excited state lifetime is 1.25 μs.

### Comparative Example C1

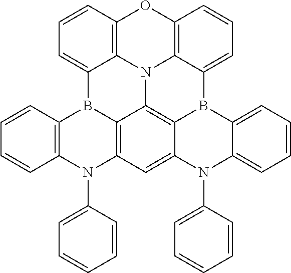 [SMILES: c1ccc(N2c3ccccc3B3c4cccc5c4N4c6c(cccc6B6c7ccccc7N(c7ccccc7)c7cc2c3c4c76)O5)cc1]

The emission maximum of example C₁ (1% by weight in PMMA) is at 452 nm, the full width at half maximum (FWHM) is 0.23 eV (40 nm), the CIE_{X} and CIE_{Y} coordinates are 0.15, and 0.11, respectively, the excited state lifetime is 0.45 ms.

### Additional Examples of Organic Molecules of the Invention

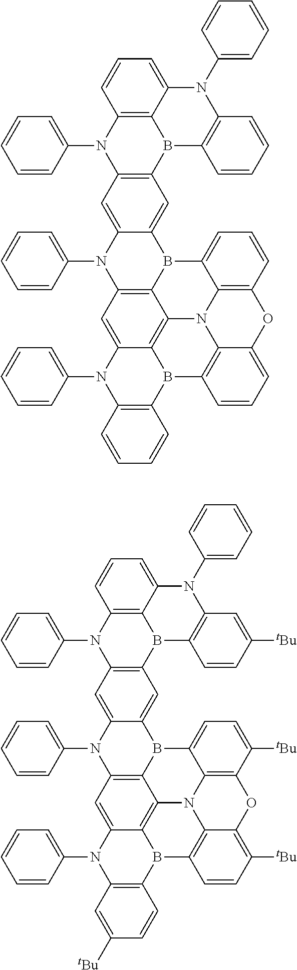 [SMILES: c1ccc(N2c3ccccc3B3c4cc5c(cc4N(c4ccccc4)c4cccc2c43)N(c2ccccc2)c2cc3c4c6c2B5c2cccc5c2N6c2c(cccc2B4c2ccccc2N3c2ccccc2)O5)cc1 ; CC(C)(C)c1ccc2c(c1)N(c1ccccc1)c1cccc3c1B2c1cc2c(cc1N3c1ccccc1)N(c1ccccc1)c1cc3c4c5c1B2c1ccc(C(C)(C)C)c2c1N5c1c(ccc(C(C)(C)C)c1O2)B4c1ccc(C(C)(C)C)cc1N3c1ccccc1]

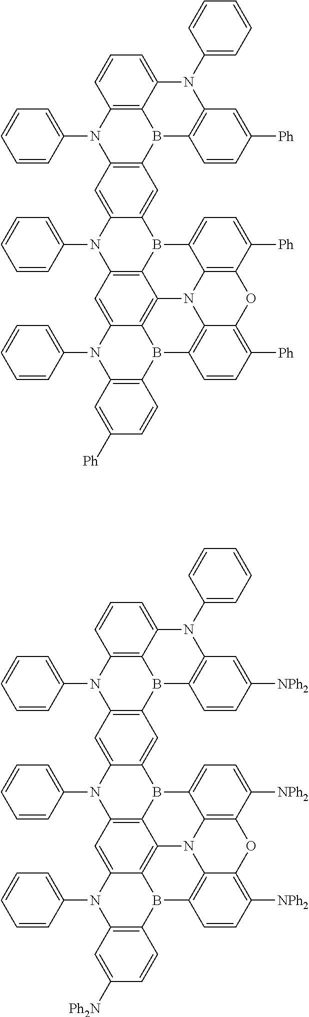

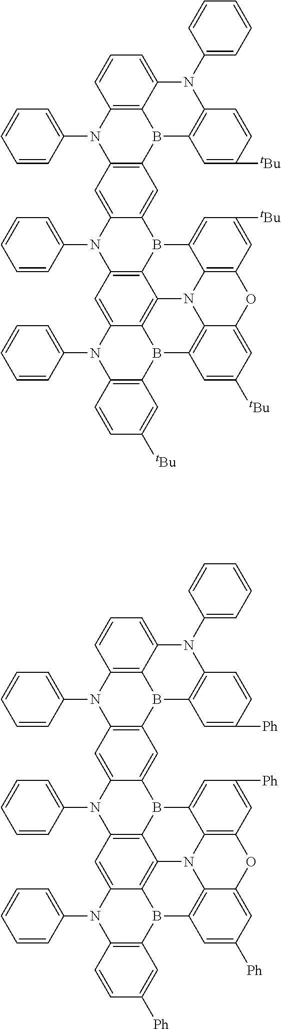 [SMILES: CC(C)(C)c1ccc2c(c1)B1c3cc4c(cc3N(c3ccccc3)c3cccc(c31)N2c1ccccc1)N(c1ccccc1)c1cc2c3c5c1B4c1cc(C(C)(C)C)cc4c1N5c1c(cc(C(C)(C)C)cc1B3c1cc(C(C)(C)C)ccc1N2c1ccccc1)O4 ; c1ccc(-c2ccc3c(c2)B2c4cc5c(cc4N(c4ccccc4)c4cccc(c42)N3c2ccccc2)N(c2ccccc2)c2cc3c4c6c2B5c2cc(-c5ccccc5)cc5c2N6c2c(cc(-c6ccccc6)cc2B4c2cc(-c4ccccc4)ccc2N3c2ccccc2)O5)cc1]

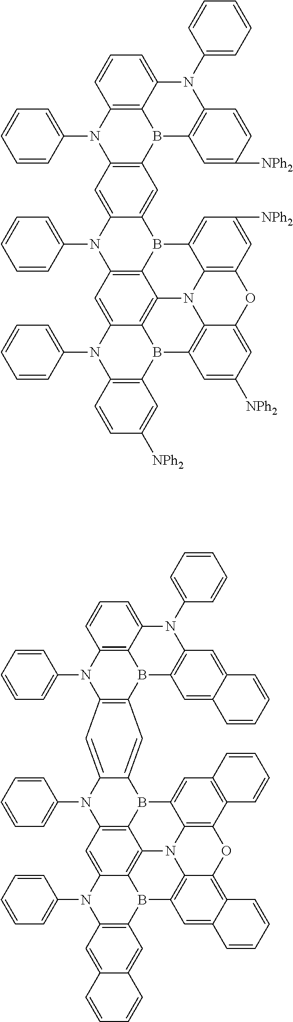

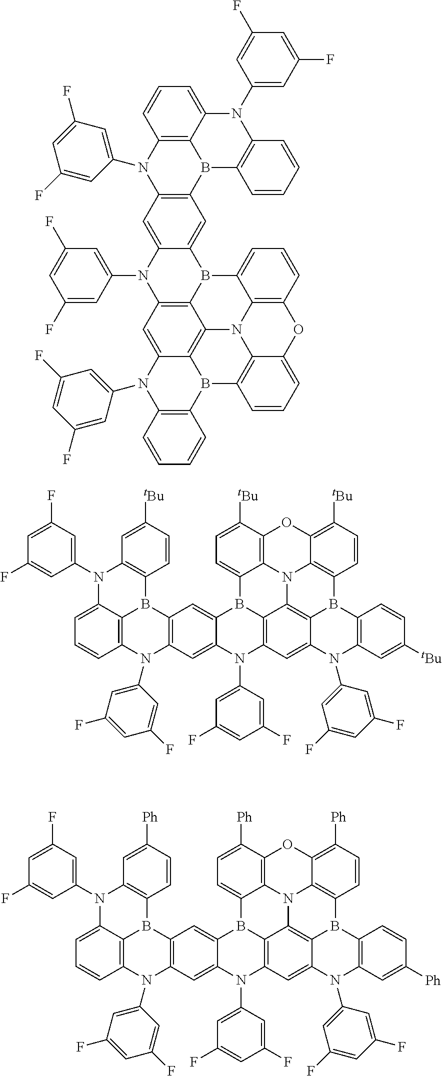

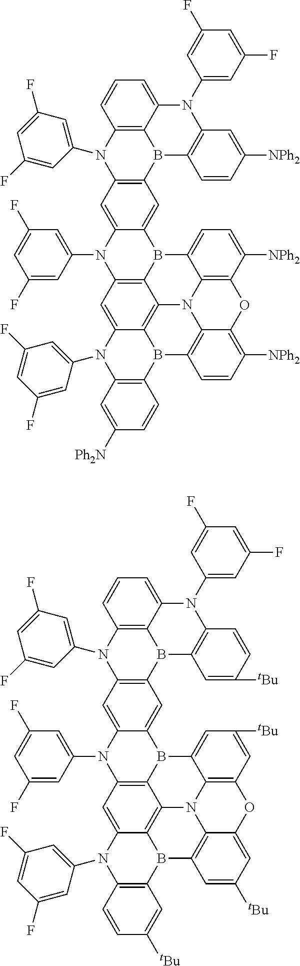

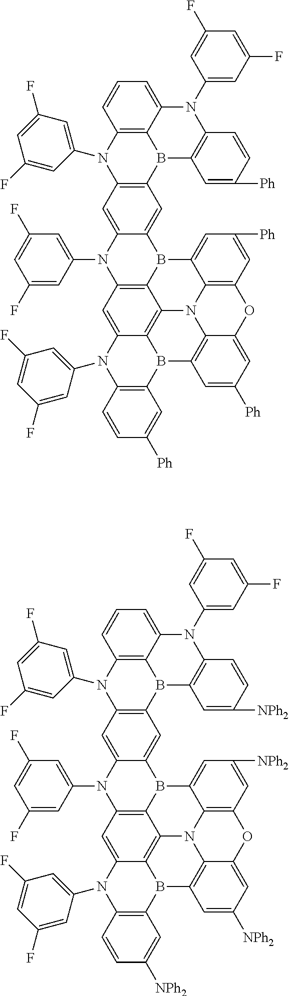

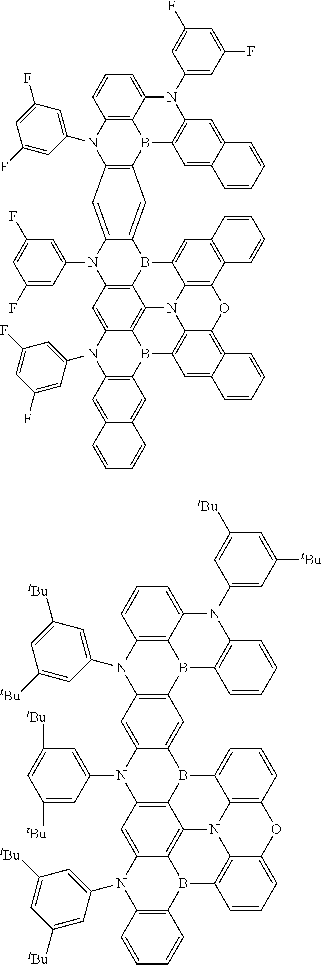 [SMILES: Fc1cc(F)cc(N2c3cc4c(cc3B3c5cc6ccccc6cc5N(c5cc(F)cc(F)c5)c5cccc2c53)B2c3cc5ccccc5c5c3N3c6c2c(cc2c6B(c6cc7ccccc7cc6N2c2cc(F)cc(F)c2)c2cc6ccccc6c(c23)O5)N4c2cc(F)cc(F)c2)c1 ; CC(C)(C)c1cc(N2c3ccccc3B3c4cc5c(cc4N(c4cc(C(C)(C)C)cc(C(C)(C)C)c4)c4cccc2c43)N(c2cc(C(C)(C)C)cc(C(C)(C)C)c2)c2cc3c4c6c2B5c2cccc5c2N6c2c(cccc2B4c2ccccc2N3c2cc(C(C)(C)C)cc(C(C)(C)C)c2)O5)cc(C(C)(C)C)c1]

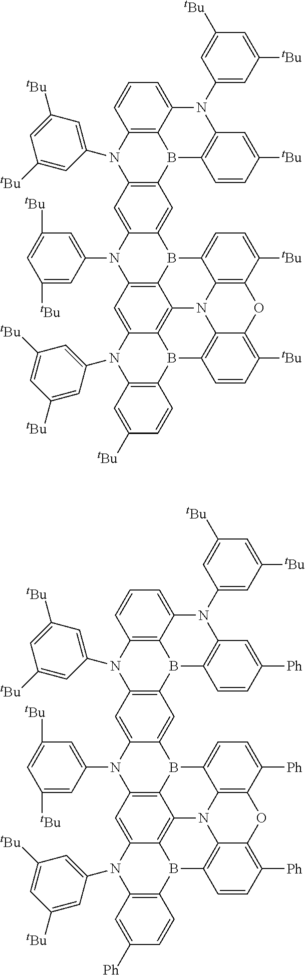 [SMILES: CC(C)(C)c1cc(N2c3cc(C(C)(C)C)ccc3B3c4cc5c(cc4N(c4cc(C(C)(C)C)cc(C(C)(C)C)c4)c4cccc2c43)N(c2cc(C(C)(C)C)cc(C(C)(C)C)c2)c2cc3c4c6c2B5c2ccc(C(C)(C)C)c5c2N6c2c(ccc(C(C)(C)C)c2O5)B4c2ccc(C(C)(C)C)cc2N3c2cc(C(C)(C)C)cc(C(C)(C)C)c2)cc(C(C)(C)C)c1 ; CC(C)(C)c1cc(N2c3cc(-c4ccccc4)ccc3B3c4cc5c(cc4N(c4cc(C(C)(C)C)cc(C(C)(C)C)c4)c4cccc2c43)N(c2cc(C(C)(C)C)cc(C(C)(C)C)c2)c2cc3c4c6c2B5c2ccc(-c5ccccc5)c5c2N6c2c(ccc(-c6ccccc6)c2O5)B4c2ccc(-c4ccccc4)cc2N3c2cc(C(C)(C)C)cc(C(C)(C)C)c2)cc(C(C)(C)C)c1]

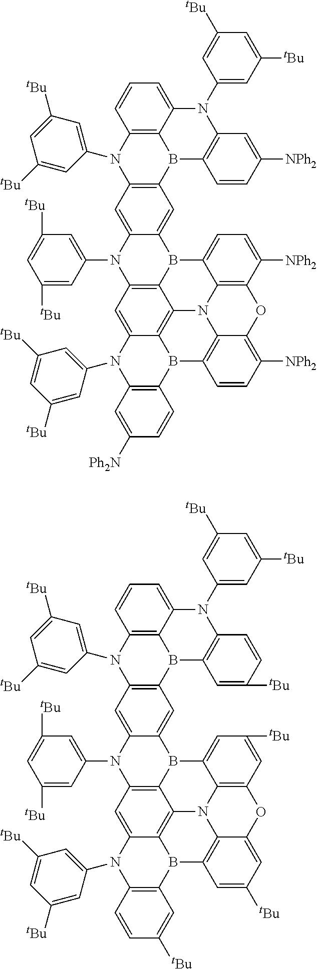

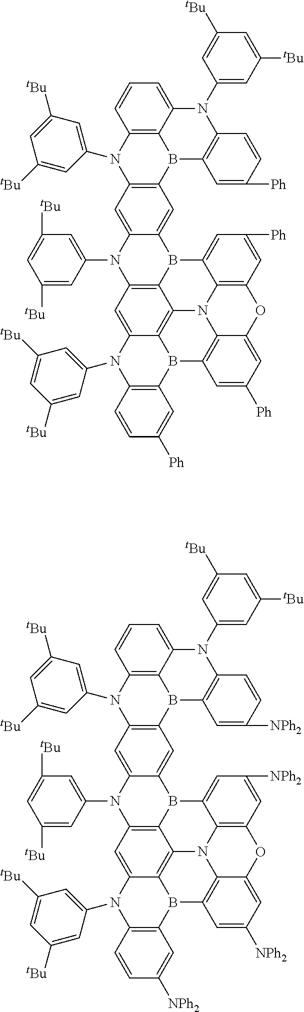

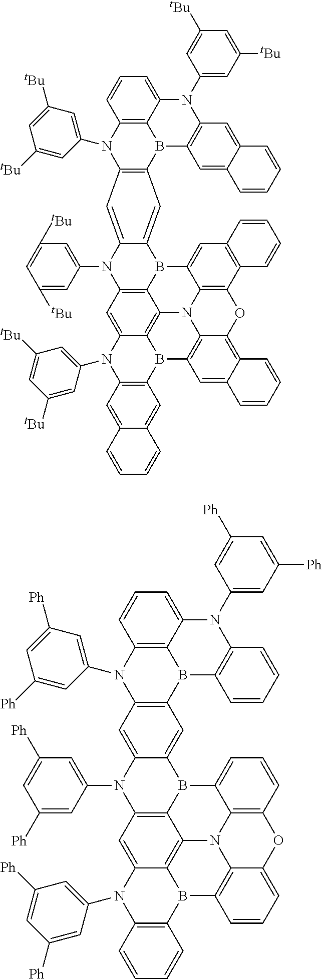 [SMILES: CC(C)(C)c1cc(N2c3cc4c(cc3B3c5cc6ccccc6cc5N(c5cc(C(C)(C)C)cc(C(C)(C)C)c5)c5cccc2c53)B2c3cc5ccccc5c5c3N3c6c2c(cc2c6B(c6cc7ccccc7cc6N2c2cc(C(C)(C)C)cc(C(C)(C)C)c2)c2cc6ccccc6c(c23)O5)N4c2cc(C(C)(C)C)cc(C(C)(C)C)c2)cc(C(C)(C)C)c1 ; c1ccc(-c2cc(-c3ccccc3)cc(N3c4ccccc4B4c5cc6c(cc5N(c5cc(-c7ccccc7)cc(-c7ccccc7)c5)c5cccc3c54)N(c3cc(-c4ccccc4)cc(-c4ccccc4)c3)c3cc4c5c7c3B6c3cccc6c3N7c3c(cccc3B5c3ccccc3N4c3cc(-c4ccccc4)cc(-c4ccccc4)c3)O6)c2)cc1]

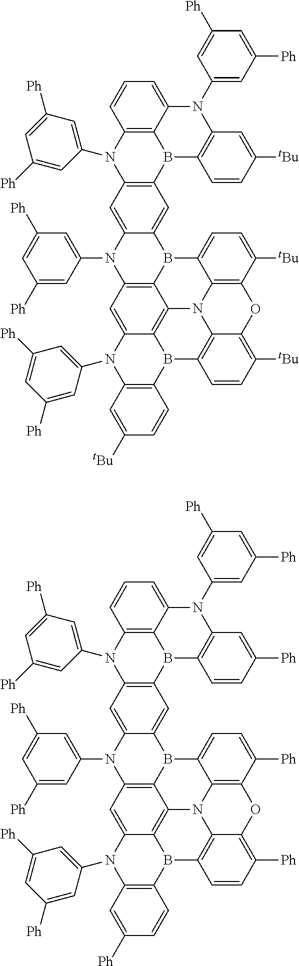

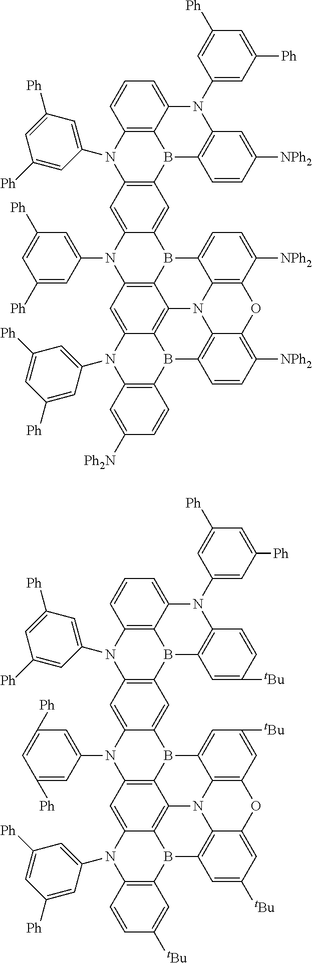

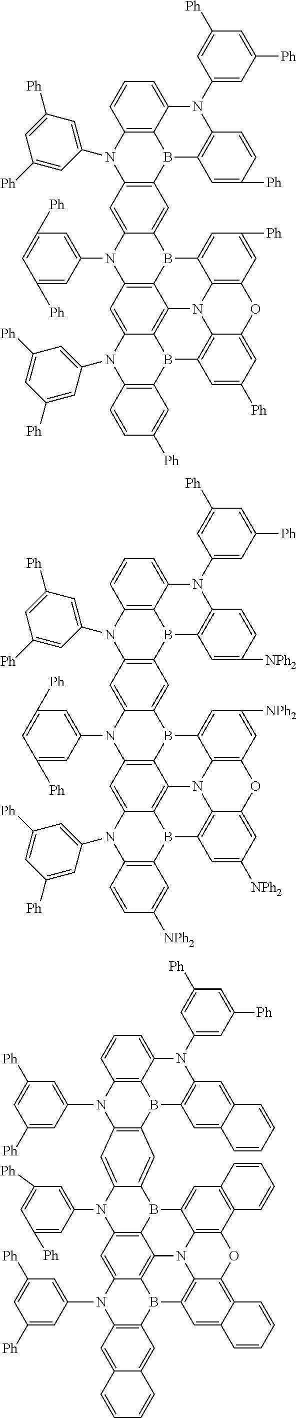

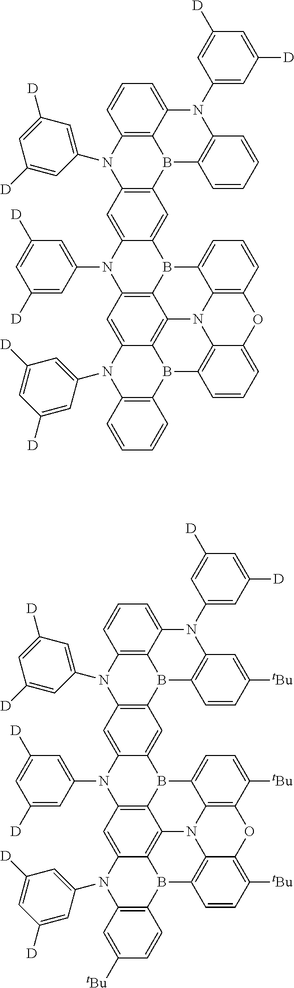 [SMILES: [2H]c1cc([2H])cc(N2c3ccccc3B3c4cc5c(cc4N(c4cc([2H])cc([2H])c4)c4cccc2c43)N(c2cc([2H])cc([2H])c2)c2cc3c4c6c2B5c2cccc5c2N6c2c(cccc2B4c2ccccc2N3c2cc([2H])cc([2H])c2)O5)c1 ; [2H]c1cc([2H])cc(N2c3cc(C(C)(C)C)ccc3B3c4cc5c(cc4N(c4cc([2H])cc([2H])c4)c4cccc2c43)N(c2cc([2H])cc([2H])c2)c2cc3c4c6c2B5c2ccc(C(C)(C)C)c5c2N6c2c(ccc(C(C)(C)C)c2O5)B4c2ccc(C(C)(C)C)cc2N3c2cc([2H])cc([2H])c2)c1]

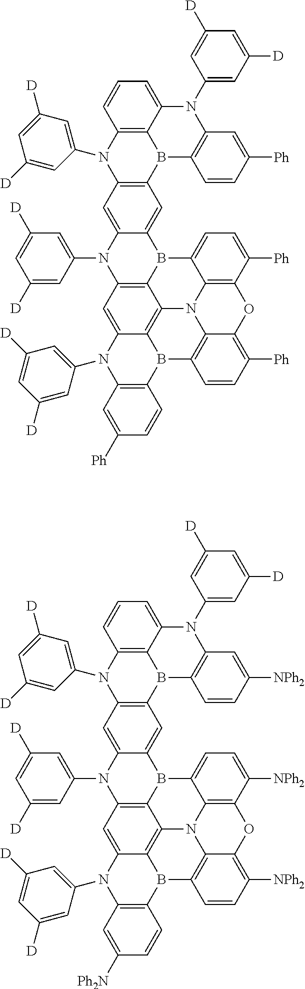

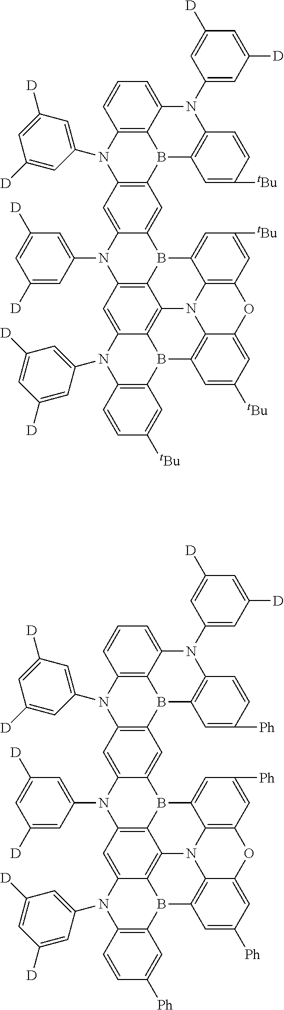 [SMILES: [2H]c1cc([2H])cc(N2c3ccc(C(C)(C)C)cc3B3c4cc5c(cc4N(c4cc([2H])cc([2H])c4)c4cccc2c43)N(c2cc([2H])cc([2H])c2)c2cc3c4c6c2B5c2cc(C(C)(C)C)cc5c2N6c2c(cc(C(C)(C)C)cc2B4c2cc(C(C)(C)C)ccc2N3c2cc([2H])cc([2H])c2)O5)c1 ; [2H]c1cc([2H])cc(N2c3ccc(-c4ccccc4)cc3B3c4cc5c(cc4N(c4cc([2H])cc([2H])c4)c4cccc2c43)N(c2cc([2H])cc([2H])c2)c2cc3c4c6c2B5c2cc(-c5ccccc5)cc5c2N6c2c(cc(-c6ccccc6)cc2B4c2cc(-c4ccccc4)ccc2N3c2cc([2H])cc([2H])c2)O5)c1]

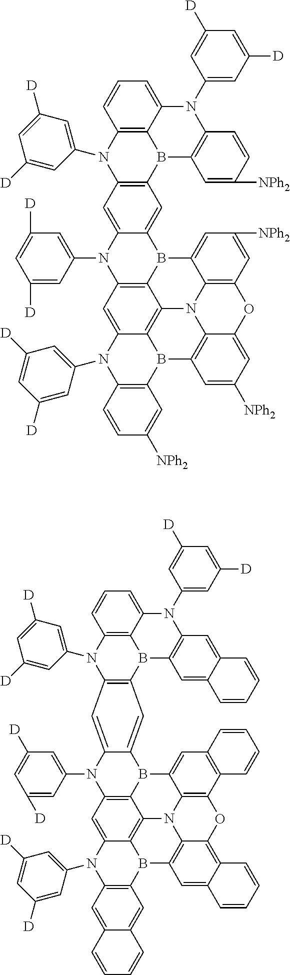

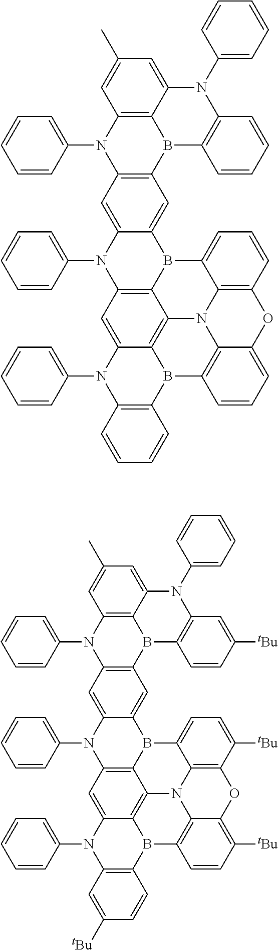 [SMILES: Cc1cc2c3c(c1)N(c1ccccc1)c1cc4c(cc1B3c1ccccc1N2c1ccccc1)B1c2cccc3c2N2c5c(cccc5B5c6ccccc6N(c6ccccc6)c6cc(c1c2c65)N4c1ccccc1)O3 ; Cc1cc2c3c(c1)N(c1ccccc1)c1cc4c(cc1B3c1ccc(C(C)(C)C)cc1N2c1ccccc1)B1c2ccc(C(C)(C)C)c3c2N2c5c(ccc(C(C)(C)C)c5O3)B3c5ccc(C(C)(C)C)cc5N(c5ccccc5)c5cc(c1c2c53)N4c1ccccc1]

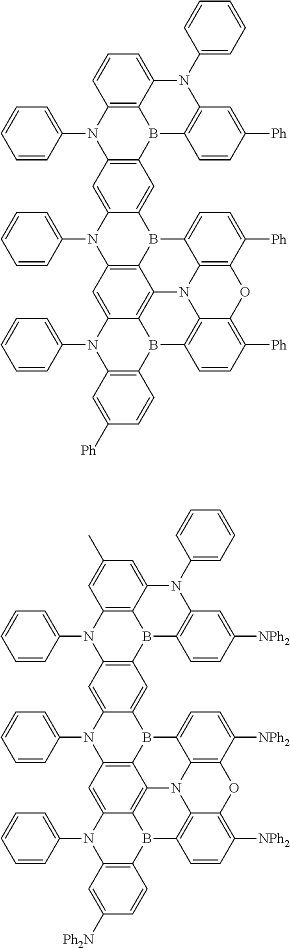

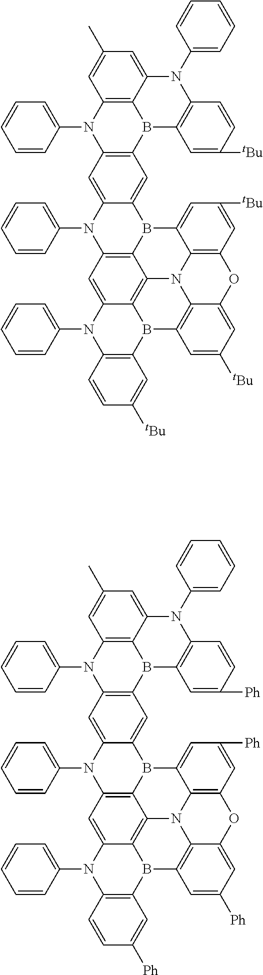 [SMILES: Cc1cc2c3c(c1)N(c1ccccc1)c1cc4c(cc1B3c1cc(C(C)(C)C)ccc1N2c1ccccc1)B1c2cc(C(C)(C)C)cc3c2N2c5c(cc(C(C)(C)C)cc5B5c6cc(C(C)(C)C)ccc6N(c6ccccc6)c6cc(c1c2c65)N4c1ccccc1)O3 ; Cc1cc2c3c(c1)N(c1ccccc1)c1cc4c(cc1B3c1cc(-c3ccccc3)ccc1N2c1ccccc1)B1c2cc(-c3ccccc3)cc3c2N2c5c(cc(-c6ccccc6)cc5B5c6cc(-c7ccccc7)ccc6N(c6ccccc6)c6cc(c1c2c65)N4c1ccccc1)O3]

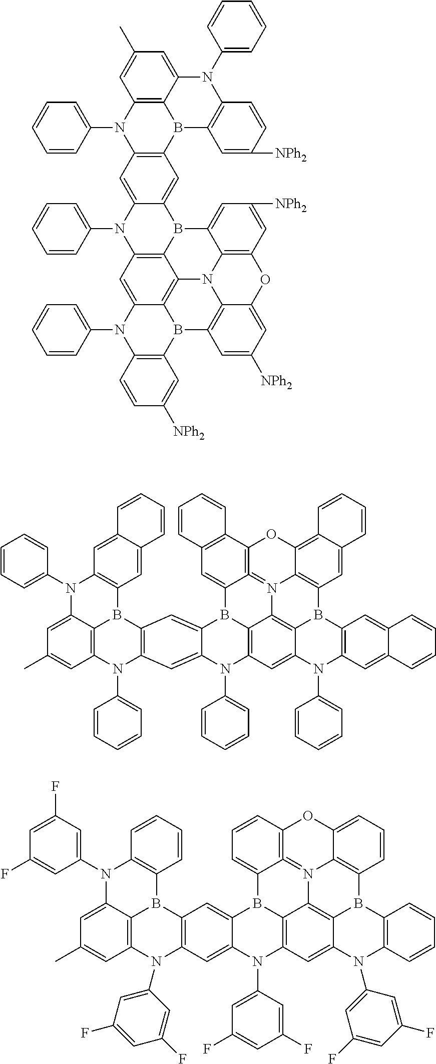

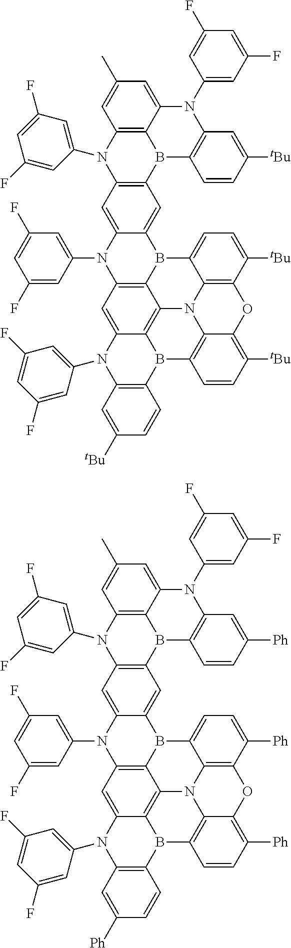 [SMILES: Cc1cc2c3c(c1)N(c1cc(F)cc(F)c1)c1cc4c(cc1B3c1ccc(C(C)(C)C)cc1N2c1cc(F)cc(F)c1)B1c2ccc(C(C)(C)C)c3c2N2c5c(ccc(C(C)(C)C)c5O3)B3c5ccc(C(C)(C)C)cc5N(c5cc(F)cc(F)c5)c5cc(c1c2c53)N4c1cc(F)cc(F)c1 ; Cc1cc2c3c(c1)N(c1cc(F)cc(F)c1)c1cc4c(cc1B3c1ccc(-c3ccccc3)cc1N2c1cc(F)cc(F)c1)B1c2ccc(-c3ccccc3)c3c2N2c5c(ccc(-c6ccccc6)c5O3)B3c5ccc(-c6ccccc6)cc5N(c5cc(F)cc(F)c5)c5cc(c1c2c53)N4c1cc(F)cc(F)c1]

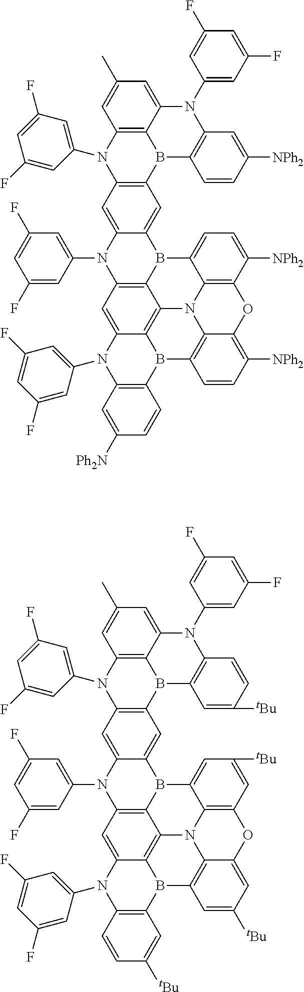

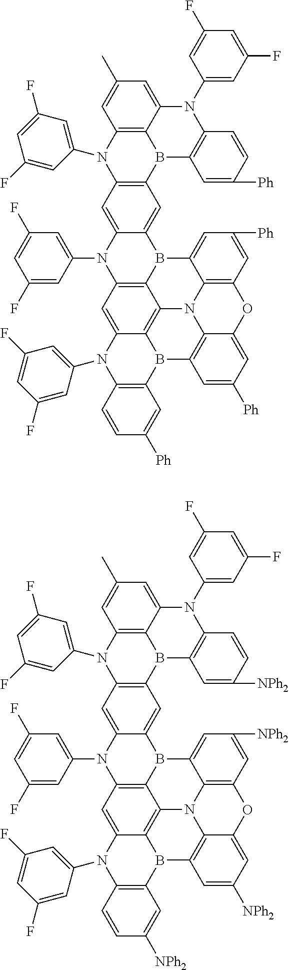

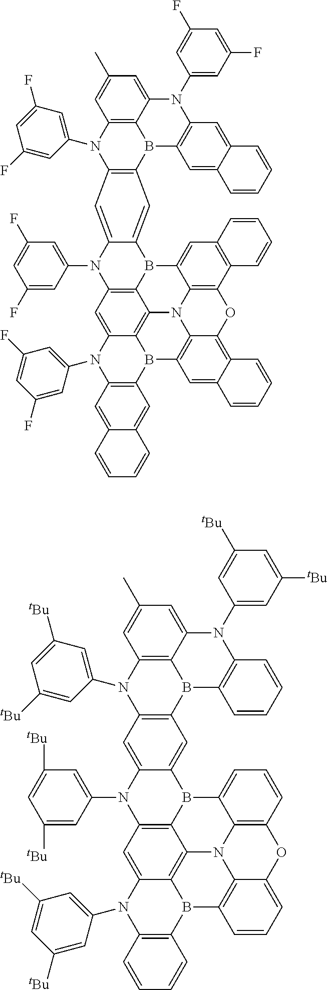 [SMILES: Cc1cc2c3c(c1)N(c1cc(F)cc(F)c1)c1cc4ccccc4cc1B3c1cc3c(cc1N2c1cc(F)cc(F)c1)N(c1cc(F)cc(F)c1)c1cc2c4c5c1B3c1cc3ccccc3c3c1N5c1c(cc5ccccc5c1O3)B4c1cc3ccccc3cc1N2c1cc(F)cc(F)c1 ; Cc1cc2c3c(c1)N(c1cc(C(C)(C)C)cc(C(C)(C)C)c1)c1cc4c(cc1B3c1ccccc1N2c1cc(C(C)(C)C)cc(C(C)(C)C)c1)B1c2cccc3c2N2c5c(cccc5B5c6ccccc6N(c6cc(C(C)(C)C)cc(C(C)(C)C)c6)c6cc(c1c2c65)N4c1cc(C(C)(C)C)cc(C(C)(C)C)c1)O3]

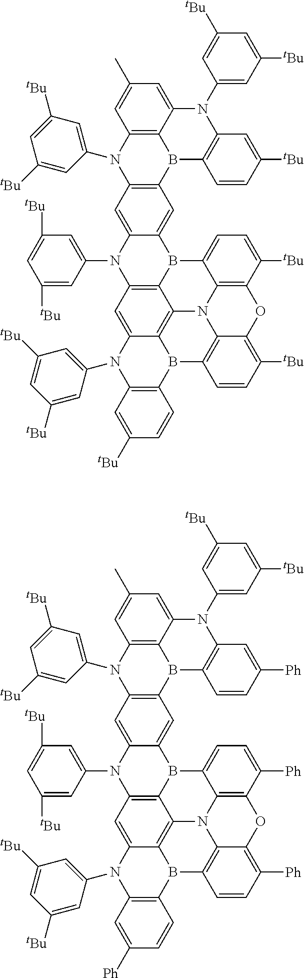 [SMILES: Cc1cc2c3c(c1)N(c1cc(C(C)(C)C)cc(C(C)(C)C)c1)c1cc4c(cc1B3c1ccc(C(C)(C)C)cc1N2c1cc(C(C)(C)C)cc(C(C)(C)C)c1)B1c2ccc(C(C)(C)C)c3c2N2c5c(ccc(C(C)(C)C)c5O3)B3c5ccc(C(C)(C)C)cc5N(c5cc(C(C)(C)C)cc(C(C)(C)C)c5)c5cc(c1c2c53)N4c1cc(C(C)(C)C)cc(C(C)(C)C)c1 ; Cc1cc2c3c(c1)N(c1cc(C(C)(C)C)cc(C(C)(C)C)c1)c1cc4c(cc1B3c1ccc(-c3ccccc3)cc1N2c1cc(C(C)(C)C)cc(C(C)(C)C)c1)B1c2ccc(-c3ccccc3)c3c2N2c5c(ccc(-c6ccccc6)c5O3)B3c5ccc(-c6ccccc6)cc5N(c5cc(C(C)(C)C)cc(C(C)(C)C)c5)c5cc(c1c2c53)N4c1cc(C(C)(C)C)cc(C(C)(C)C)c1]

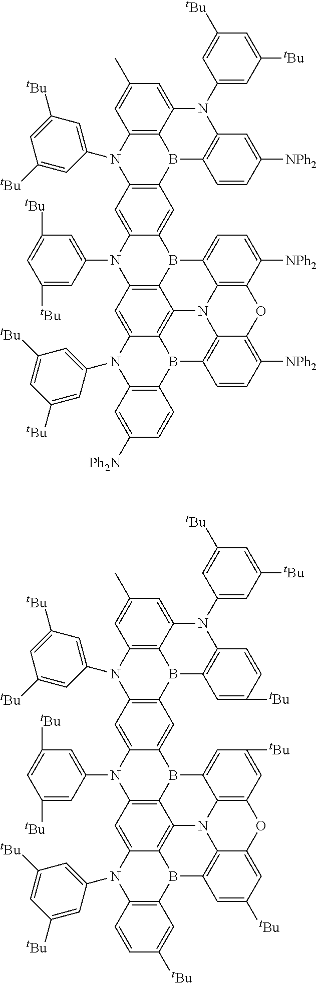

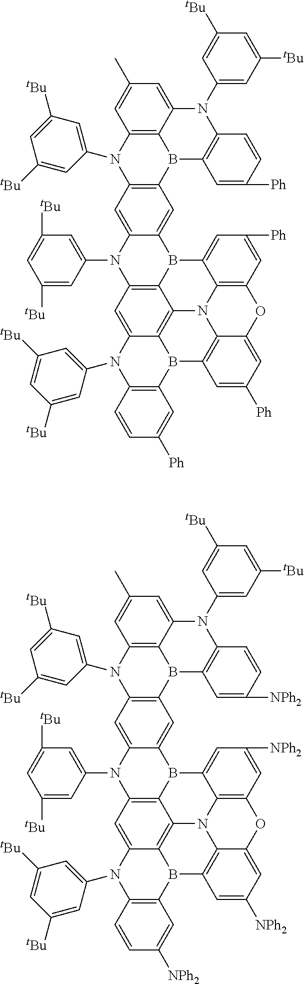

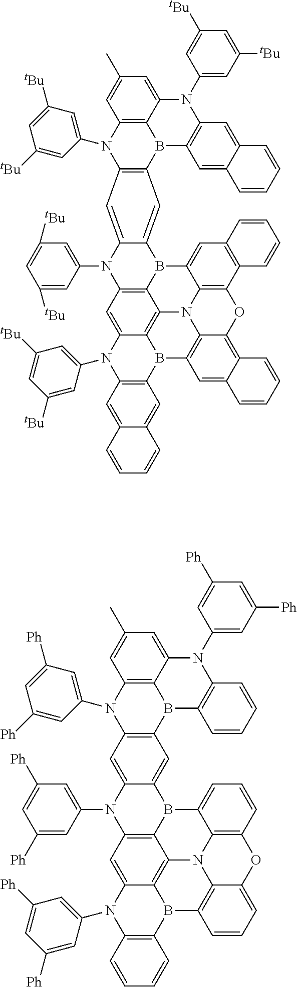 [SMILES: Cc1cc2c3c(c1)N(c1cc(C(C)(C)C)cc(C(C)(C)C)c1)c1cc4ccccc4cc1B3c1cc3c(cc1N2c1cc(C(C)(C)C)cc(C(C)(C)C)c1)N(c1cc(C(C)(C)C)cc(C(C)(C)C)c1)c1cc2c4c5c1B3c1cc3ccccc3c3c1N5c1c(cc5ccccc5c1O3)B4c1cc3ccccc3cc1N2c1cc(C(C)(C)C)cc(C(C)(C)C)c1 ; Cc1cc2c3c(c1)N(c1cc(-c4ccccc4)cc(-c4ccccc4)c1)c1cc4c(cc1B3c1ccccc1N2c1cc(-c2ccccc2)cc(-c2ccccc2)c1)B1c2cccc3c2N2c5c(cccc5B5c6ccccc6N(c6cc(-c7ccccc7)cc(-c7ccccc7)c6)c6cc(c1c2c65)N4c1cc(-c2ccccc2)cc(-c2ccccc2)c1)O3]

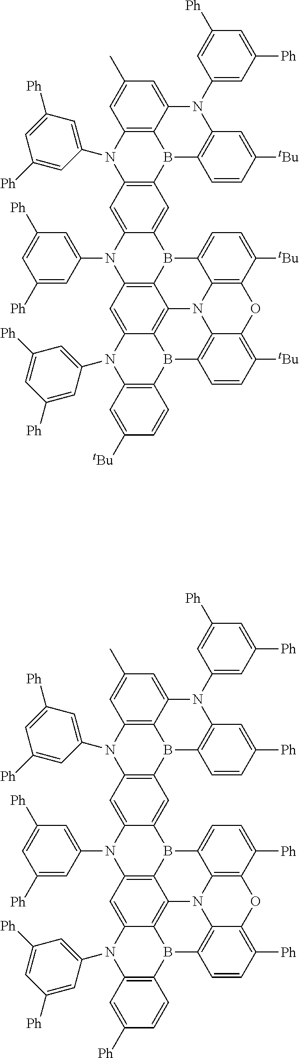

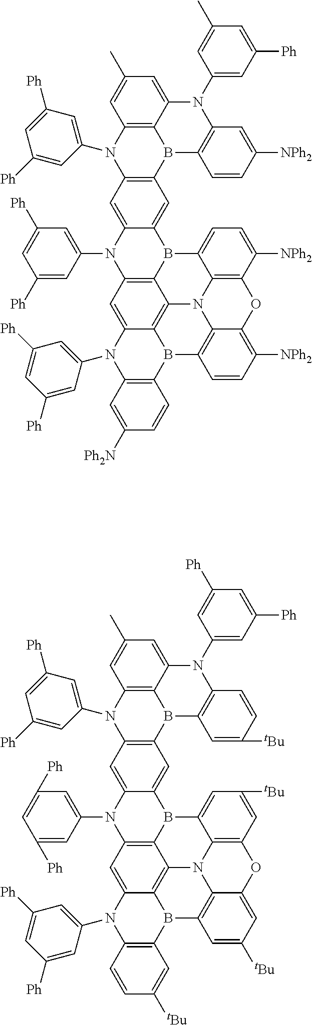

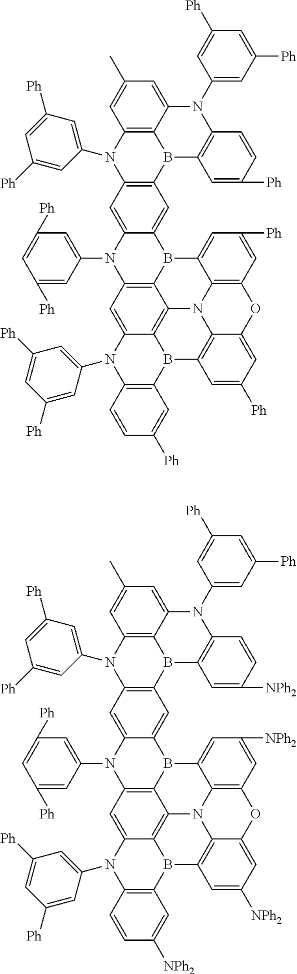

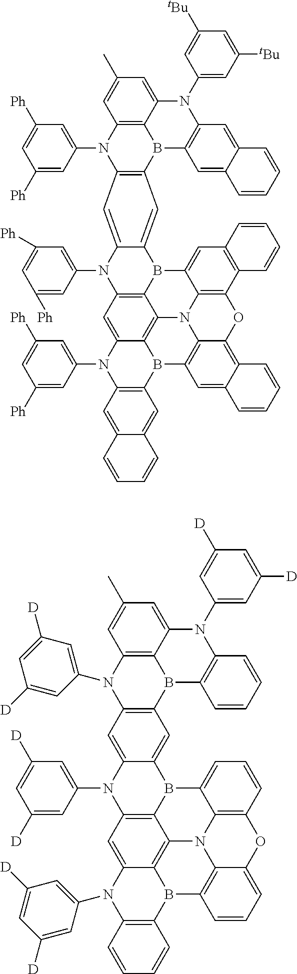 [SMILES: Cc1cc2c3c(c1)N(c1cc(C(C)(C)C)cc(C(C)(C)C)c1)c1cc4ccccc4cc1B3c1cc3c(cc1N2c1cc(-c2ccccc2)cc(-c2ccccc2)c1)N(c1cc(-c2ccccc2)cc(-c2ccccc2)c1)c1cc2c4c5c1B3c1cc3ccccc3c3c1N5c1c(cc5ccccc5c1O3)B4c1cc3ccccc3cc1N2c1cc(-c2ccccc2)cc(-c2ccccc2)c1 ; [2H]c1cc([2H])cc(N2c3ccccc3B3c4cc5c(cc4N(c4cc([2H])cc([2H])c4)c4cc(C)cc2c43)N(c2cc([2H])cc([2H])c2)c2cc3c4c6c2B5c2cccc5c2N6c2c(cccc2B4c2ccccc2N3c2cc([2H])cc([2H])c2)O5)c1]

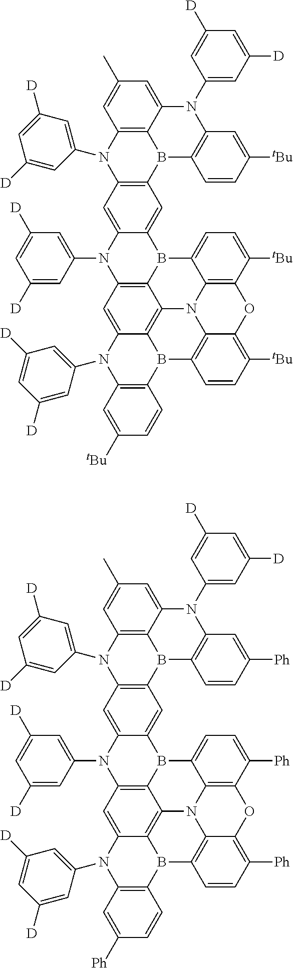 [SMILES: [2H]c1cc([2H])cc(N2c3cc(C(C)(C)C)ccc3B3c4cc5c(cc4N(c4cc([2H])cc([2H])c4)c4cc(C)cc2c43)N(c2cc([2H])cc([2H])c2)c2cc3c4c6c2B5c2ccc(C(C)(C)C)c5c2N6c2c(ccc(C(C)(C)C)c2O5)B4c2ccc(C(C)(C)C)cc2N3c2cc([2H])cc([2H])c2)c1 ; [2H]c1cc([2H])cc(N2c3cc(-c4ccccc4)ccc3B3c4cc5c(cc4N(c4cc([2H])cc([2H])c4)c4cc(C)cc2c43)N(c2cc([2H])cc([2H])c2)c2cc3c4c6c2B5c2ccc(-c5ccccc5)c5c2N6c2c(ccc(-c6ccccc6)c2O5)B4c2ccc(-c4ccccc4)cc2N3c2cc([2H])cc([2H])c2)c1]

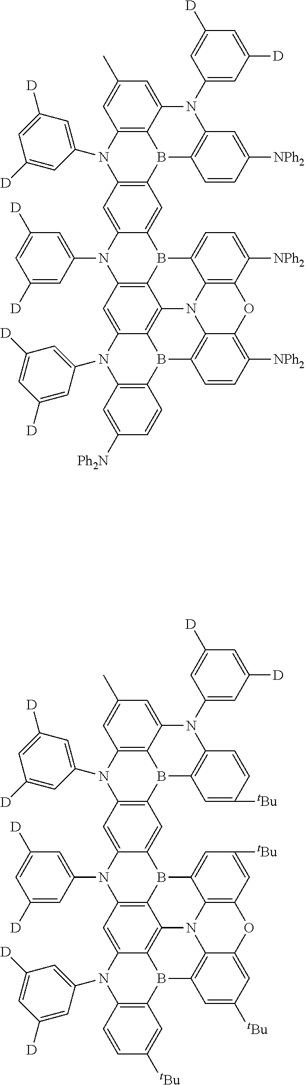

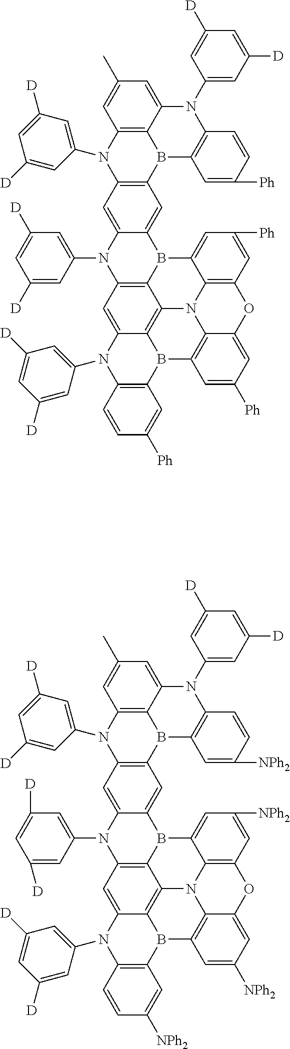

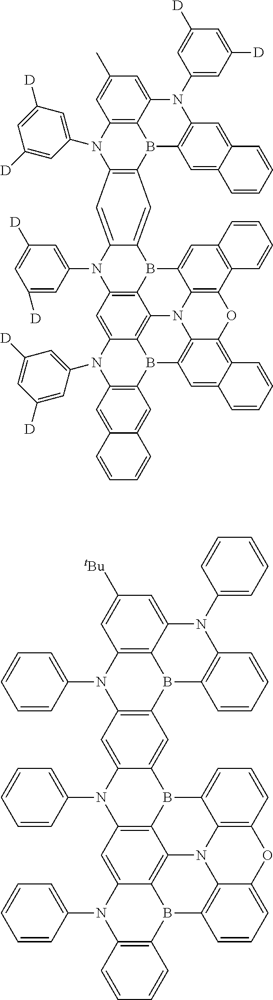 [SMILES: [2H]c1cc([2H])cc(N2c3cc4c(cc3B3c5cc6ccccc6cc5N(c5cc([2H])cc([2H])c5)c5cc(C)cc2c53)B2c3cc5ccccc5c5c3N3c6c2c(cc2c6B(c6cc7ccccc7cc6N2c2cc([2H])cc([2H])c2)c2cc6ccccc6c(c23)O5)N4c2cc([2H])cc([2H])c2)c1 ; CC(C)(C)c1cc2c3c(c1)N(c1ccccc1)c1cc4c(cc1B3c1ccccc1N2c1ccccc1)B1c2cccc3c2N2c5c(cccc5B5c6ccccc6N(c6ccccc6)c6cc(c1c2c65)N4c1ccccc1)O3]

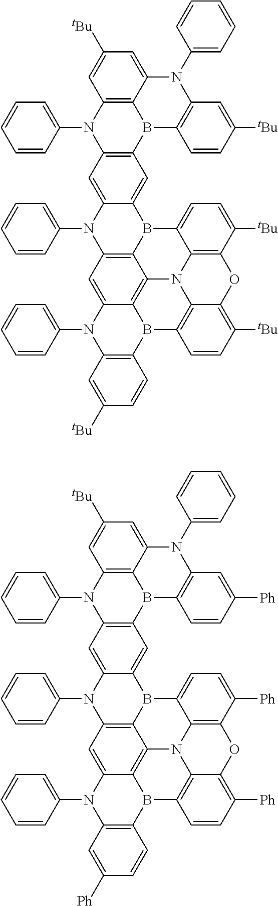 [SMILES: CC(C)(C)c1ccc2c(c1)N(c1ccccc1)c1cc(C(C)(C)C)cc3c1B2c1cc2c(cc1N3c1ccccc1)N(c1ccccc1)c1cc3c4c5c1B2c1ccc(C(C)(C)C)c2c1N5c1c(ccc(C(C)(C)C)c1O2)B4c1ccc(C(C)(C)C)cc1N3c1ccccc1 ; CC(C)(C)c1cc2c3c(c1)N(c1ccccc1)c1cc4c(cc1B3c1ccc(-c3ccccc3)cc1N2c1ccccc1)B1c2ccc(-c3ccccc3)c3c2N2c5c(ccc(-c6ccccc6)c5O3)B3c5ccc(-c6ccccc6)cc5N(c5ccccc5)c5cc(c1c2c53)N4c1ccccc1]

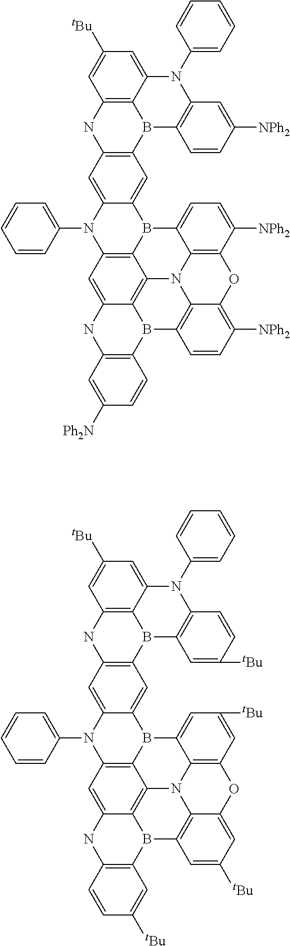

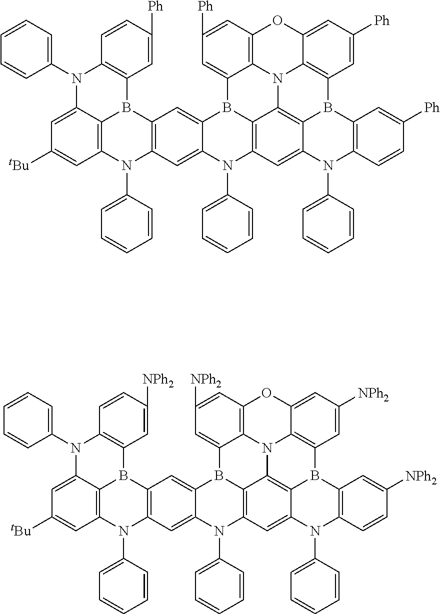

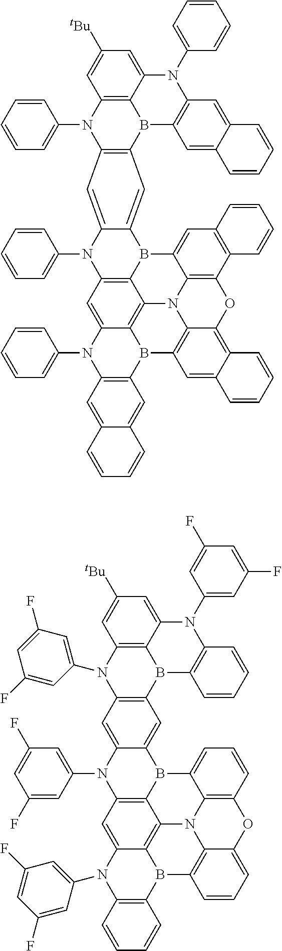 [SMILES: CC(C)(C)c1cc2c3c(c1)N(c1ccccc1)c1cc4ccccc4cc1B3c1cc3c(cc1N2c1ccccc1)N(c1ccccc1)c1cc2c4c5c1B3c1cc3ccccc3c3c1N5c1c(cc5ccccc5c1O3)B4c1cc3ccccc3cc1N2c1ccccc1 ; CC(C)(C)c1cc2c3c(c1)N(c1cc(F)cc(F)c1)c1cc4c(cc1B3c1ccccc1N2c1cc(F)cc(F)c1)B1c2cccc3c2N2c5c(cccc5B5c6ccccc6N(c6cc(F)cc(F)c6)c6cc(c1c2c65)N4c1cc(F)cc(F)c1)O3]

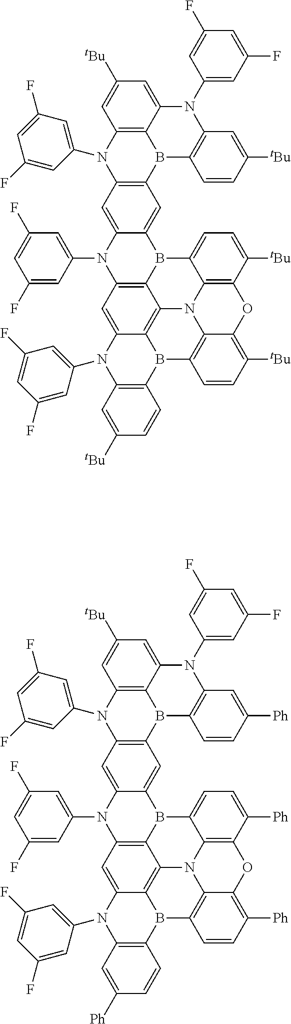 [SMILES: CC(C)(C)c1ccc2c(c1)N(c1cc(F)cc(F)c1)c1cc(C(C)(C)C)cc3c1B2c1cc2c(cc1N3c1cc(F)cc(F)c1)N(c1cc(F)cc(F)c1)c1cc3c4c5c1B2c1ccc(C(C)(C)C)c2c1N5c1c(ccc(C(C)(C)C)c1O2)B4c1ccc(C(C)(C)C)cc1N3c1cc(F)cc(F)c1 ; CC(C)(C)c1cc2c3c(c1)N(c1cc(F)cc(F)c1)c1cc4c(cc1B3c1ccc(-c3ccccc3)cc1N2c1cc(F)cc(F)c1)B1c2ccc(-c3ccccc3)c3c2N2c5c(ccc(-c6ccccc6)c5O3)B3c5ccc(-c6ccccc6)cc5N(c5cc(F)cc(F)c5)c5cc(c1c2c53)N4c1cc(F)cc(F)c1]

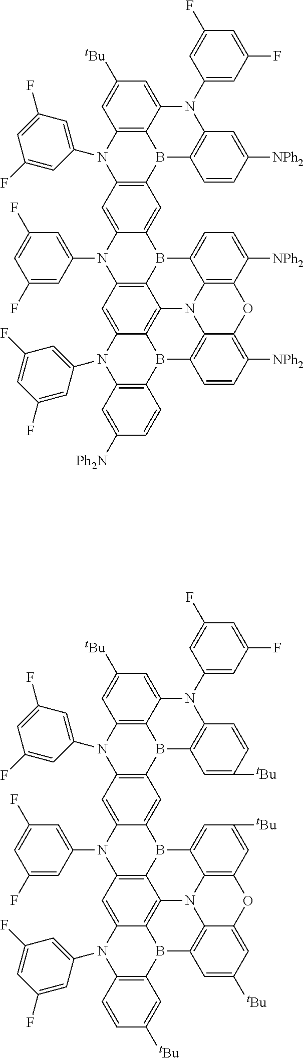

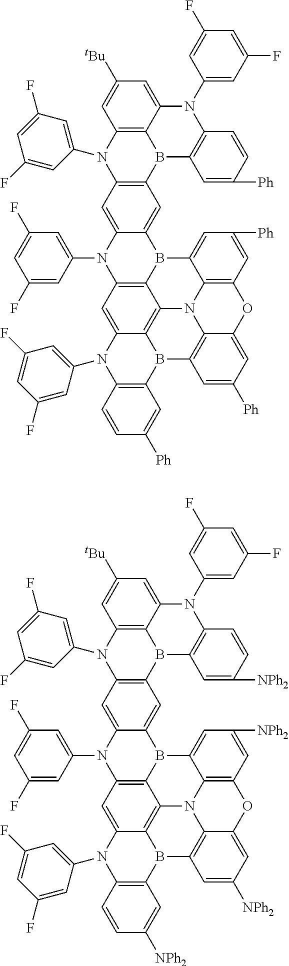

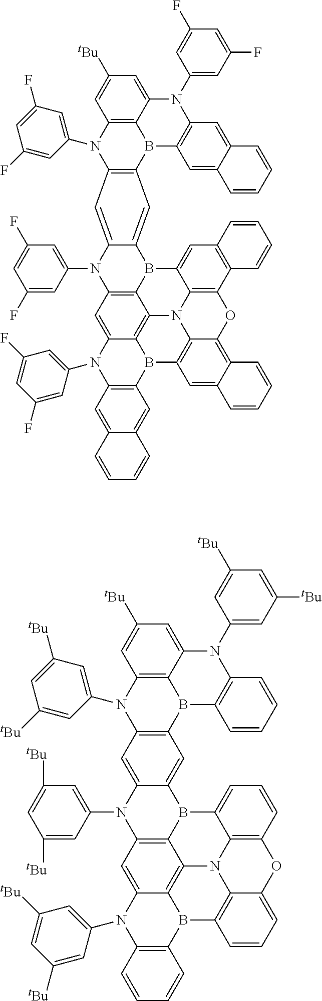 [SMILES: CC(C)(C)c1cc2c3c(c1)N(c1cc(F)cc(F)c1)c1cc4ccccc4cc1B3c1cc3c(cc1N2c1cc(F)cc(F)c1)N(c1cc(F)cc(F)c1)c1cc2c4c5c1B3c1cc3ccccc3c3c1N5c1c(cc5ccccc5c1O3)B4c1cc3ccccc3cc1N2c1cc(F)cc(F)c1 ; CC(C)(C)c1cc(N2c3ccccc3B3c4cc5c(cc4N(c4cc(C(C)(C)C)cc(C(C)(C)C)c4)c4cc(C(C)(C)C)cc2c43)N(c2cc(C(C)(C)C)cc(C(C)(C)C)c2)c2cc3c4c6c2B5c2cccc5c2N6c2c(cccc2B4c2ccccc2N3c2cc(C(C)(C)C)cc(C(C)(C)C)c2)O5)cc(C(C)(C)C)c1]

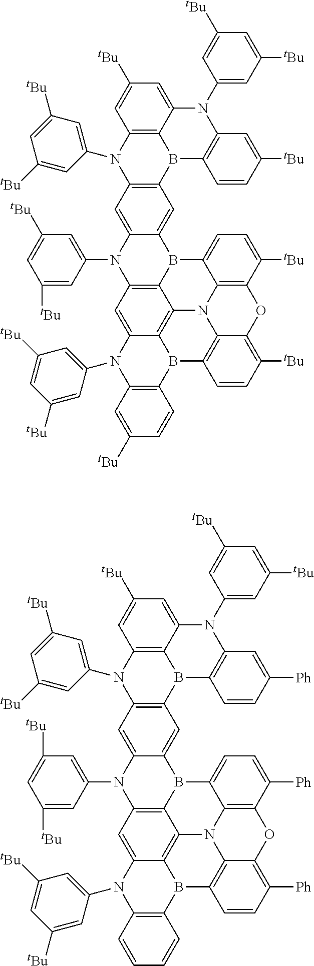 [SMILES: CC(C)(C)c1cc(N2c3cc(C(C)(C)C)ccc3B3c4cc5c(cc4N(c4cc(C(C)(C)C)cc(C(C)(C)C)c4)c4cc(C(C)(C)C)cc2c43)N(c2cc(C(C)(C)C)cc(C(C)(C)C)c2)c2cc3c4c6c2B5c2ccc(C(C)(C)C)c5c2N6c2c(ccc(C(C)(C)C)c2O5)B4c2ccc(C(C)(C)C)cc2N3c2cc(C(C)(C)C)cc(C(C)(C)C)c2)cc(C(C)(C)C)c1 ; CC(C)(C)c1cc(N2c3cc(-c4ccccc4)ccc3B3c4cc5c(cc4N(c4cc(C(C)(C)C)cc(C(C)(C)C)c4)c4cc(C(C)(C)C)cc2c43)N(c2cc(C(C)(C)C)cc(C(C)(C)C)c2)c2cc3c4c6c2B5c2ccc(-c5ccccc5)c5c2N6c2c(ccc(-c6ccccc6)c2O5)B4c2ccccc2N3c2cc(C(C)(C)C)cc(C(C)(C)C)c2)cc(C(C)(C)C)c1]

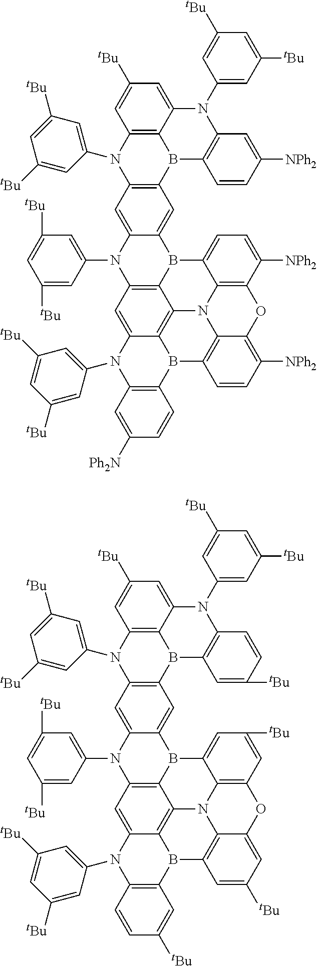

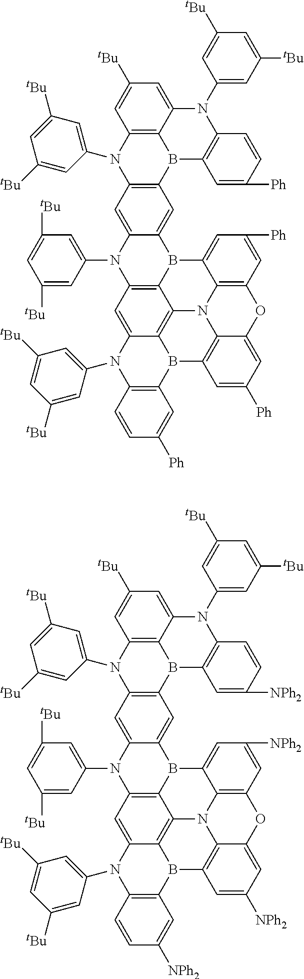

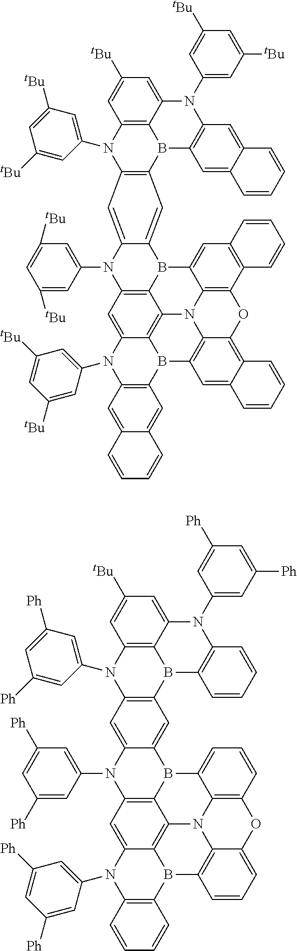 [SMILES: CC(C)(C)c1cc(N2c3cc4c(cc3B3c5cc6ccccc6cc5N(c5cc(C(C)(C)C)cc(C(C)(C)C)c5)c5cc(C(C)(C)C)cc2c53)B2c3cc5ccccc5c5c3N3c6c2c(cc2c6B(c6cc7ccccc7cc6N2c2cc(C(C)(C)C)cc(C(C)(C)C)c2)c2cc6ccccc6c(c23)O5)N4c2cc(C(C)(C)C)cc(C(C)(C)C)c2)cc(C(C)(C)C)c1 ; CC(C)(C)c1cc2c3c(c1)N(c1cc(-c4ccccc4)cc(-c4ccccc4)c1)c1cc4c(cc1B3c1ccccc1N2c1cc(-c2ccccc2)cc(-c2ccccc2)c1)B1c2cccc3c2N2c5c(cccc5B5c6ccccc6N(c6cc(-c7ccccc7)cc(-c7ccccc7)c6)c6cc(c1c2c65)N4c1cc(-c2ccccc2)cc(-c2ccccc2)c1)O3]

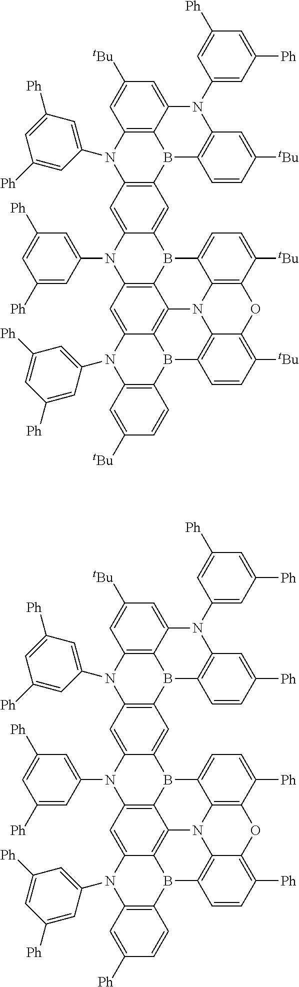

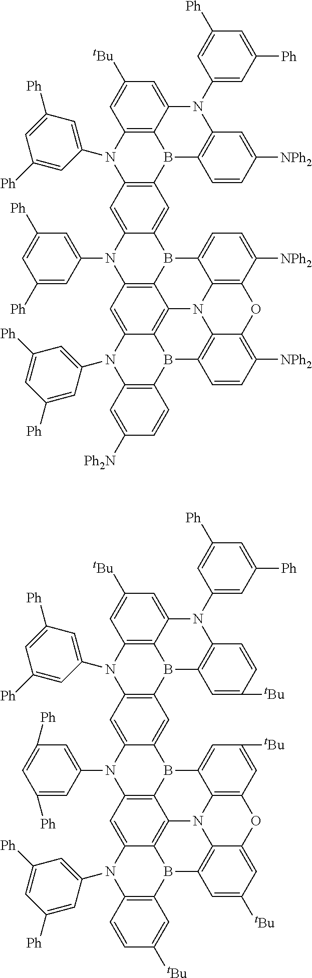

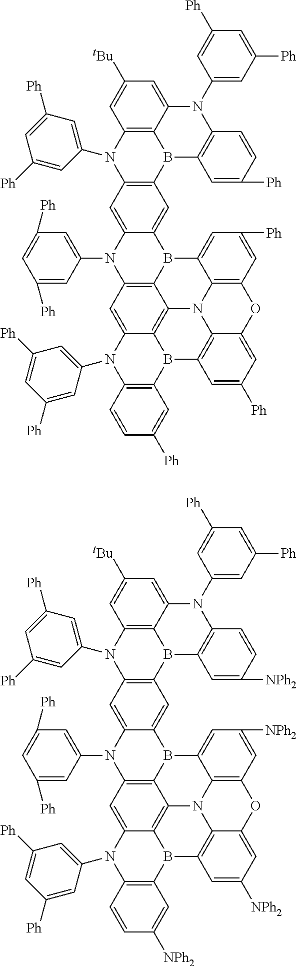

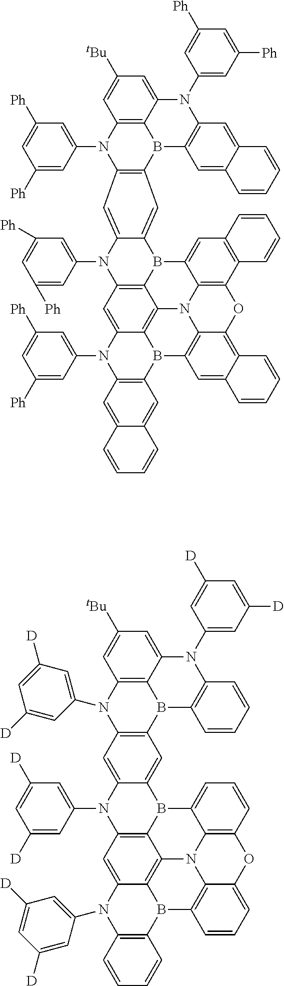 [SMILES: CC(C)(C)c1cc2c3c(c1)N(c1cc(-c4ccccc4)cc(-c4ccccc4)c1)c1cc4ccccc4cc1B3c1cc3c(cc1N2c1cc(-c2ccccc2)cc(-c2ccccc2)c1)N(c1cc(-c2ccccc2)cc(-c2ccccc2)c1)c1cc2c4c5c1B3c1cc3ccccc3c3c1N5c1c(cc5ccccc5c1O3)B4c1cc3ccccc3cc1N2c1cc(-c2ccccc2)cc(-c2ccccc2)c1 ; [2H]c1cc([2H])cc(N2c3ccccc3B3c4cc5c(cc4N(c4cc([2H])cc([2H])c4)c4cc(C(C)(C)C)cc2c43)N(c2cc([2H])cc([2H])c2)c2cc3c4c6c2B5c2cccc5c2N6c2c(cccc2B4c2ccccc2N3c2cc([2H])cc([2H])c2)O5)c1]

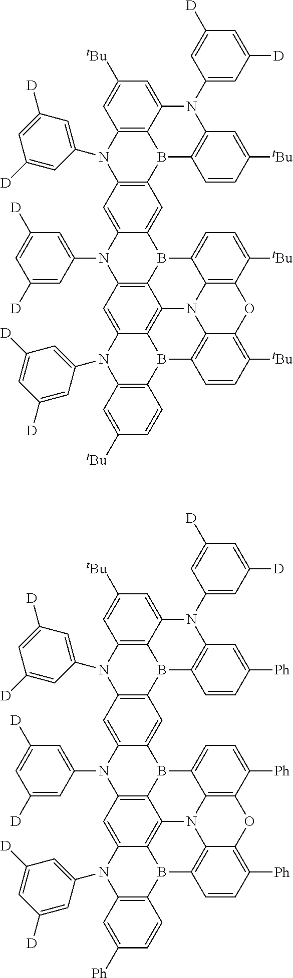 [SMILES: [2H]c1cc([2H])cc(N2c3cc(C(C)(C)C)ccc3B3c4cc5c(cc4N(c4cc([2H])cc([2H])c4)c4cc(C(C)(C)C)cc2c43)N(c2cc([2H])cc([2H])c2)c2cc3c4c6c2B5c2ccc(C(C)(C)C)c5c2N6c2c(ccc(C(C)(C)C)c2O5)B4c2ccc(C(C)(C)C)cc2N3c2cc([2H])cc([2H])c2)c1 ; [2H]c1cc([2H])cc(N2c3cc(-c4ccccc4)ccc3B3c4cc5c(cc4N(c4cc([2H])cc([2H])c4)c4cc(C(C)(C)C)cc2c43)N(c2cc([2H])cc([2H])c2)c2cc3c4c6c2B5c2ccc(-c5ccccc5)c5c2N6c2c(ccc(-c6ccccc6)c2O5)B4c2ccc(-c4ccccc4)cc2N3c2cc([2H])cc([2H])c2)c1]

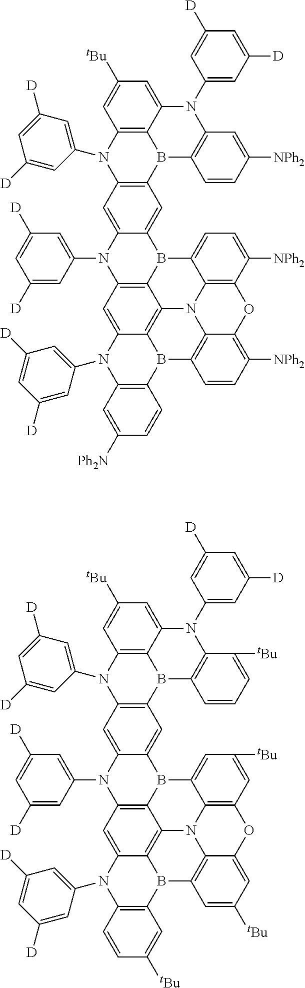

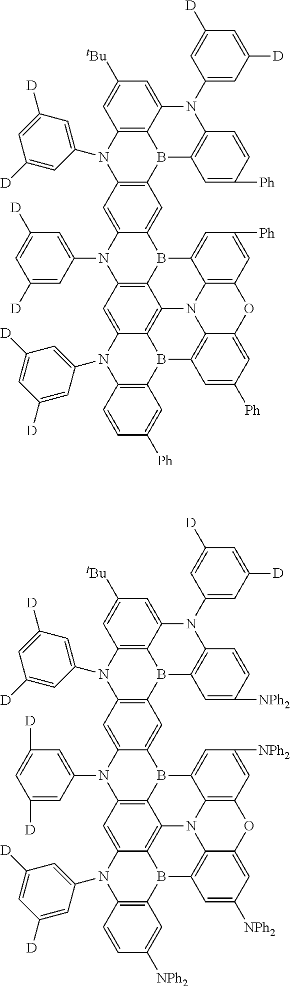

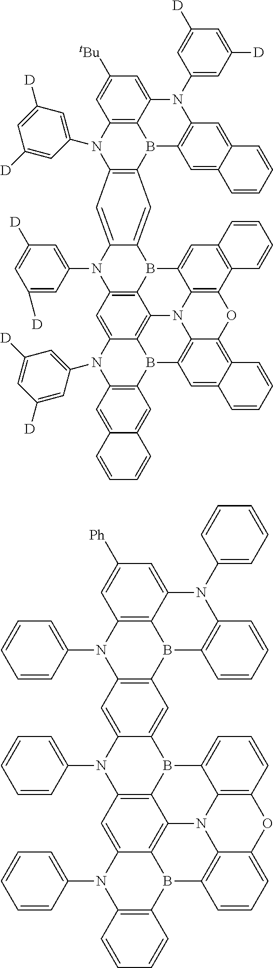 [SMILES: [2H]c1cc([2H])cc(N2c3cc4c(cc3B3c5cc6ccccc6cc5N(c5cc([2H])cc([2H])c5)c5cc(C(C)(C)C)cc2c53)B2c3cc5ccccc5c5c3N3c6c2c(cc2c6B(c6cc7ccccc7cc6N2c2cc([2H])cc([2H])c2)c2cc6ccccc6c(c23)O5)N4c2cc([2H])cc([2H])c2)c1 ; c1ccc(-c2cc3c4c(c2)N(c2ccccc2)c2cc5c(cc2B4c2ccccc2N3c2ccccc2)B2c3cccc4c3N3c6c(cccc6B6c7ccccc7N(c7ccccc7)c7cc(c2c3c76)N5c2ccccc2)O4)cc1]

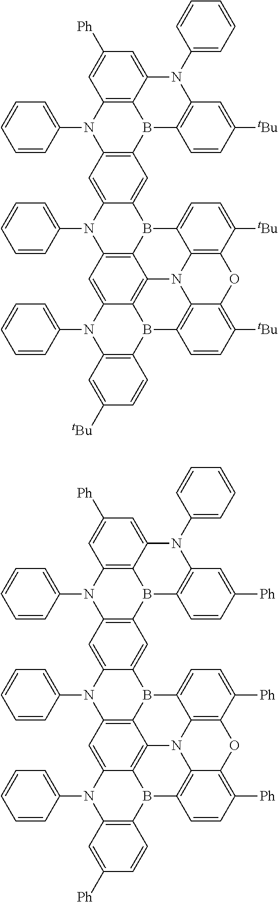 [SMILES: CC(C)(C)c1ccc2c(c1)N(c1ccccc1)c1cc(-c3ccccc3)cc3c1B2c1cc2c(cc1N3c1ccccc1)N(c1ccccc1)c1cc3c4c5c1B2c1ccc(C(C)(C)C)c2c1N5c1c(ccc(C(C)(C)C)c1O2)B4c1ccc(C(C)(C)C)cc1N3c1ccccc1 ; c1ccc(-c2ccc3c(c2)N(c2ccccc2)c2cc(-c4ccccc4)cc4c2B3c2cc3c(cc2N4c2ccccc2)N(c2ccccc2)c2cc4c5c6c2B3c2ccc(-c3ccccc3)c3c2N6c2c(ccc(-c6ccccc6)c2O3)B5c2ccc(-c3ccccc3)cc2N4c2ccccc2)cc1]

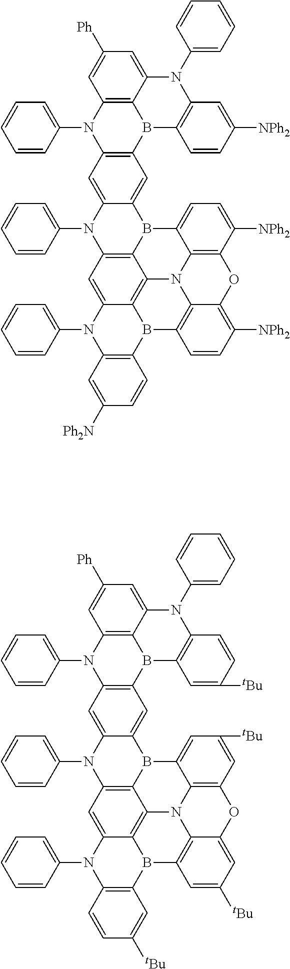

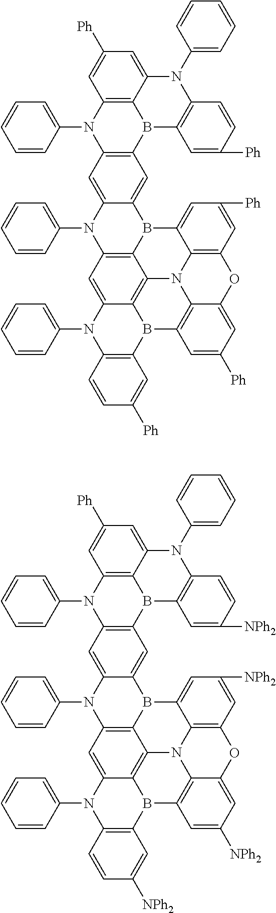

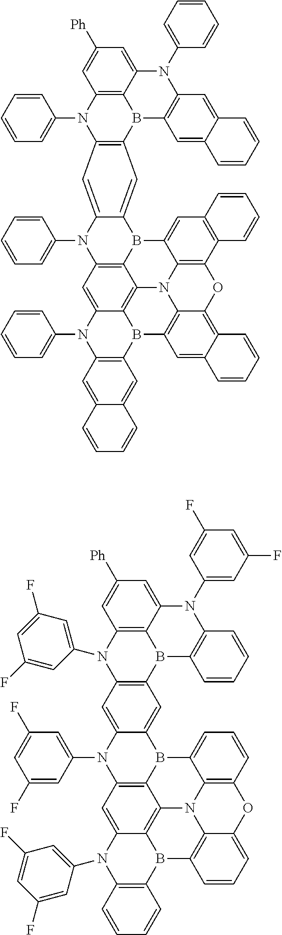 [SMILES: c1ccc(-c2cc3c4c(c2)N(c2ccccc2)c2cc5ccccc5cc2B4c2cc4c(cc2N3c2ccccc2)N(c2ccccc2)c2cc3c5c6c2B4c2cc4ccccc4c4c2N6c2c(cc6ccccc6c2O4)B5c2cc4ccccc4cc2N3c2ccccc2)cc1 ; Fc1cc(F)cc(N2c3ccccc3B3c4cc5c(cc4N(c4cc(F)cc(F)c4)c4cc(-c6ccccc6)cc2c43)N(c2cc(F)cc(F)c2)c2cc3c4c6c2B5c2cccc5c2N6c2c(cccc2B4c2ccccc2N3c2cc(F)cc(F)c2)O5)c1]

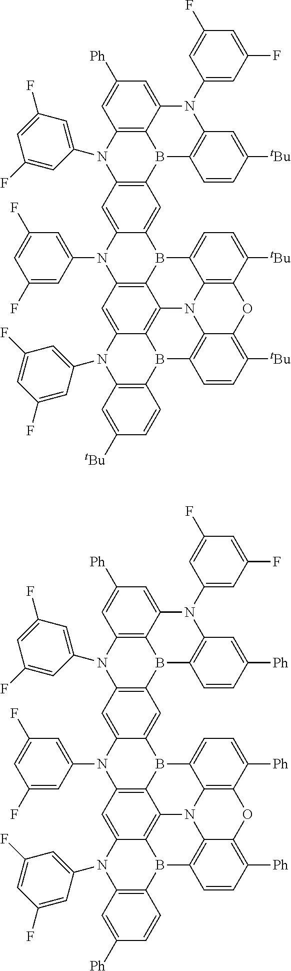 [SMILES: CC(C)(C)c1ccc2c(c1)N(c1cc(F)cc(F)c1)c1cc(-c3ccccc3)cc3c1B2c1cc2c(cc1N3c1cc(F)cc(F)c1)N(c1cc(F)cc(F)c1)c1cc3c4c5c1B2c1ccc(C(C)(C)C)c2c1N5c1c(ccc(C(C)(C)C)c1O2)B4c1ccc(C(C)(C)C)cc1N3c1cc(F)cc(F)c1 ; Fc1cc(F)cc(N2c3cc(-c4ccccc4)ccc3B3c4cc5c(cc4N(c4cc(F)cc(F)c4)c4cc(-c6ccccc6)cc2c43)N(c2cc(F)cc(F)c2)c2cc3c4c6c2B5c2ccc(-c5ccccc5)c5c2N6c2c(ccc(-c6ccccc6)c2O5)B4c2ccc(-c4ccccc4)cc2N3c2cc(F)cc(F)c2)c1]

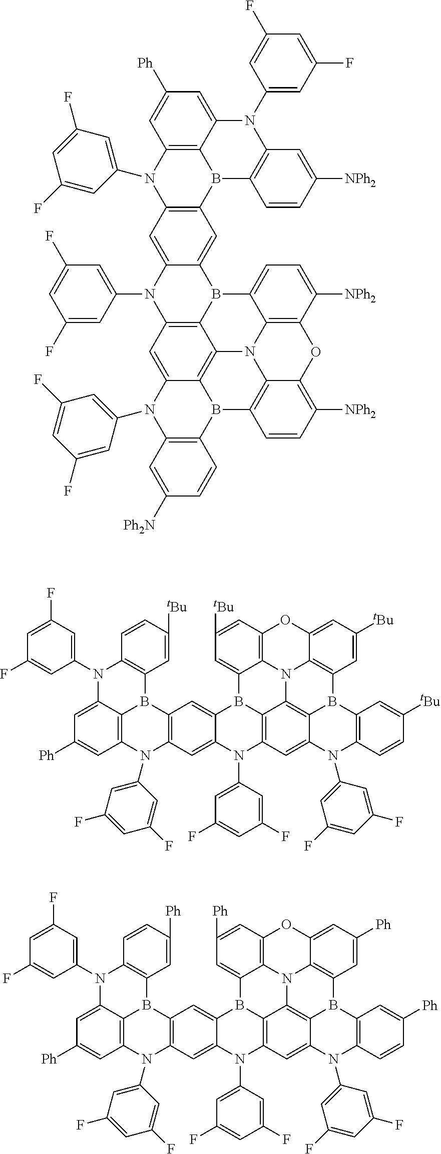

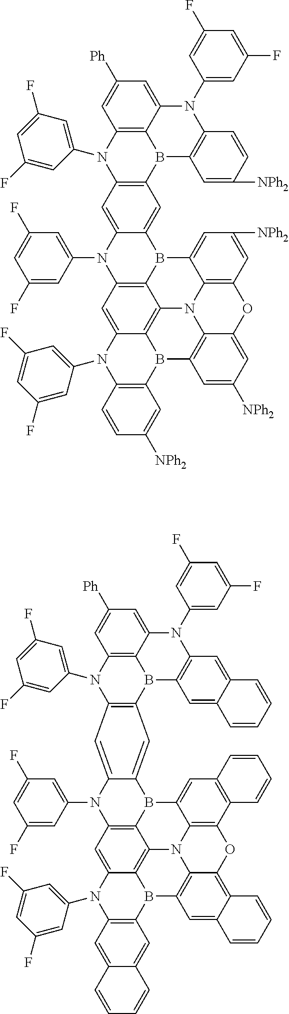

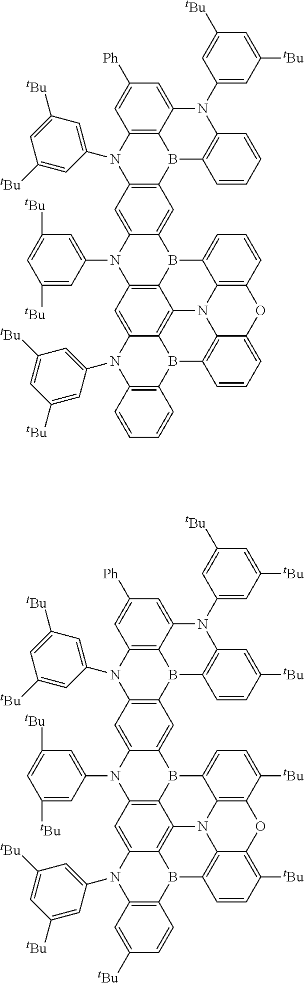 [SMILES: CC(C)(C)c1cc(N2c3ccccc3B3c4cc5c(cc4N(c4cc(C(C)(C)C)cc(C(C)(C)C)c4)c4cc(-c6ccccc6)cc2c43)N(c2cc(C(C)(C)C)cc(C(C)(C)C)c2)c2cc3c4c6c2B5c2cccc5c2N6c2c(cccc2B4c2ccccc2N3c2cc(C(C)(C)C)cc(C(C)(C)C)c2)O5)cc(C(C)(C)C)c1 ; CC(C)(C)c1cc(N2c3cc(C(C)(C)C)ccc3B3c4cc5c(cc4N(c4cc(C(C)(C)C)cc(C(C)(C)C)c4)c4cc(-c6ccccc6)cc2c43)N(c2cc(C(C)(C)C)cc(C(C)(C)C)c2)c2cc3c4c6c2B5c2ccc(C(C)(C)C)c5c2N6c2c(ccc(C(C)(C)C)c2O5)B4c2ccc(C(C)(C)C)cc2N3c2cc(C(C)(C)C)cc(C(C)(C)C)c2)cc(C(C)(C)C)c1]

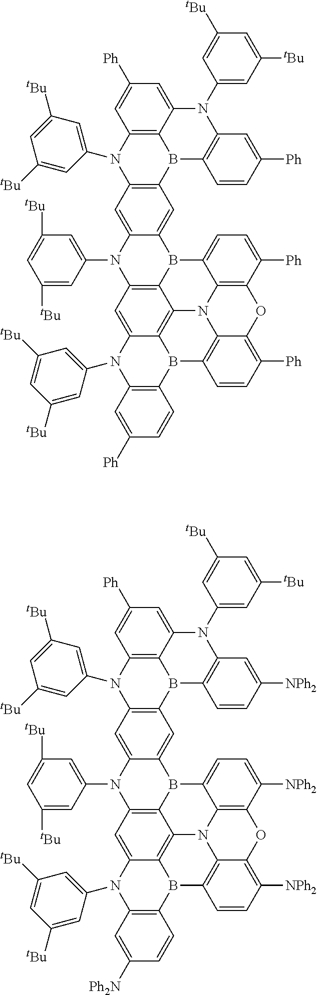

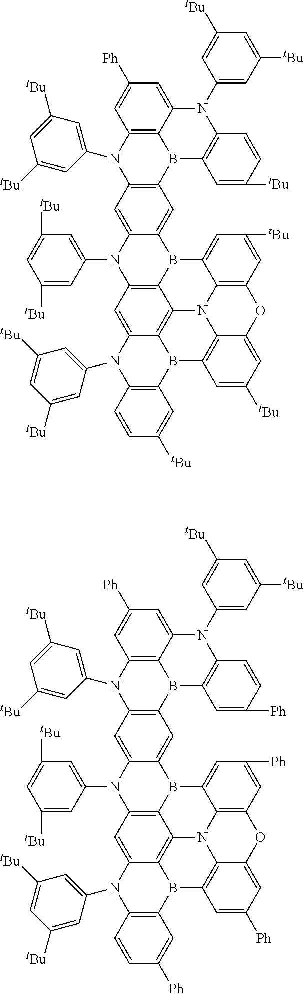

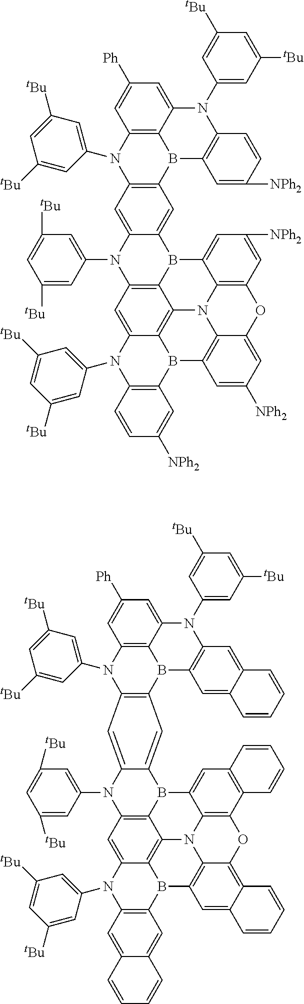

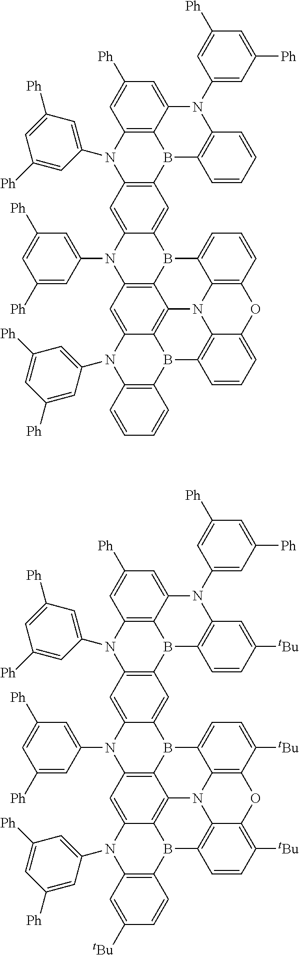 [SMILES: c1ccc(-c2cc(-c3ccccc3)cc(N3c4ccccc4B4c5cc6c(cc5N(c5cc(-c7ccccc7)cc(-c7ccccc7)c5)c5cc(-c7ccccc7)cc3c54)N(c3cc(-c4ccccc4)cc(-c4ccccc4)c3)c3cc4c5c7c3B6c3cccc6c3N7c3c(cccc3B5c3ccccc3N4c3cc(-c4ccccc4)cc(-c4ccccc4)c3)O6)c2)cc1 ; CC(C)(C)c1ccc2c(c1)N(c1cc(-c3ccccc3)cc(-c3ccccc3)c1)c1cc(-c3ccccc3)cc3c1B2c1cc2c(cc1N3c1cc(-c3ccccc3)cc(-c3ccccc3)c1)N(c1cc(-c3ccccc3)cc(-c3ccccc3)c1)c1cc3c4c5c1B2c1ccc(C(C)(C)C)c2c1N5c1c(ccc(C(C)(C)C)c1O2)B4c1ccc(C(C)(C)C)cc1N3c1cc(-c2ccccc2)cc(-c2ccccc2)c1]

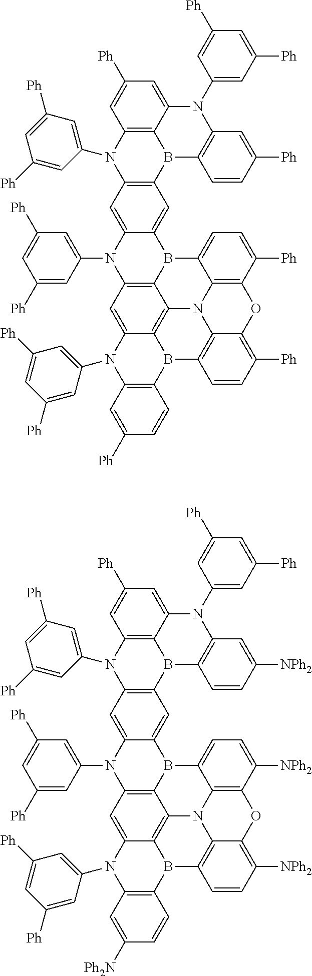

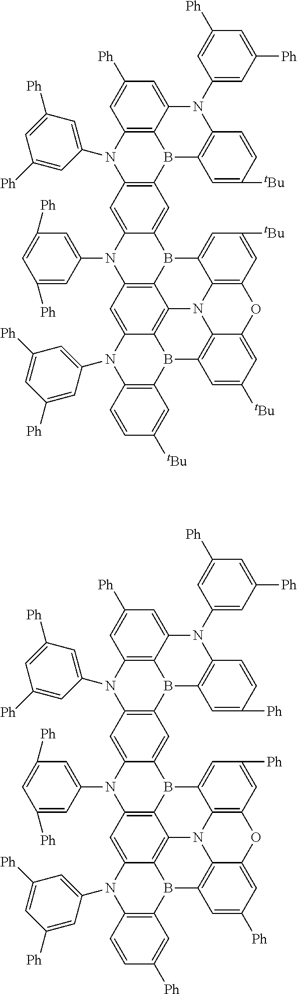

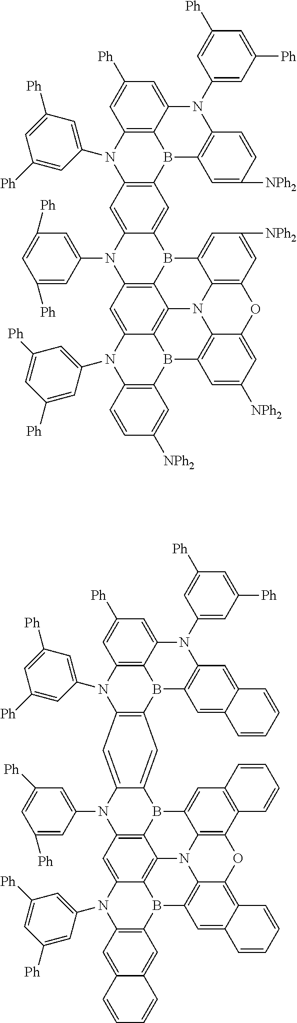

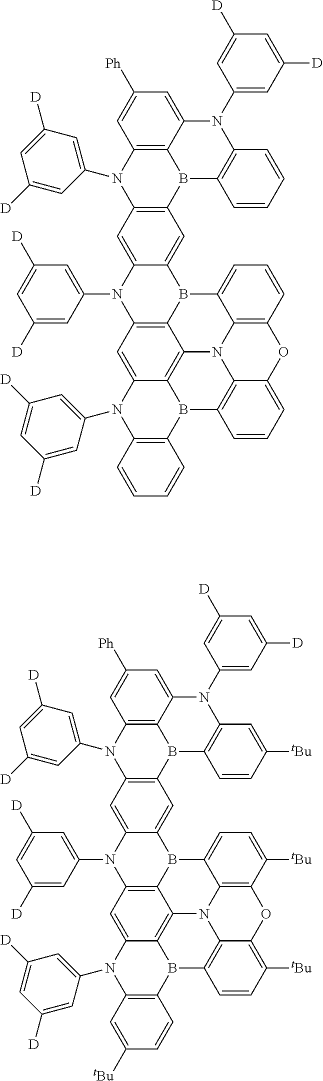 [SMILES: [2H]c1cc([2H])cc(N2c3ccccc3B3c4cc5c(cc4N(c4cc([2H])cc([2H])c4)c4cc(-c6ccccc6)cc2c43)N(c2cc([2H])cc([2H])c2)c2cc3c4c6c2B5c2cccc5c2N6c2c(cccc2B4c2ccccc2N3c2cc([2H])cc([2H])c2)O5)c1 ; [2H]c1cc([2H])cc(N2c3cc(C(C)(C)C)ccc3B3c4cc5c(cc4N(c4cc([2H])cc([2H])c4)c4cc(-c6ccccc6)cc2c43)N(c2cc([2H])cc([2H])c2)c2cc3c4c6c2B5c2ccc(C(C)(C)C)c5c2N6c2c(ccc(C(C)(C)C)c2O5)B4c2ccc(C(C)(C)C)cc2N3c2cc([2H])cc([2H])c2)c1]

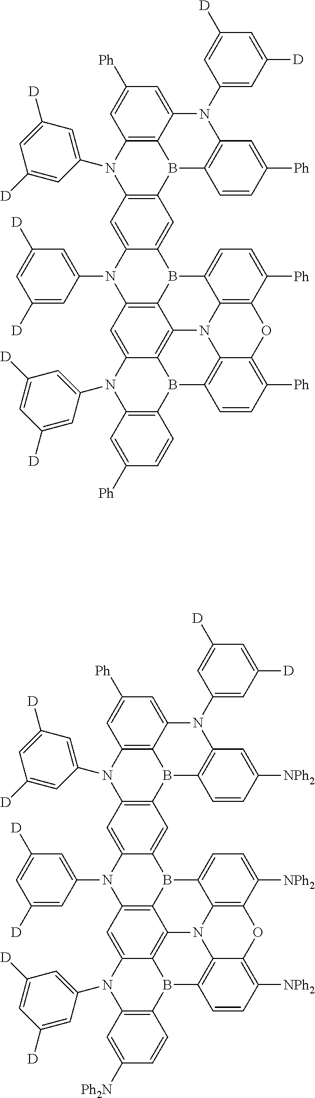

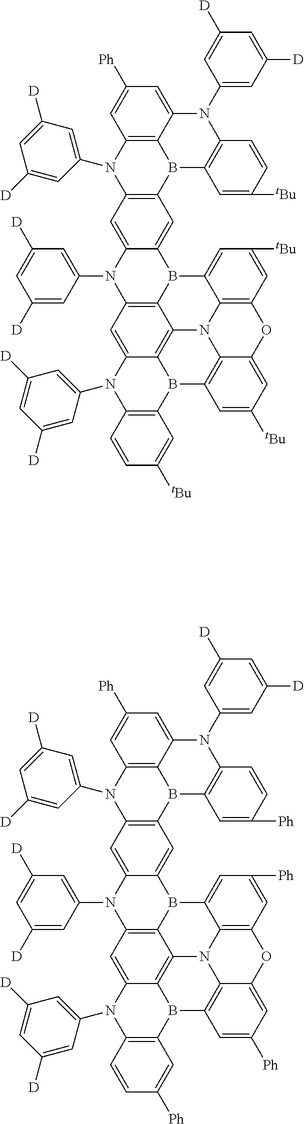 [SMILES: [2H]c1cc([2H])cc(N2c3ccc(C(C)(C)C)cc3B3c4cc5c(cc4N(c4cc([2H])cc([2H])c4)c4cc(-c6ccccc6)cc2c43)N(c2cc([2H])cc([2H])c2)c2cc3c4c6c2B5c2cc(C(C)(C)C)cc5c2N6c2c(cc(C(C)(C)C)cc2B4c2cc(C(C)(C)C)ccc2N3c2cc([2H])cc([2H])c2)O5)c1 ; [2H]c1cc([2H])cc(N2c3ccc(-c4ccccc4)cc3B3c4cc5c(cc4N(c4cc([2H])cc([2H])c4)c4cc(-c6ccccc6)cc2c43)N(c2cc([2H])cc([2H])c2)c2cc3c4c6c2B5c2cc(-c5ccccc5)cc5c2N6c2c(cc(-c6ccccc6)cc2B4c2cc(-c4ccccc4)ccc2N3c2cc([2H])cc([2H])c2)O5)c1]

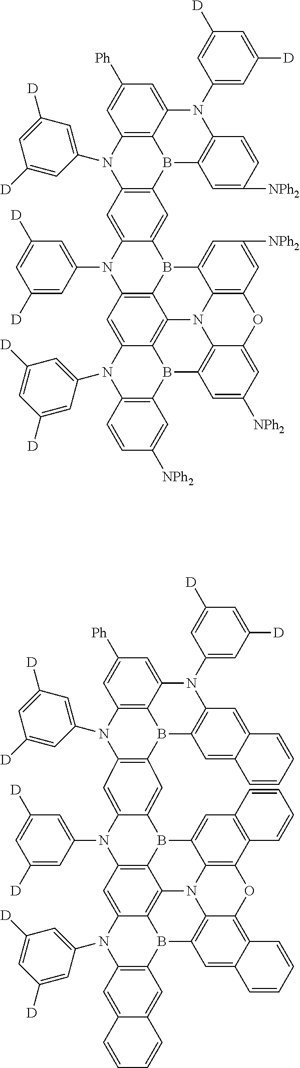

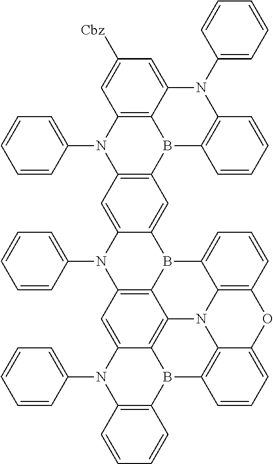 [SMILES: O=C(OCc1ccccc1)c1cc2c3c(c1)N(c1ccccc1)c1cc4c(cc1B3c1ccccc1N2c1ccccc1)B1c2cccc3c2N2c5c(cccc5B5c6ccccc6N(c6ccccc6)c6cc(c1c2c65)N4c1ccccc1)O3]

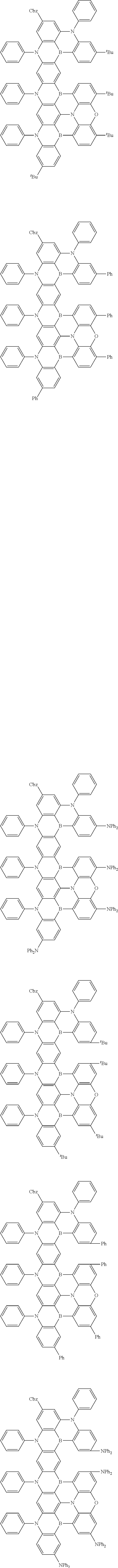

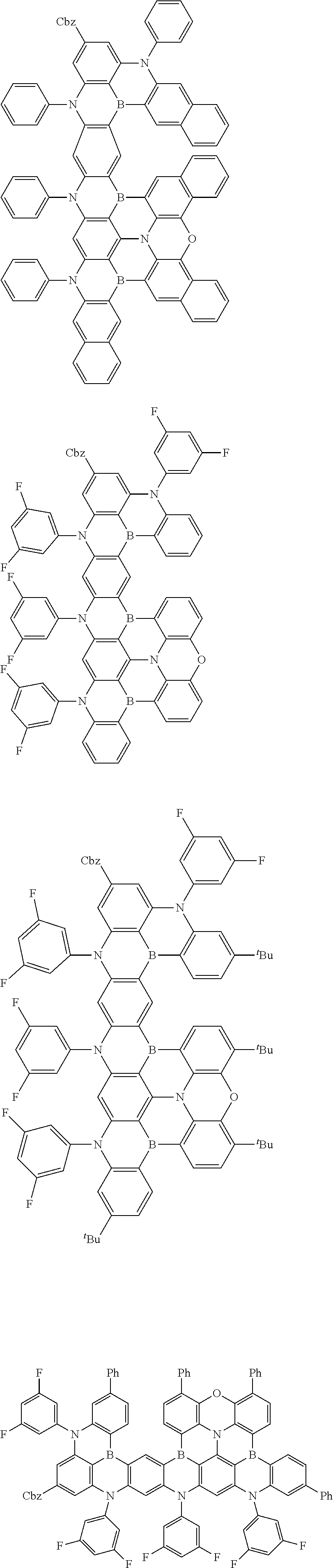

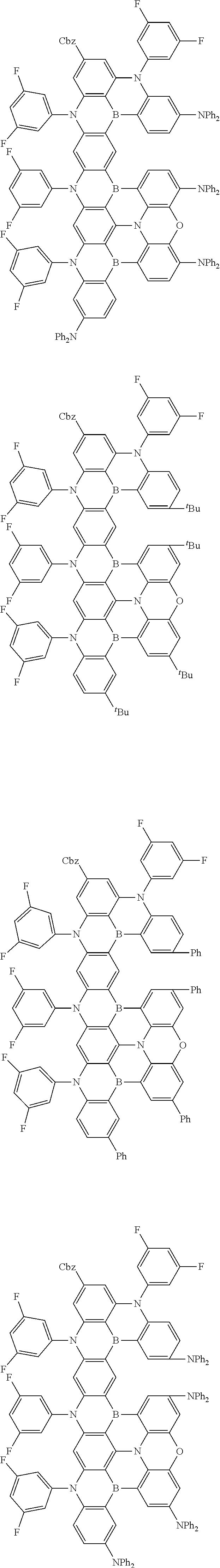

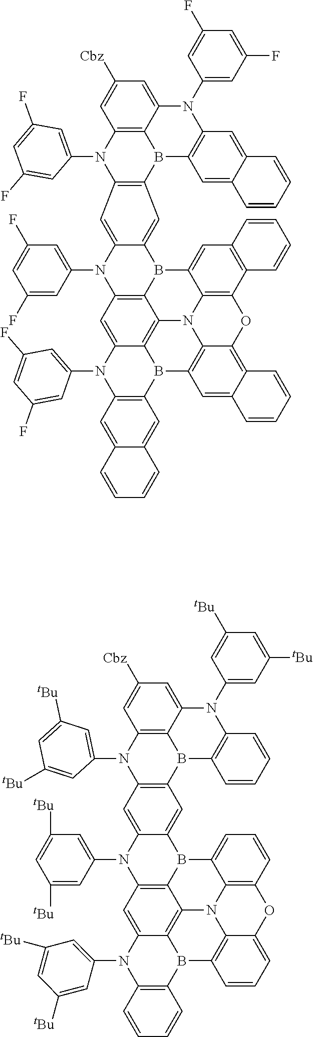 [SMILES: O=C(OCc1ccccc1)c1cc2c3c(c1)N(c1cc(F)cc(F)c1)c1cc4ccccc4cc1B3c1cc3c(cc1N2c1cc(F)cc(F)c1)N(c1cc(F)cc(F)c1)c1cc2c4c5c1B3c1cc3ccccc3c3c1N5c1c(cc5ccccc5c1O3)B4c1cc3ccccc3cc1N2c1cc(F)cc(F)c1 ; CC(C)(C)c1cc(N2c3ccccc3B3c4cc5c(cc4N(c4cc(C(C)(C)C)cc(C(C)(C)C)c4)c4cc(C(=O)OCc6ccccc6)cc2c43)N(c2cc(C(C)(C)C)cc(C(C)(C)C)c2)c2cc3c4c6c2B5c2cccc5c2N6c2c(cccc2B4c2ccccc2N3c2cc(C(C)(C)C)cc(C(C)(C)C)c2)O5)cc(C(C)(C)C)c1]

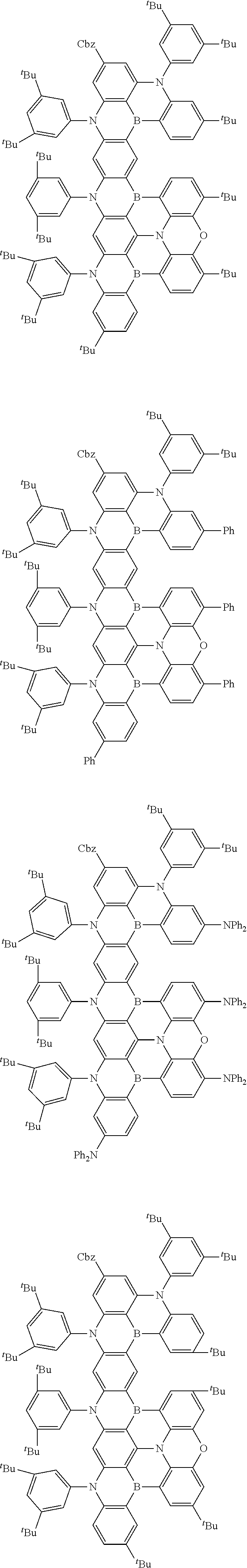

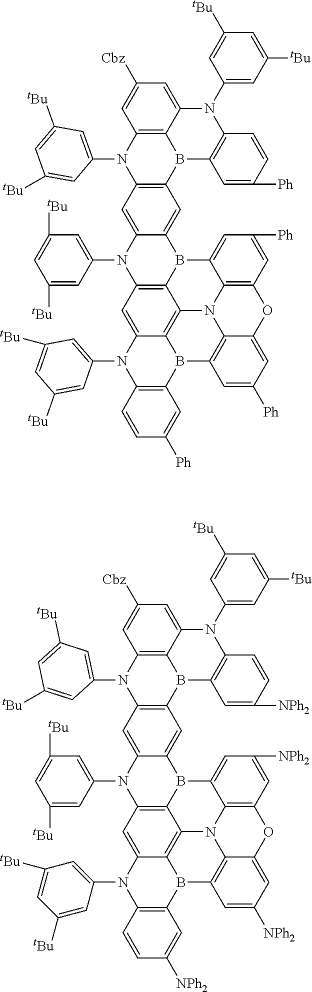

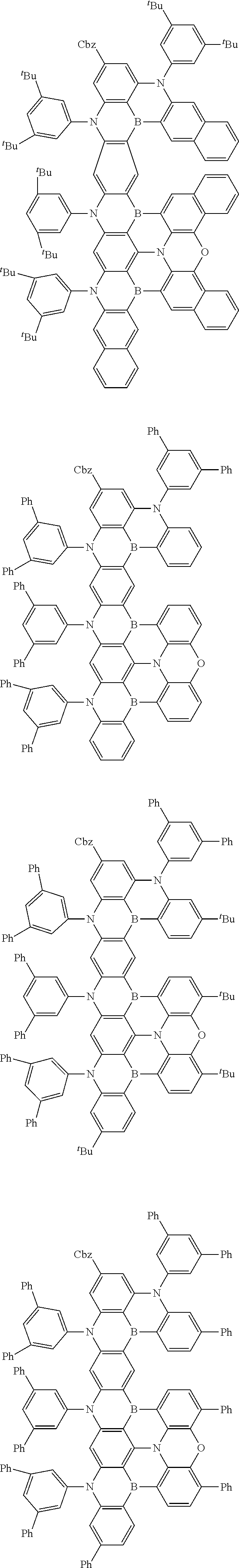

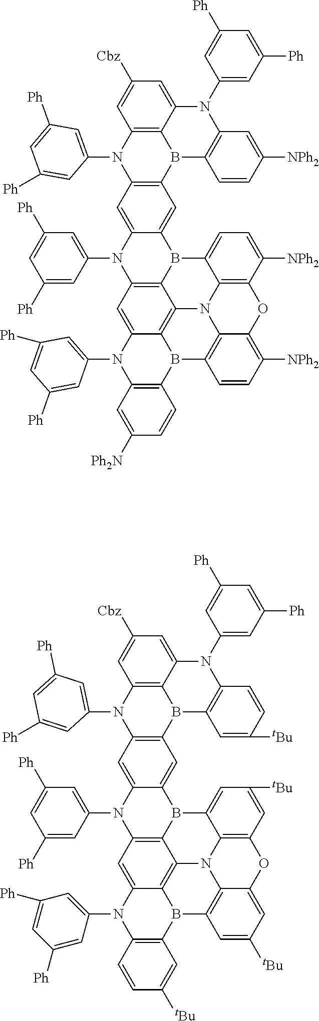

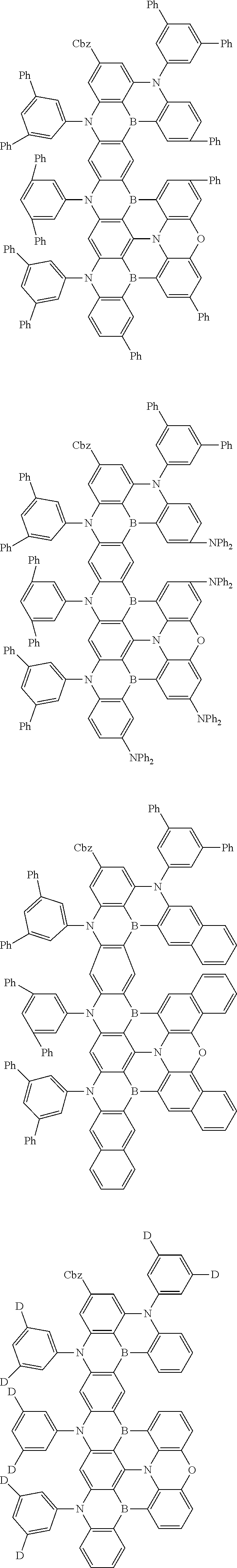

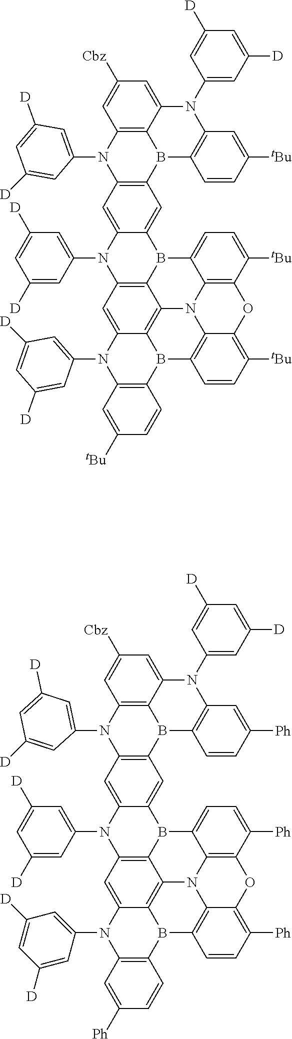 [SMILES: [2H]c1cc([2H])cc(N2c3cc(C(C)(C)C)ccc3B3c4cc5c(cc4N(c4cc([2H])cc([2H])c4)c4cc(C(=O)OCc6ccccc6)cc2c43)N(c2cc([2H])cc([2H])c2)c2cc3c4c6c2B5c2ccc(C(C)(C)C)c5c2N6c2c(ccc(C(C)(C)C)c2O5)B4c2ccc(C(C)(C)C)cc2N3c2cc([2H])cc([2H])c2)c1 ; [2H]c1cc([2H])cc(N2c3cc(-c4ccccc4)ccc3B3c4cc5c(cc4N(c4cc([2H])cc([2H])c4)c4cc(C(=O)OCc6ccccc6)cc2c43)N(c2cc([2H])cc([2H])c2)c2cc3c4c6c2B5c2ccc(-c5ccccc5)c5c2N6c2c(ccc(-c6ccccc6)c2O5)B4c2ccc(-c4ccccc4)cc2N3c2cc([2H])cc([2H])c2)c1]

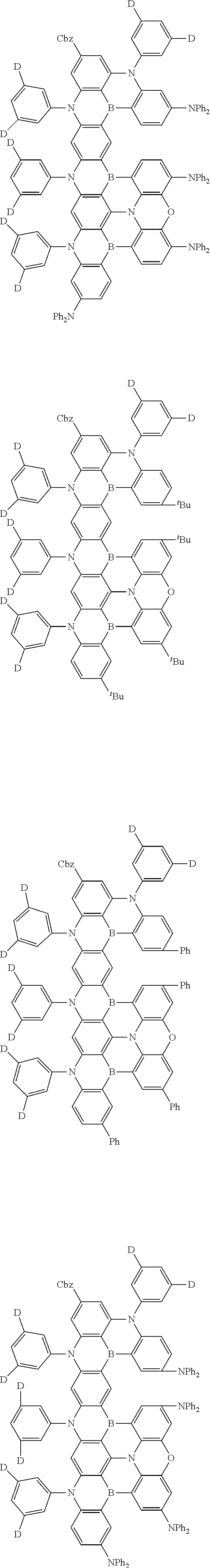

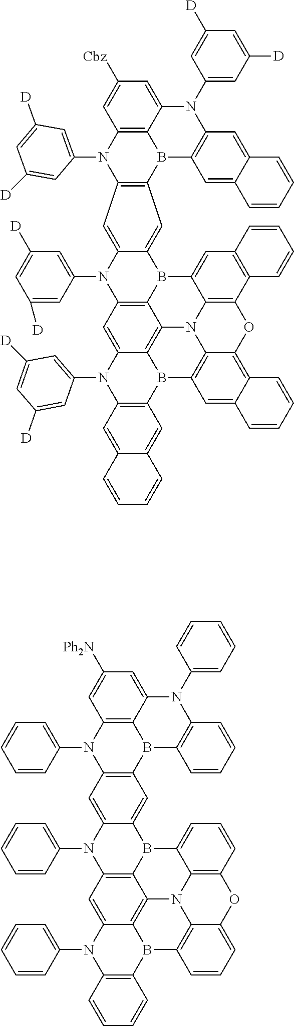

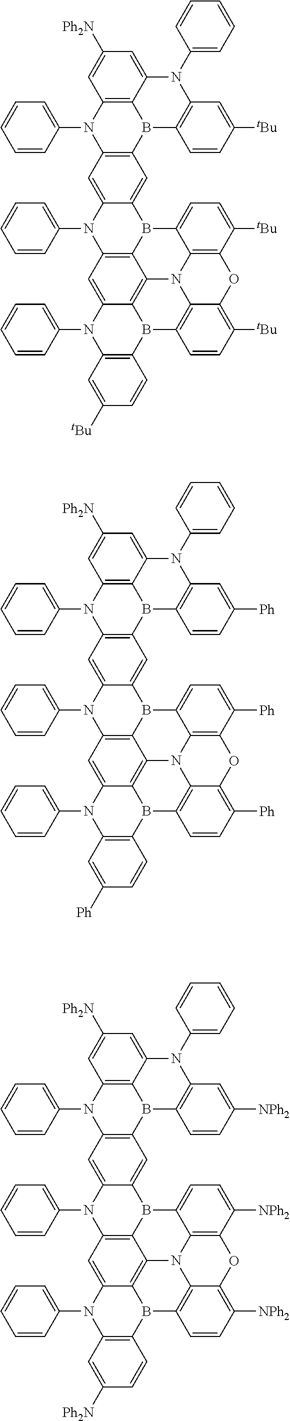

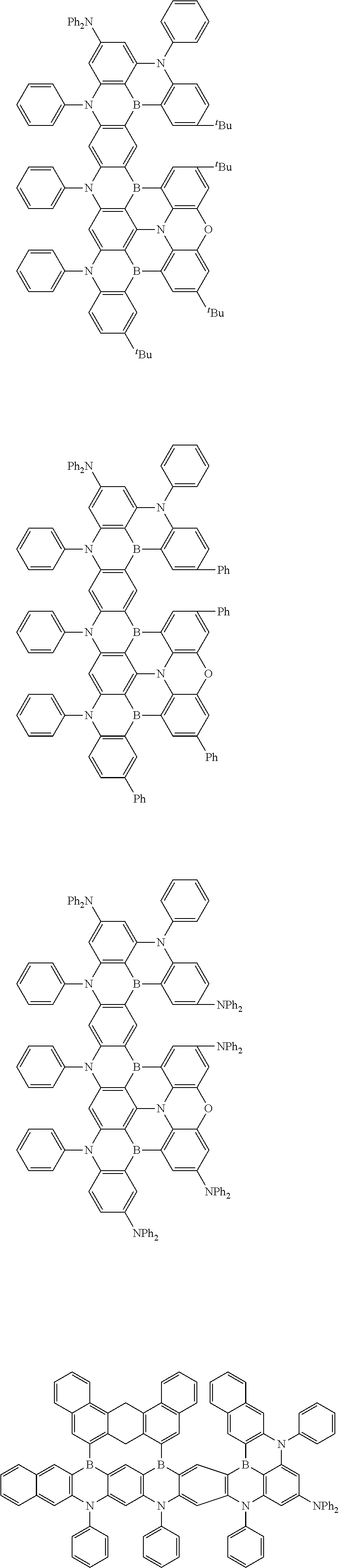

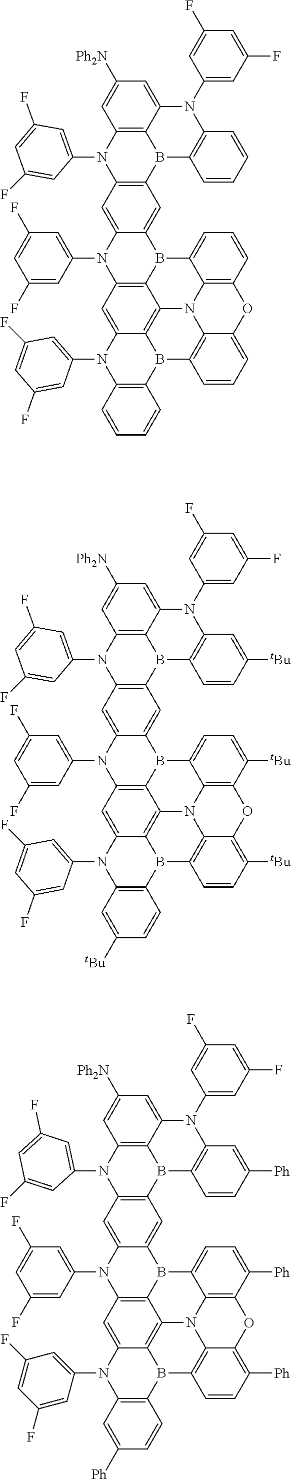

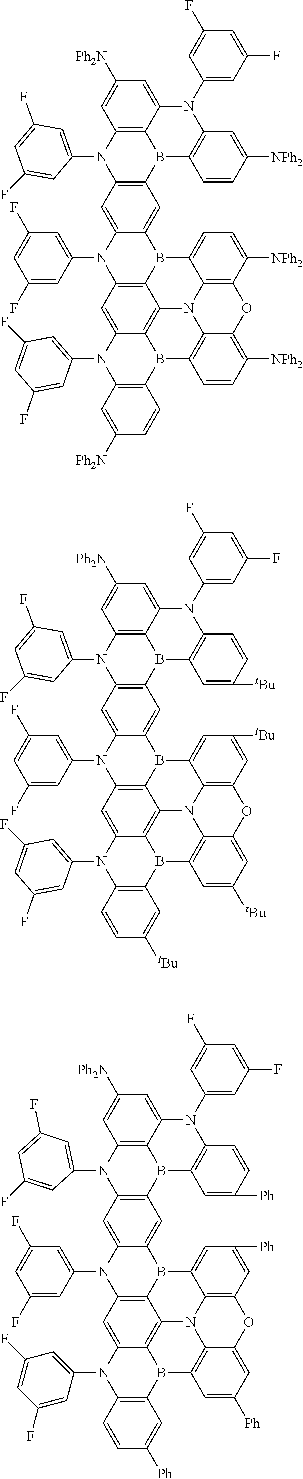

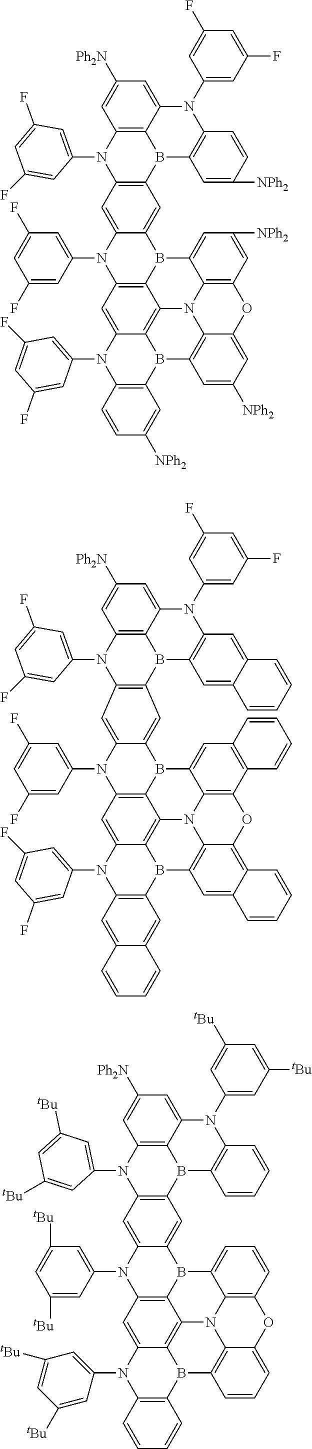

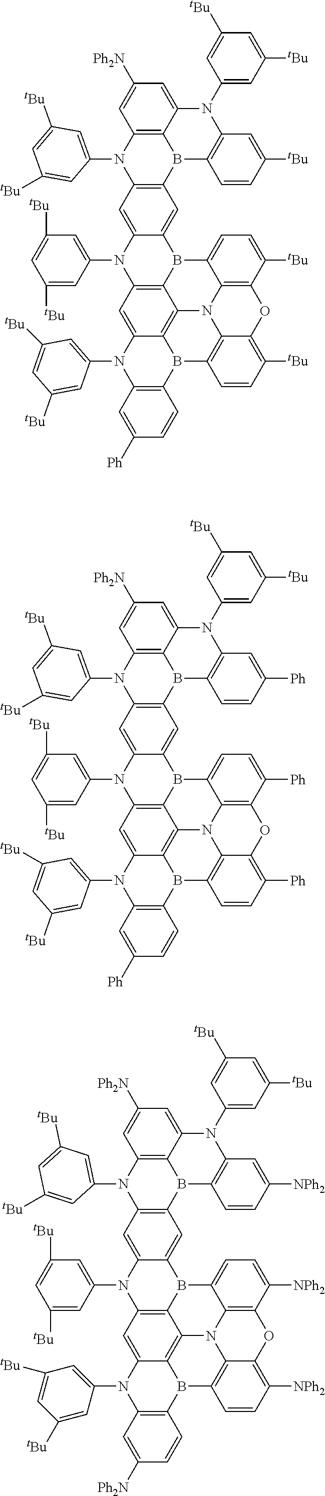

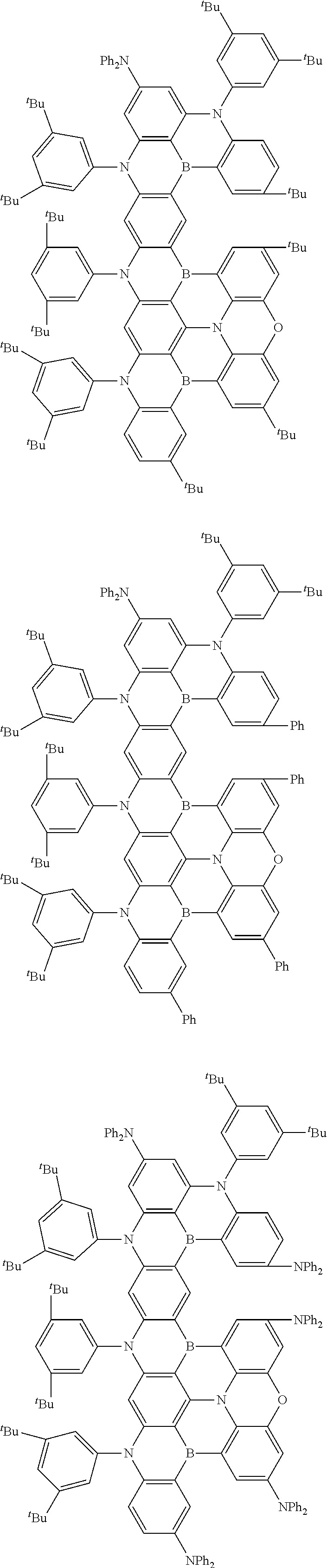

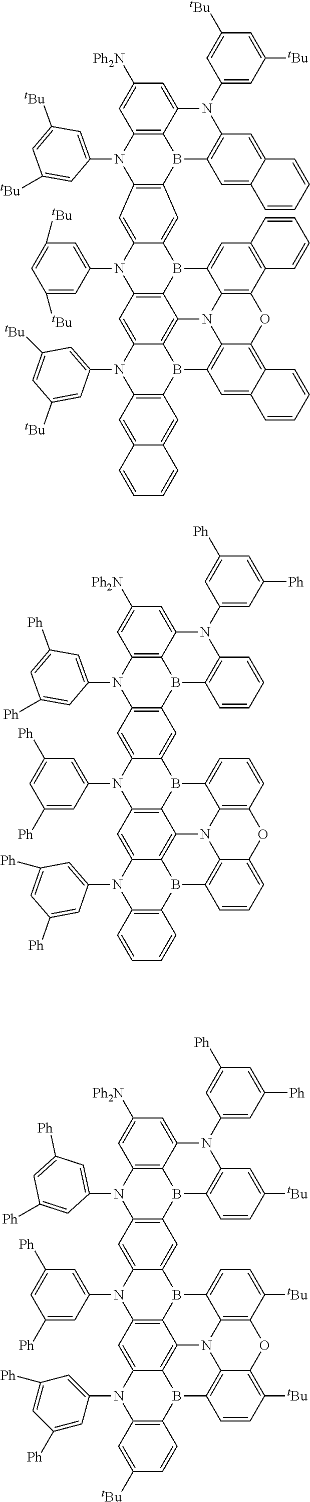

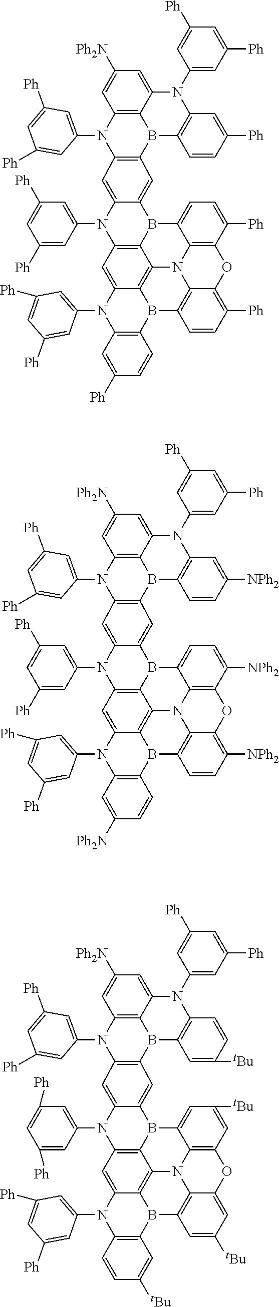

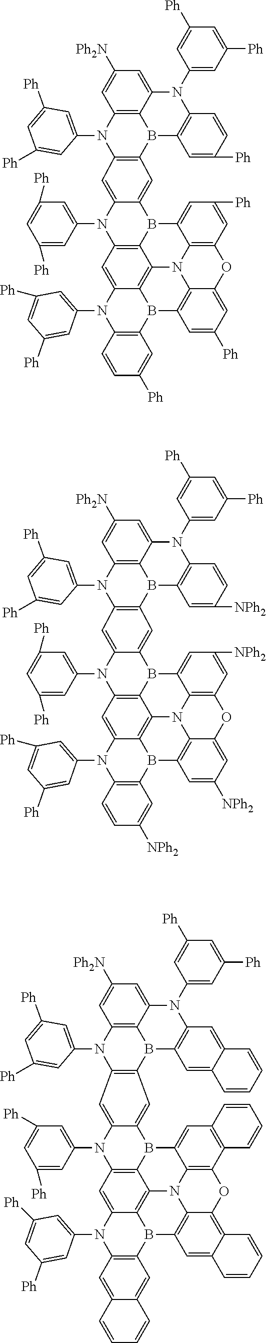

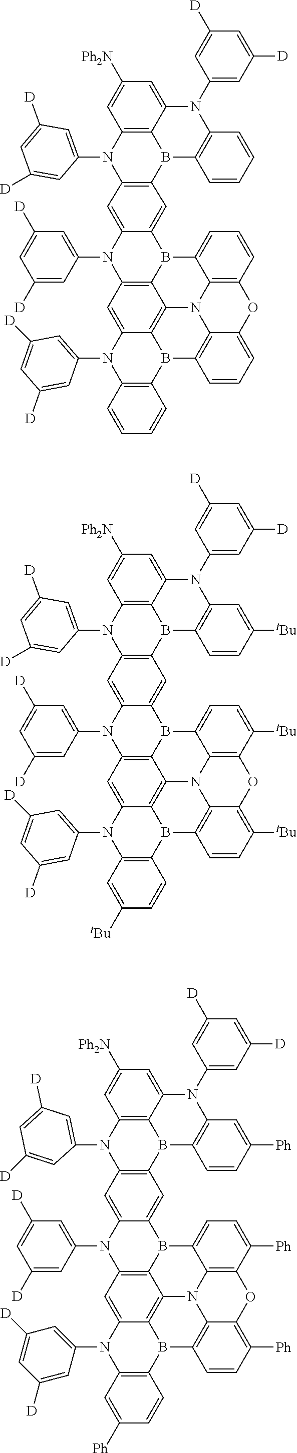

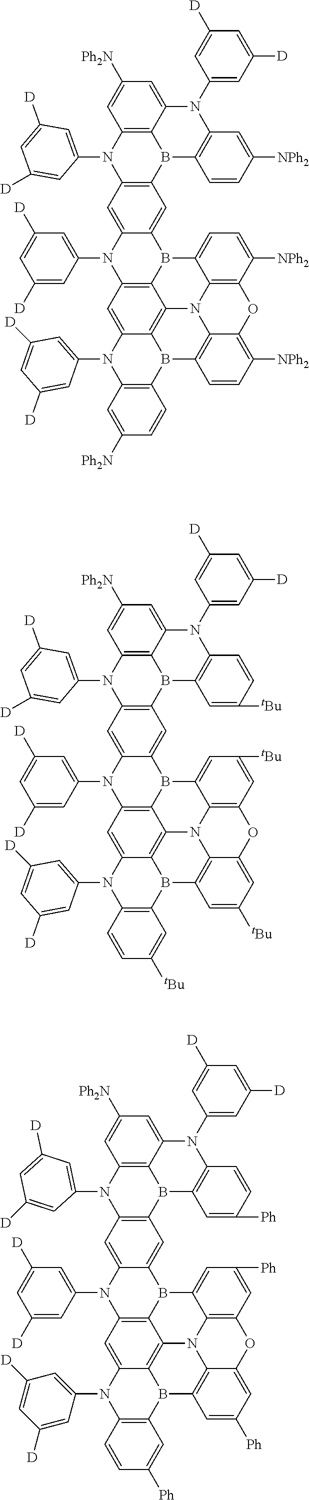

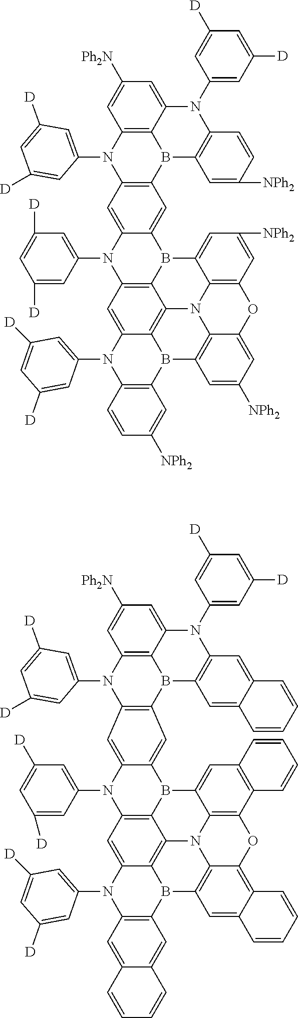

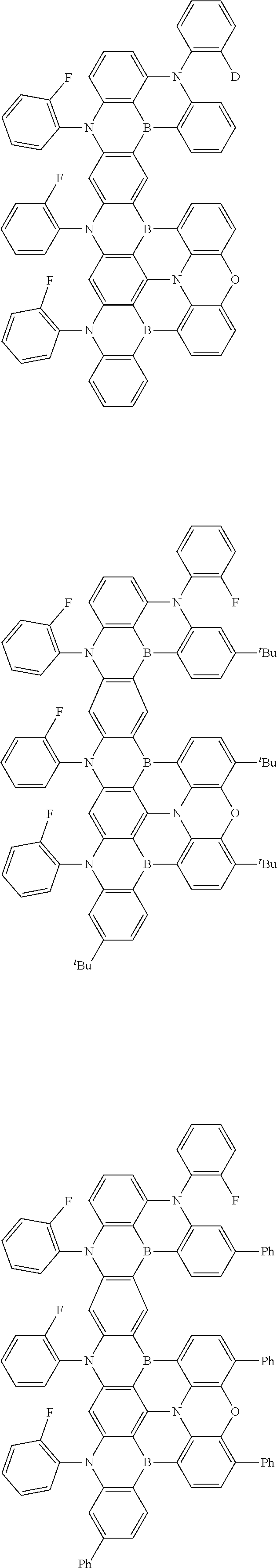 [SMILES: [2H]c1ccccc1N1c2ccccc2B2c3cc4c(cc3N(c3ccccc3F)c3cccc1c32)N(c1ccccc1F)c1cc2c3c5c1B4c1cccc4c1N5c1c(cccc1B3c1ccccc1N2c1ccccc1F)O4 ; CC(C)(C)c1ccc2c(c1)N(c1ccccc1F)c1cccc3c1B2c1cc2c(cc1N3c1ccccc1F)N(c1ccccc1F)c1cc3c4c5c1B2c1ccc(C(C)(C)C)c2c1N5c1c(ccc(C(C)(C)C)c1O2)B4c1ccc(C(C)(C)C)cc1N3c1ccccc1F ; Fc1ccccc1N1c2cc(-c3ccccc3)ccc2B2c3cc4c(cc3N(c3ccccc3F)c3cccc1c32)N(c1ccccc1F)c1cc2c3c5c1B4c1ccc(-c4ccccc4)c4c1N5c1c(ccc(-c5ccccc5)c1O4)B3c1ccc(-c3ccccc3)cc1N2c1ccccc1F]

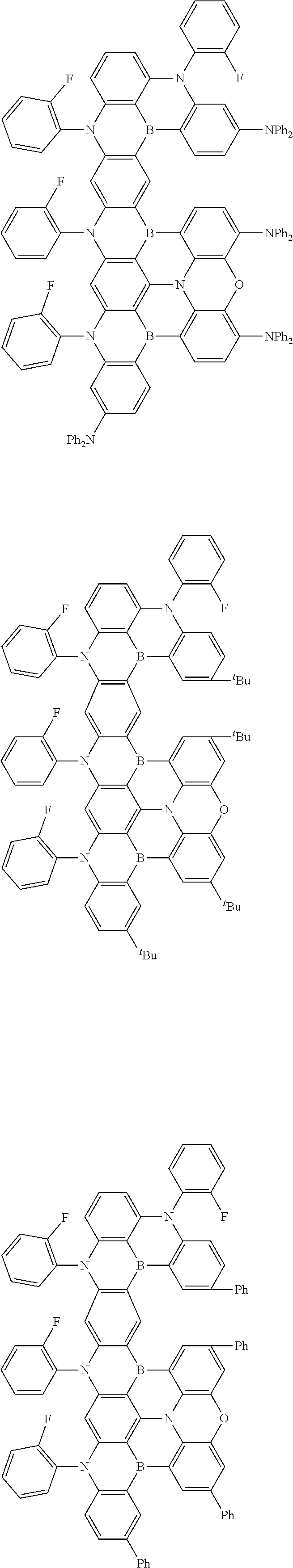

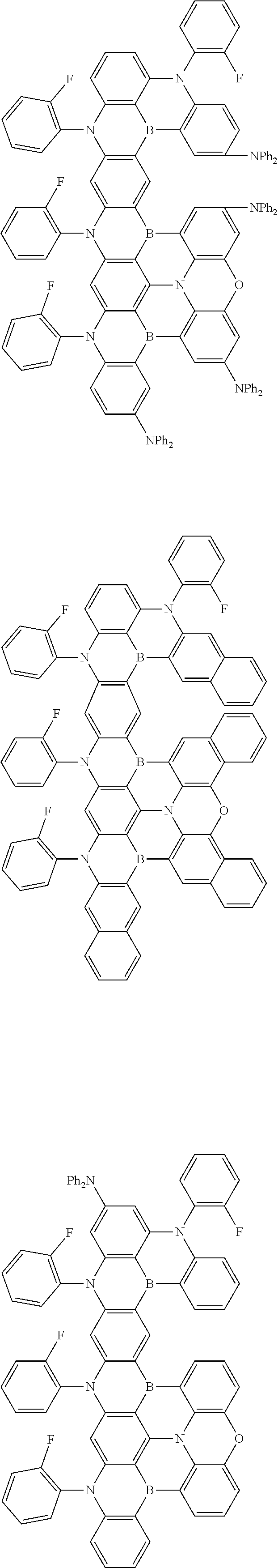

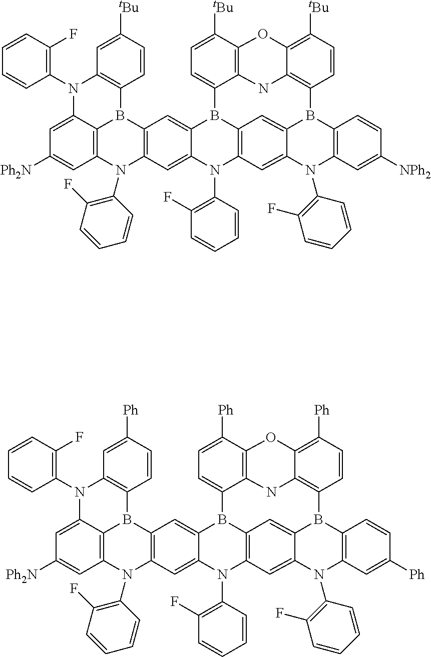

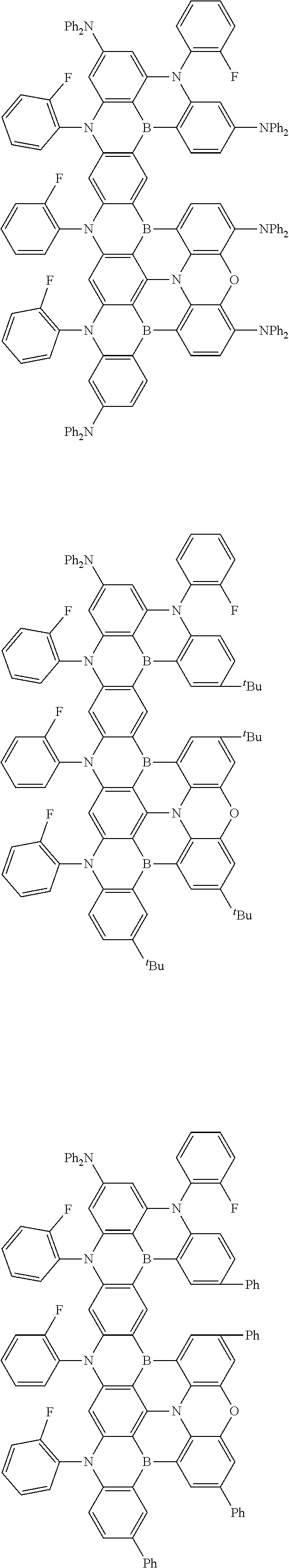

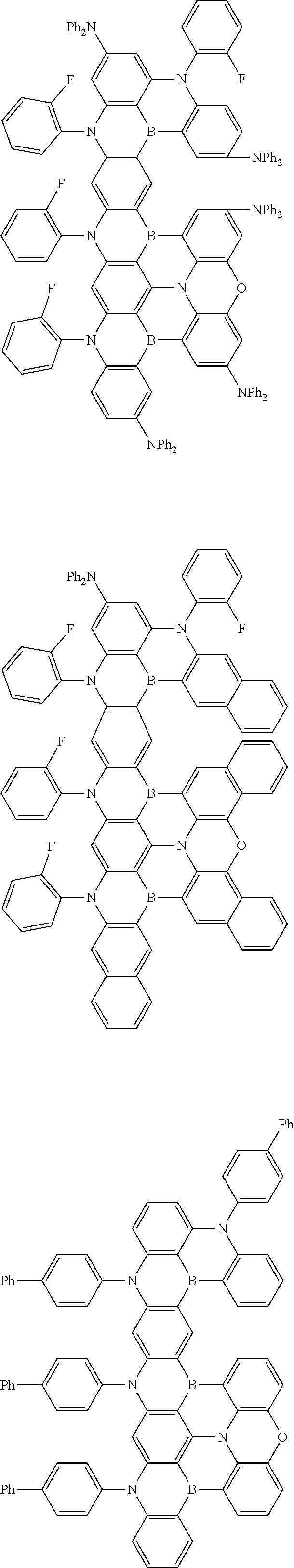

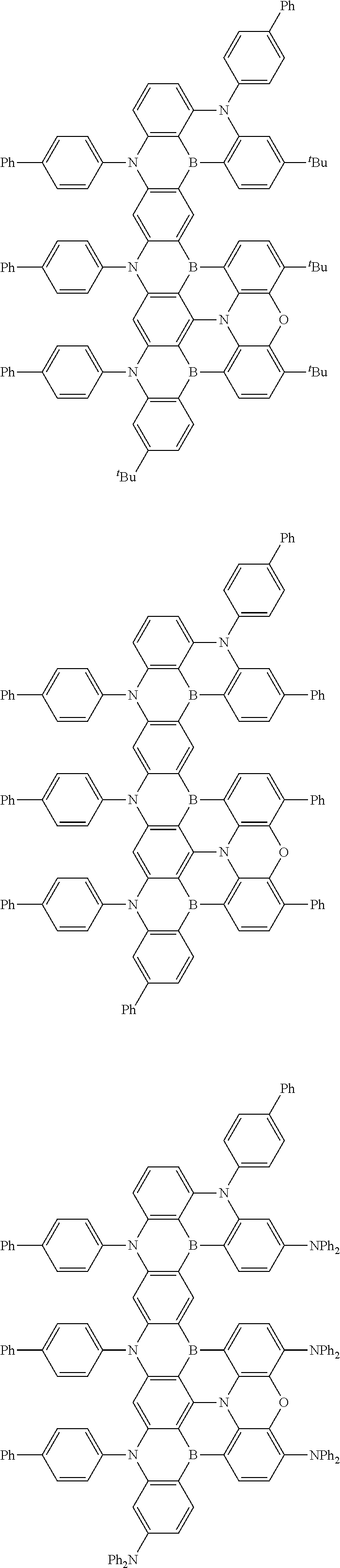

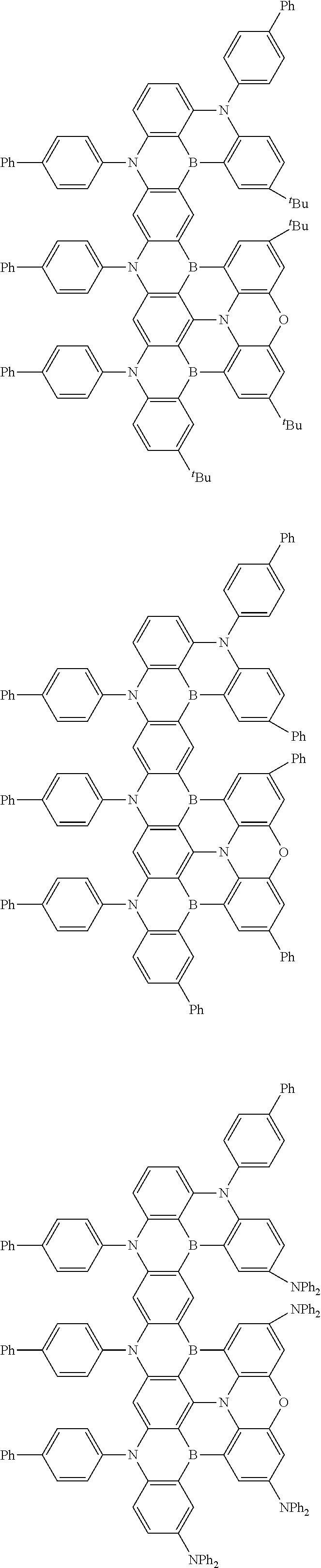

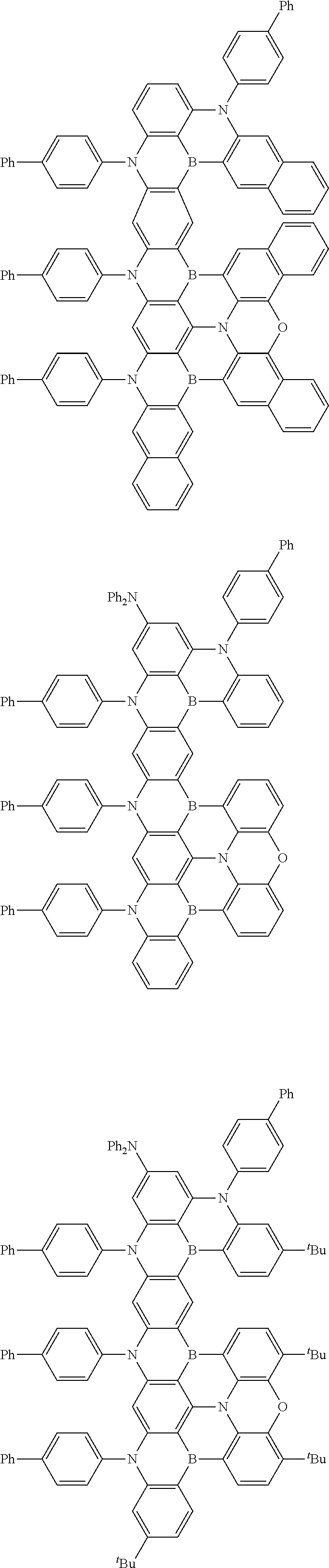

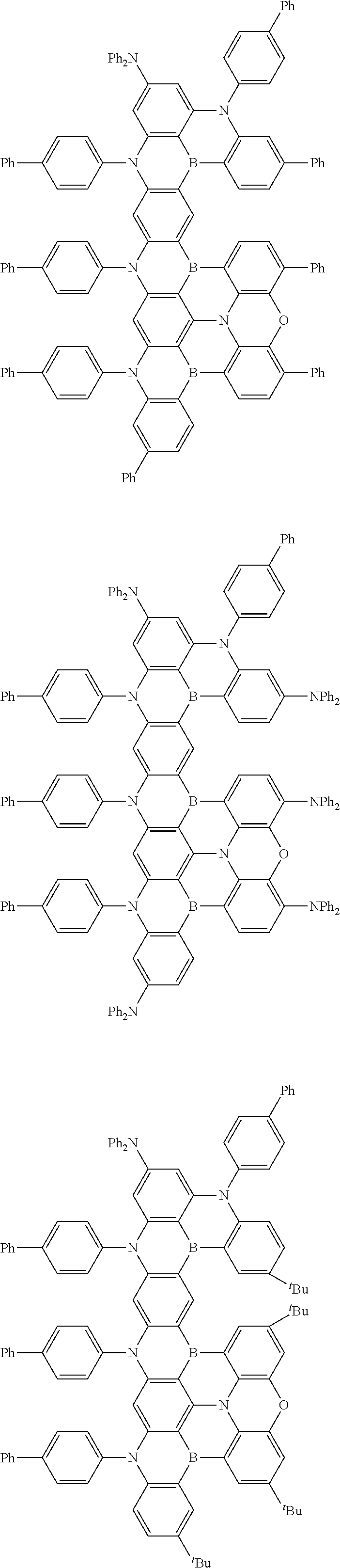

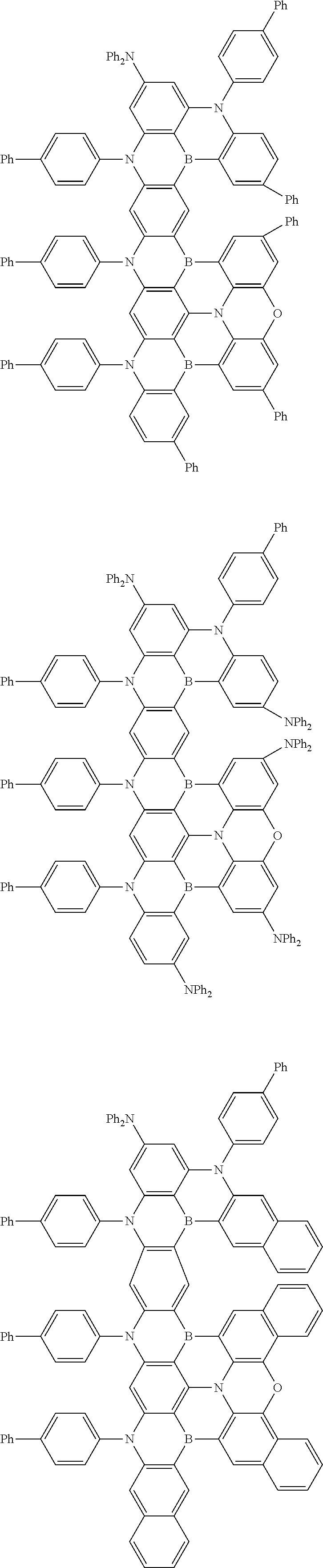

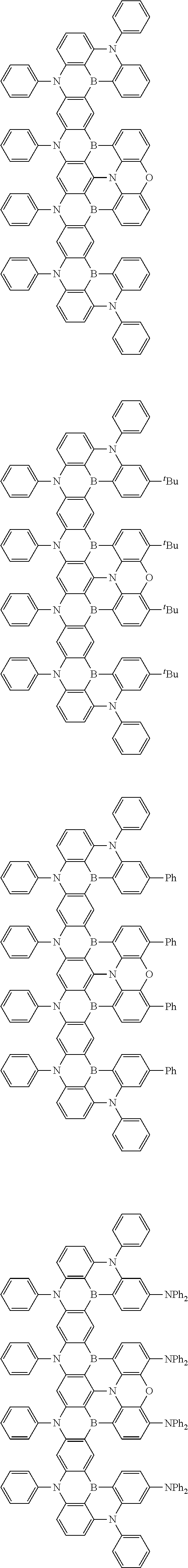

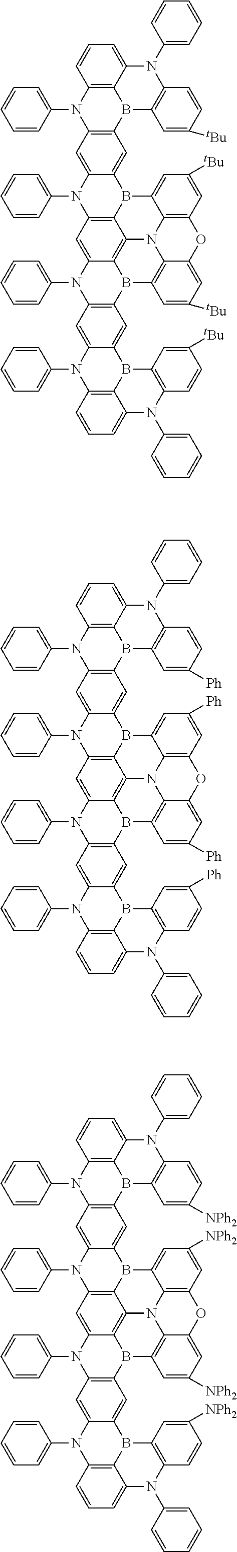

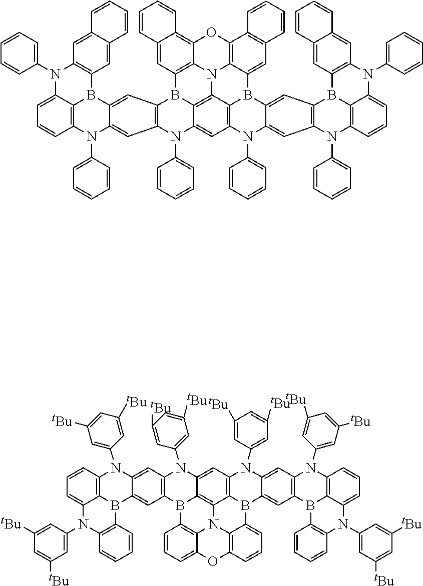 [SMILES: c1ccc(N2c3cc4c(cc3B3c5cc6ccccc6cc5N(c5ccccc5)c5cccc2c53)B2c3cc5ccccc5c5c3N3c6c2c(cc2c6B(c6cc7c(cc6N2c2ccccc2)N(c2ccccc2)c2cccc6c2B7c2cc7ccccc7cc2N6c2ccccc2)c2cc6ccccc6c(c23)O5)N4c2ccccc2)cc1 ; CC(C)(C)c1cc(N2c3ccccc3B3c4cc5c(cc4N(c4cc(C(C)(C)C)cc(C(C)(C)C)c4)c4cccc2c43)N(c2cc(C(C)(C)C)cc(C(C)(C)C)c2)c2cc3c4c6c2B5c2cccc5c2N6c2c(cccc2B4c2cc4c(cc2N3c2cc(C(C)(C)C)cc(C(C)(C)C)c2)N(c2cc(C(C)(C)C)cc(C(C)(C)C)c2)c2cccc3c2B4c2ccccc2N3c2cc(C(C)(C)C)cc(C(C)(C)C)c2)O5)cc(C(C)(C)C)c1]

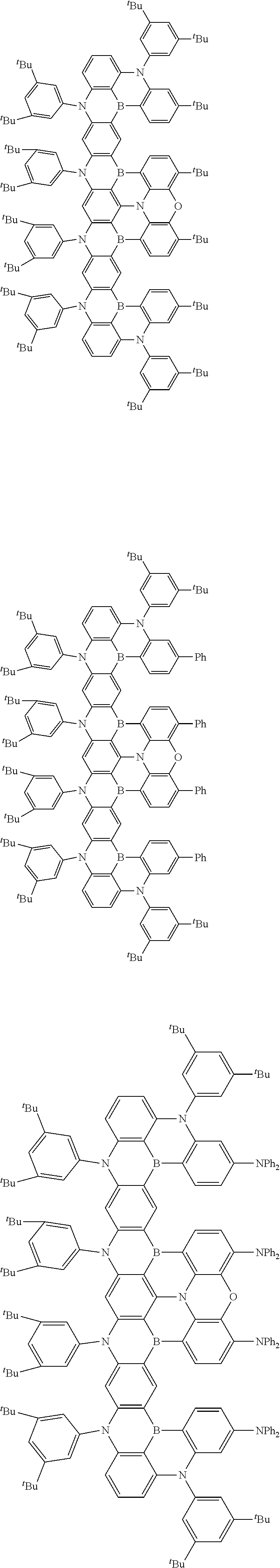

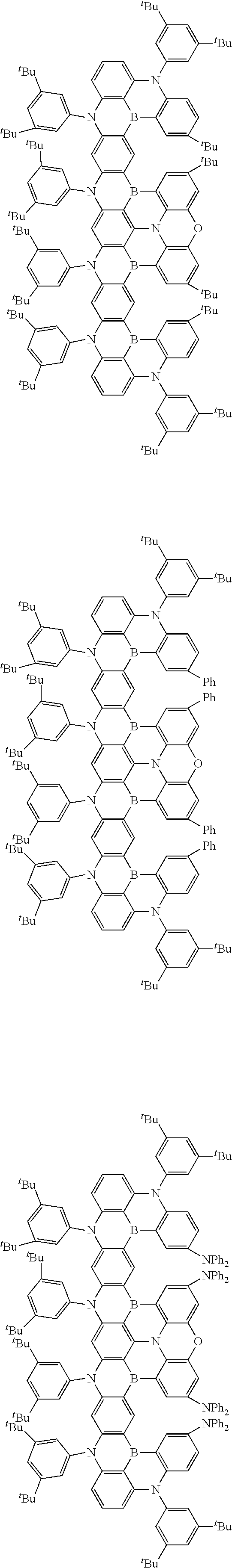

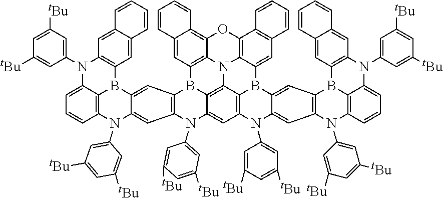 [SMILES: CC(C)(C)c1cc(N2c3cc4c(cc3B3c5cc6ccccc6cc5N(c5cc(C(C)(C)C)cc(C(C)(C)C)c5)c5cccc2c53)B2c3cc5ccccc5c5c3N3c6c2c(cc2c6B(c6cc7c(cc6N2c2cc(C(C)(C)C)cc(C(C)(C)C)c2)N(c2cc(C(C)(C)C)cc(C(C)(C)C)c2)c2cccc6c2B7c2cc7ccccc7cc2N6c2cc(C(C)(C)C)cc(C(C)(C)C)c2)c2cc6ccccc6c(c23)O5)N4c2cc(C(C)(C)C)cc(C(C)(C)C)c2)cc(C(C)(C)C)c1]

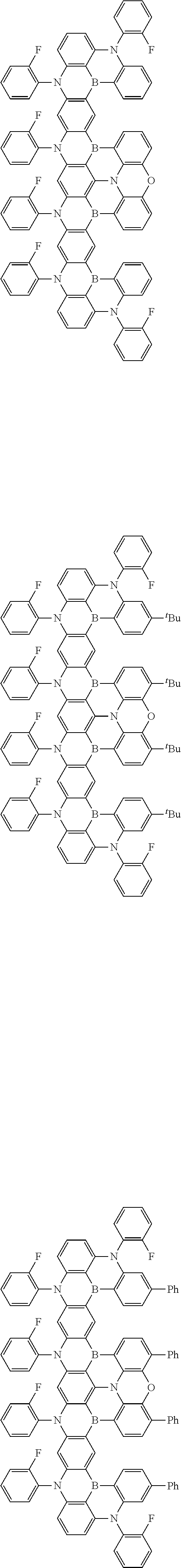

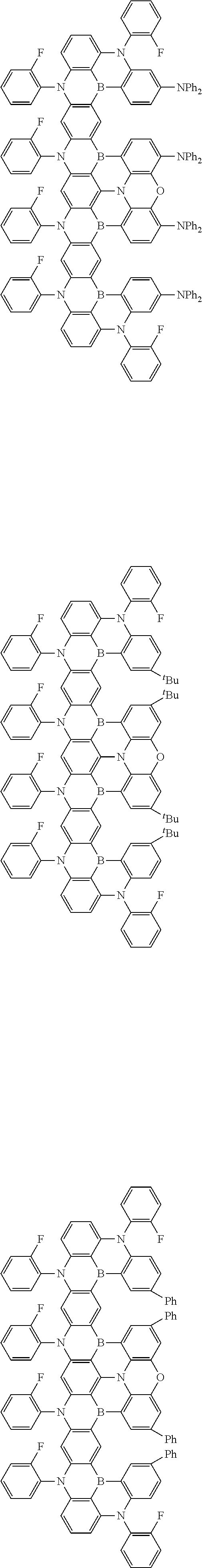

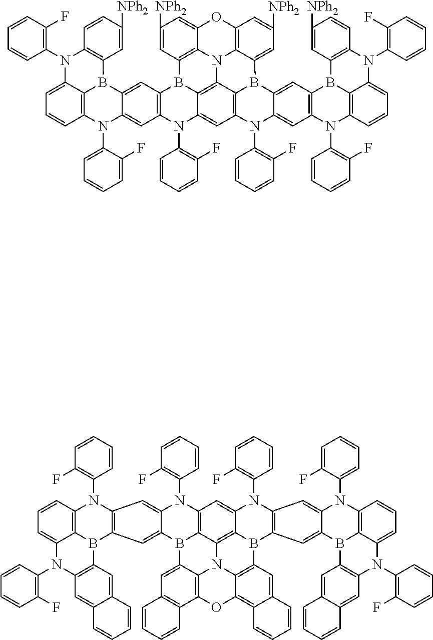

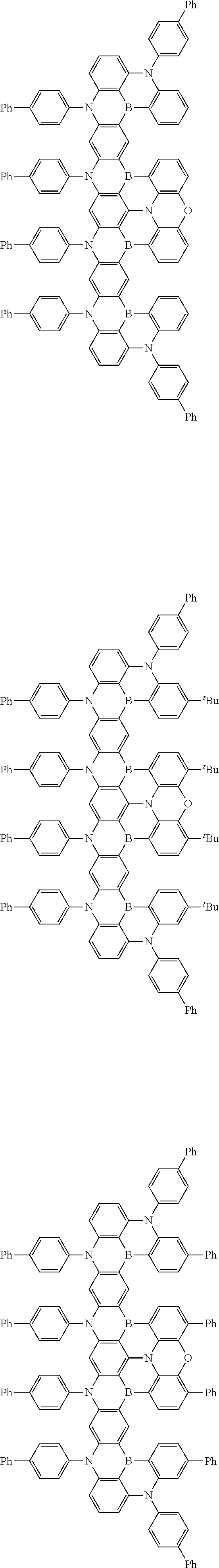

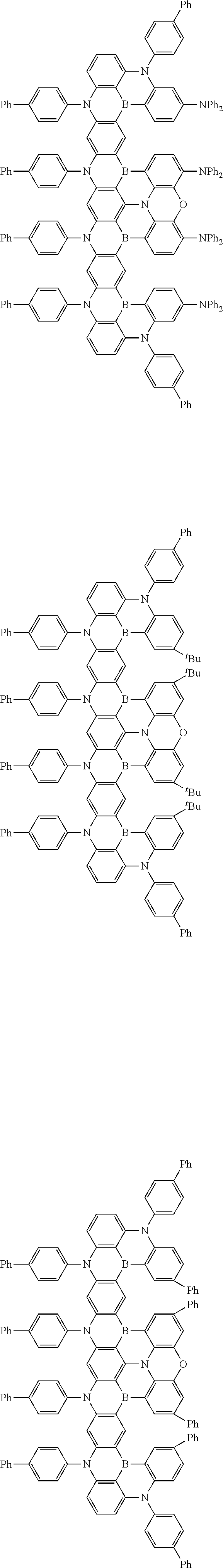

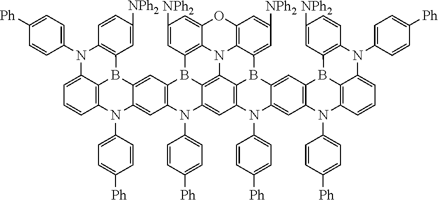

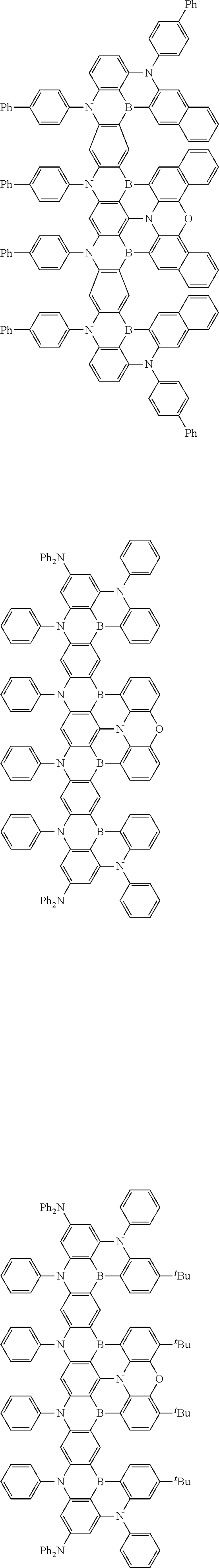

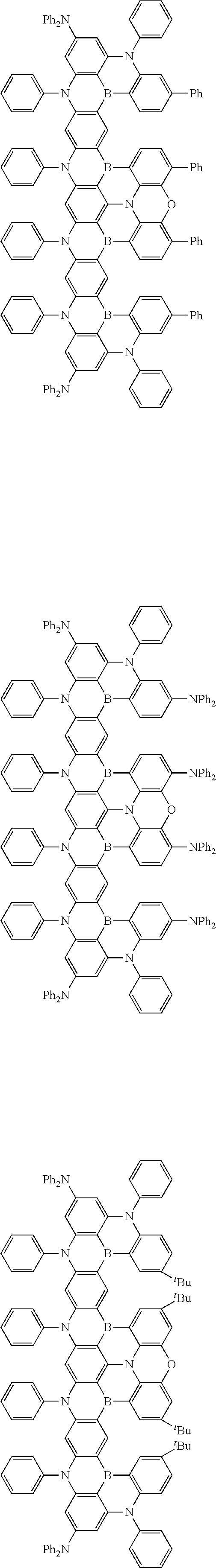

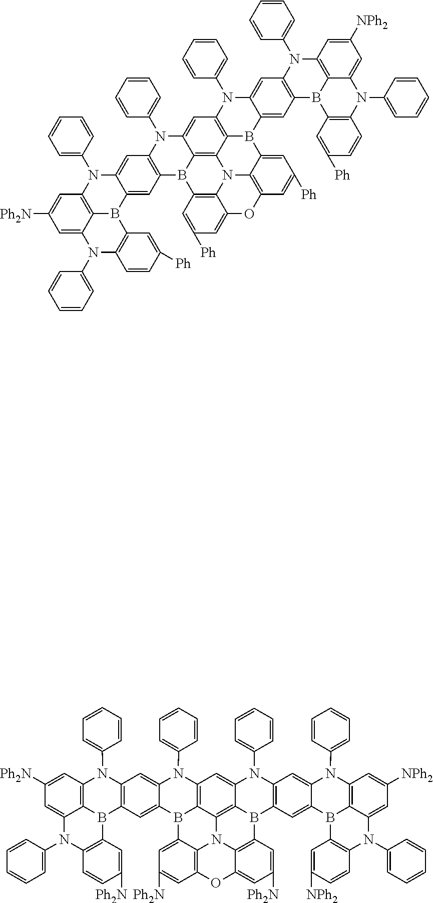

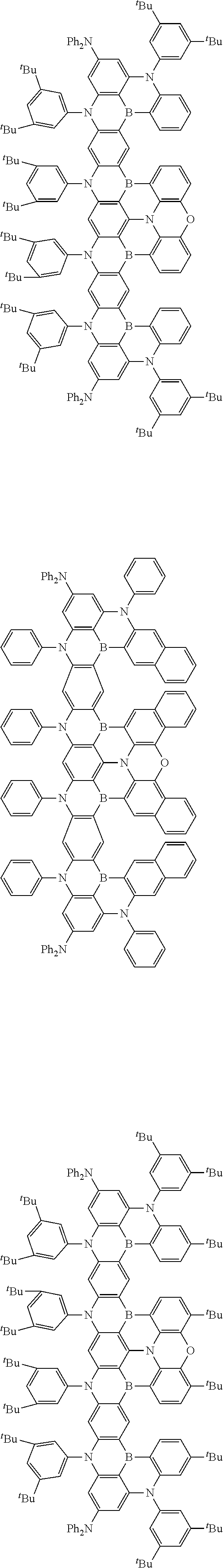

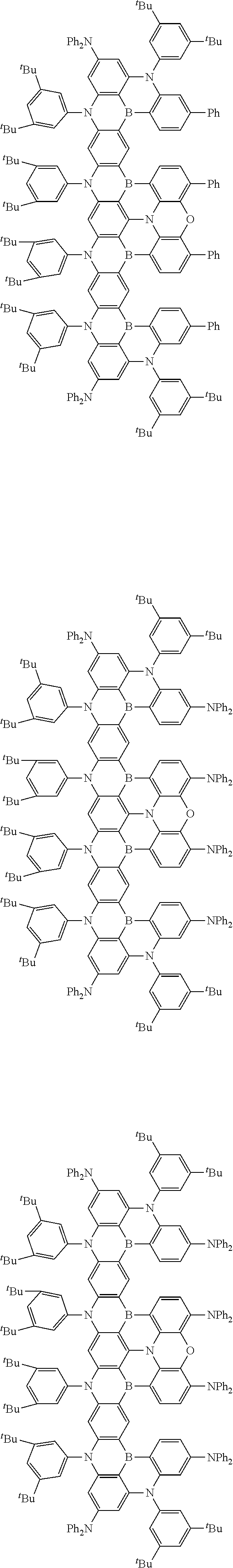

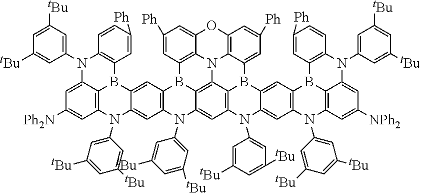

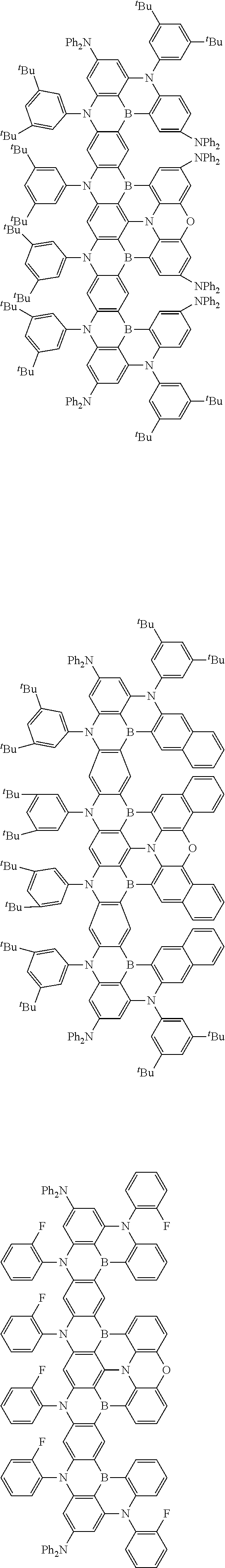

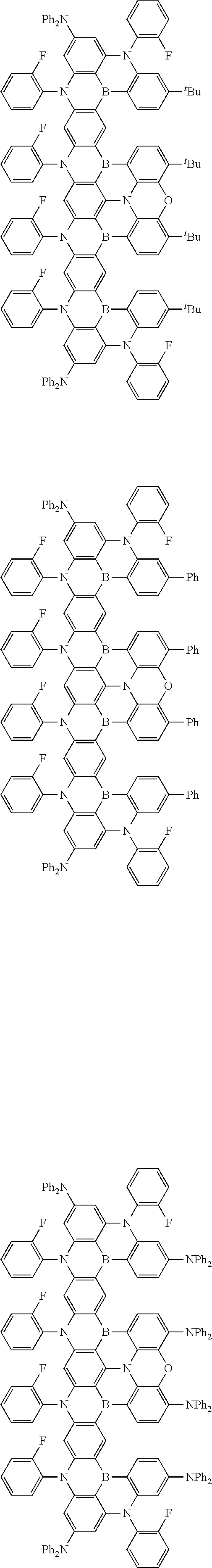

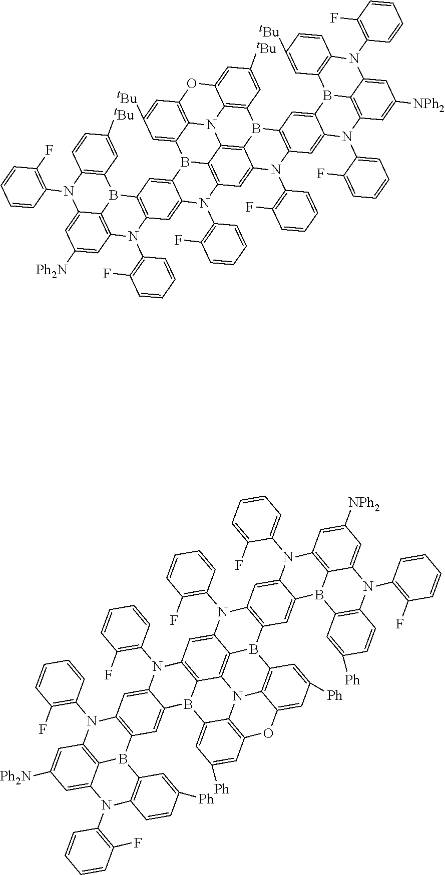

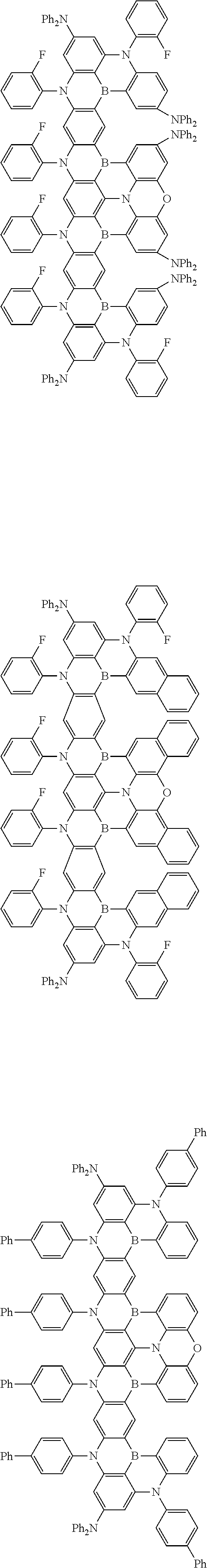

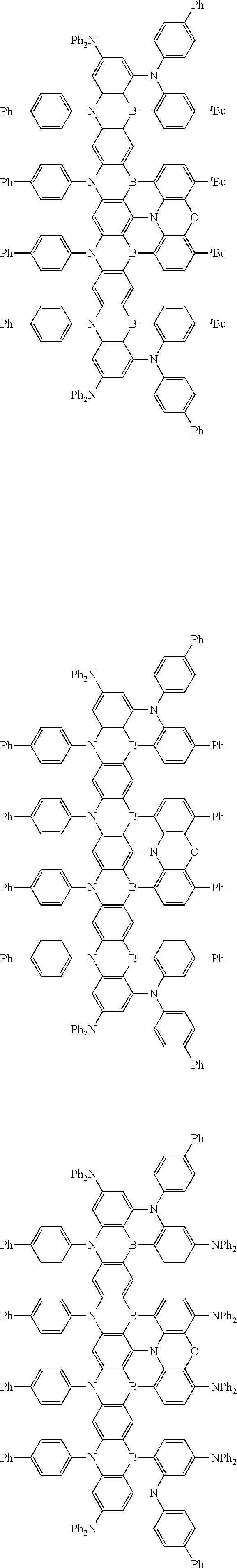

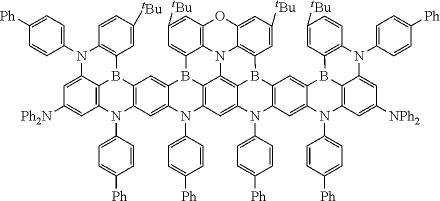

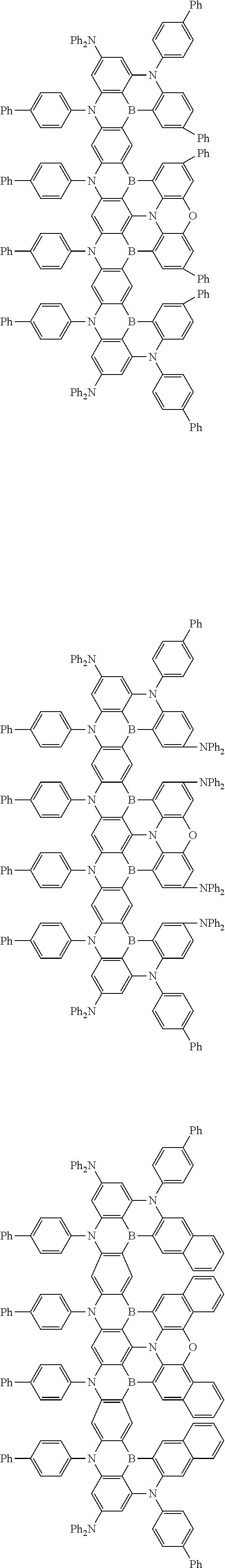

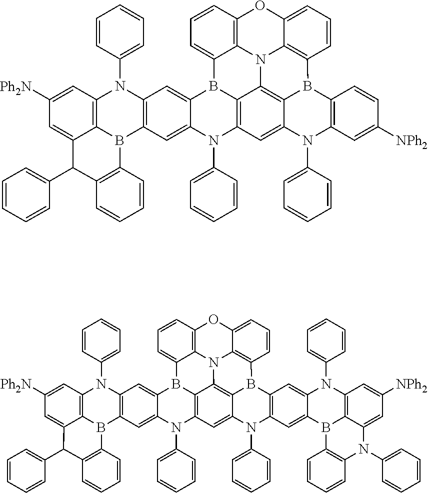

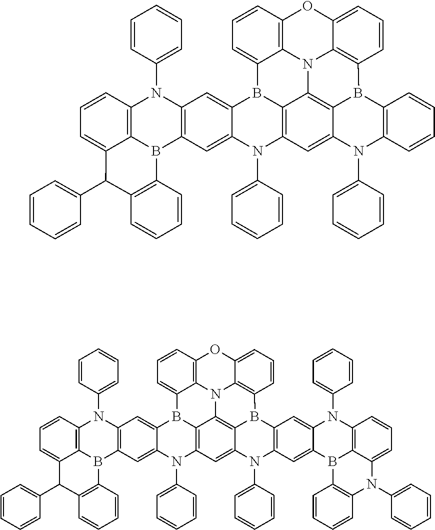 [SMILES: c1ccc(C2c3ccccc3B3c4cc5c(cc4N(c4ccccc4)c4cccc2c43)B2c3cccc4c3N3c6c(cccc6B6c7ccccc7N(c7ccccc7)c7cc(c2c3c76)N5c2ccccc2)O4)cc1 ; c1ccc(C2c3ccccc3B3c4cc5c(cc4N(c4ccccc4)c4cccc2c43)B2c3cccc4c3N3c6c(cccc6B6c7cc8c(cc7N(c7ccccc7)c7cc(c2c3c76)N5c2ccccc2)B2c3ccccc3N(c3ccccc3)c3cccc(c32)N8c2ccccc2)O4)cc1]

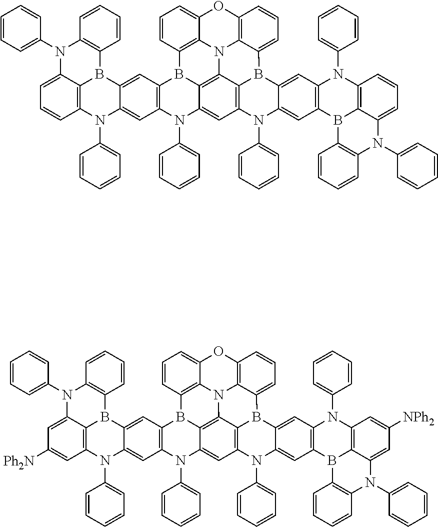

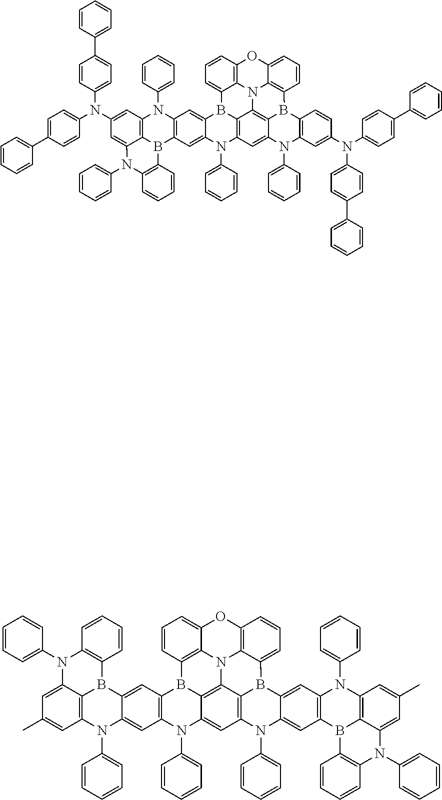 [SMILES: c1ccc(-c2ccc(N(c3ccc(-c4ccccc4)cc3)c3ccc4c(c3)N(c3ccccc3)c3cc5c6c7c3B4c3cccc4c3N7c3c(cccc3B6c3cc6c(cc3N5c3ccccc3)B3c5ccccc5N(c5ccccc5)c5cc(N(c7ccc(-c8ccccc8)cc7)c7ccc(-c8ccccc8)cc7)cc(c53)N6c3ccccc3)O4)cc2)cc1 ; Cc1cc2c3c(c1)N(c1ccccc1)c1cc4c(cc1B3c1ccccc1N2c1ccccc1)N(c1ccccc1)c1cc2c3c5c1B4c1cccc4c1N5c1c(cccc1B3c1cc3c(cc1N2c1ccccc1)N(c1ccccc1)c1cc(C)cc2c1B3c1ccccc1N2c1ccccc1)O4]

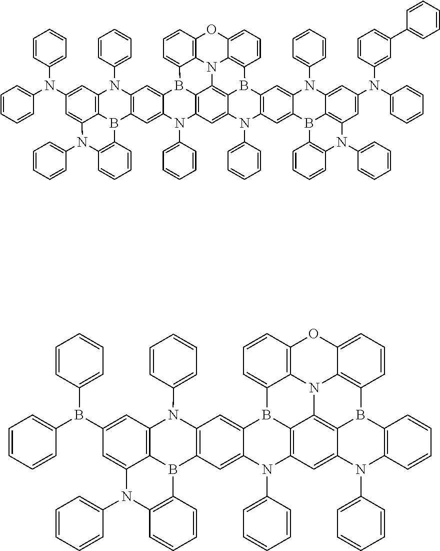 [SMILES: c1ccc(-c2cccc(N(c3ccccc3)c3cc4c5c(c3)N(c3ccccc3)c3cc6c(cc3B5c3ccccc3N4c3ccccc3)N(c3ccccc3)c3cc4c5c7c3B6c3cccc6c3N7c3c(cccc3B5c3cc5c(cc3N4c3ccccc3)B3c4ccccc4N(c4ccccc4)c4cc(N(c7ccccc7)c7ccccc7)cc(c43)N5c3ccccc3)O6)c2)cc1 ; c1ccc(B(c2ccccc2)c2cc3c4c(c2)N(c2ccccc2)c2cc5c(cc2B4c2ccccc2N3c2ccccc2)N(c2ccccc2)c2cc3c4c6c2B5c2cccc5c2N6c2c(cccc2B4c2ccccc2N3c2ccccc2)O5)cc1]

### BRIEF DESCRIPTION OF THE DRAWINGS

FIG. 1 illustrates an emission spectrum of example 1 (1% by weight) in PMMA.

FIG. 2 illustrates an emission spectrum of example 2 (1% by weight) in PMMA.

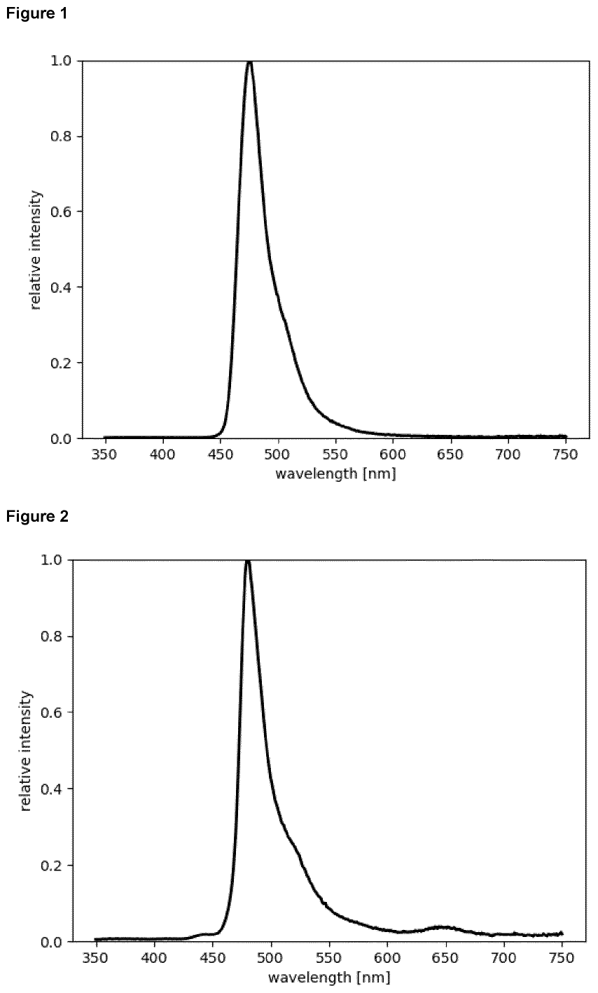

1.-15. (canceled)

16. An organic molecule, comprising
a first chemical moiety comprising a structure of Formula I: 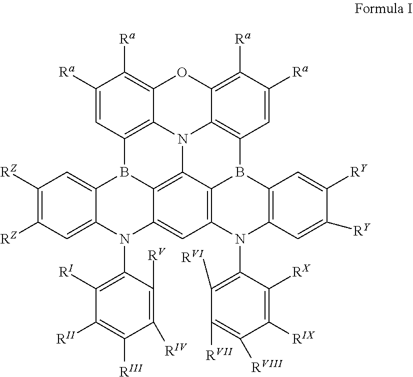
and
one or two second chemical moieties comprising a structure of Formula II: 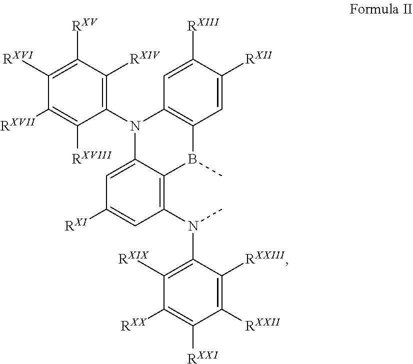
wherein
R^{Z} indicates a binding site of a single bond linking the first chemical moiety to the second moiety;
R^{Y} indicates a binding site of a single bond linking the first chemical moiety to the second moiety or is R^{a};
the dashed lines “ [symbol] ” represent binding sites of the first chemical moiety to the second chemical moiety;
R^{a} is at each occurrence independently selected from the group consisting of:
hydrogen; deuterium; N(R⁵)₂; OR⁵; SR⁵; CF₃; CN; F; Cl; Br; I;
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁴ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₃-C₅₇-heteroaryl,
which is optionally substituted with one or more substituents R⁵;
R⁵ is at each occurrence independently selected from the group consisting of:
hydrogen; deuterium; F; Cl; Br; I;
C₁-C₁₂-alkyl,
wherein optionally one or more hydrogen atoms are independently substituted by R⁶;
C₆-C₁₈-aryl,
wherein optionally one or more hydrogen atoms are independently substituted by R⁶; and
C₃-C₁₅-heteroaryl,
wherein optionally one or more hydrogen atoms are independently substituted by R⁶;
R⁶ is at each occurrence independently selected from the group consisting of:
hydrogen; deuterium; F; Cl; Br; I; C₁-C₁₂-alkyl;
C₆-C₁₈-aryl,
wherein optionally one or more hydrogen atoms are independently substituted by C₁-C₅-alkyl substituents; and
C₃-C₁₅-heteroaryl,
wherein optionally one or more hydrogen atoms are independently substituted by C₁-C₅-alkyl substituents;
R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are at each occurrence independently selected from the group consisting of:
hydrogen; deuterium; N(R⁴)₂; OR⁴; SR⁴; Si(R⁴)₃; B(OR⁴)₂; OSO₂R⁴; CF₃; CN; F; Cl; Br; I;
C₁-C₄₀-alkyl,
which is optionally substituted with one or more substituents R⁴ and
wherein one or more non-adjacent CH₂-groups are optionally substituted by R⁴C═CR⁴, C=C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-alkoxy,
which is optionally substituted with one or more substituents R⁴ and wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-thioalkoxy,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkenyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkynyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₆-C₆₀-aryl,
which is optionally substituted with one or more substituents R⁴; and
C₃-C₅₇-heteroaryl,
which is optionally substituted with one or more substituents R⁴;
R⁴ is at each occurrence independently from each other selected from the group consisting of:
hydrogen; deuterium; F; Cl; Br; I; OPh; SPh; CF₃; CN; Si(C₁-C₅-alkyl)₃; Si(Ph)₃;
C₁-C₅-alkyl,
wherein optionally one or more hydrogen atoms are independently substituted by deuterium, halogen, CN, or CF₃;
C₁-C₅-alkoxy,
wherein optionally one or more hydrogen atoms are independently substituted by deuterium, halogen, CN, or CF₃;
C₁-C₅-thioalkoxy,
wherein optionally one or more hydrogen atoms are independently substituted by deuterium, halogen, CN, or CF₃;
C₂-C₅-alkenyl,
wherein optionally one or more hydrogen atoms are independently substituted by deuterium, halogen, CN, or CF₃;
C₂-C₅-alkynyl,
wherein optionally one or more hydrogen atoms are independently substituted by deuterium, halogen, CN, or CF₃;
C₆-C₁₈-aryl,
which is optionally substituted with one or more substituents R⁵;
C₃-C₁₇-heteroaryl,
which is optionally substituted with one or more substituents R⁵;
N(C₆-C₁₈-aryl)₂;
N(C₃-C₁₇-heteroaryl)₂; and
N(C₃-C₁₇-heteroaryl)(C₆-C₁₈-aryl),
wherein substituents R^{a} positioned adjacent to each other are optionally bonded to each other and form an aryl ring, which is optionally substituted with one or more substituents selected from the group consisting of C₁-C₅-alkyl, deuterium, F, Cl, Br, I, CN and CF₃.

17. The organic molecule according to claim 16, comprising a structure of Formula II-a:

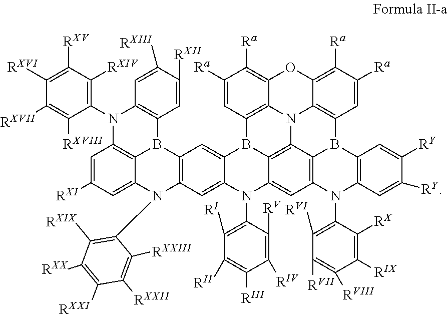

18. The organic molecule according to claim 16, wherein the second chemical moiety consists of a structure of Formula II-0a, Formula II-0b, or Formula II-0c:

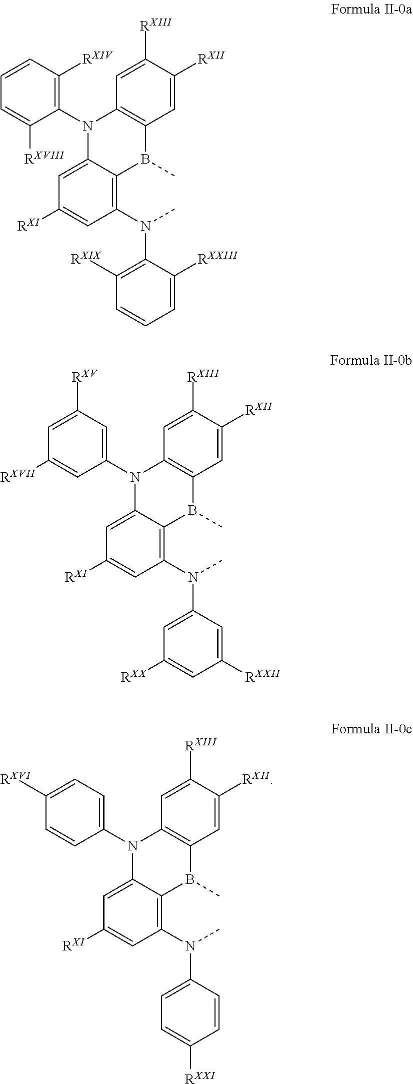

19. The organic molecule according to claim 16, wherein the second chemical moiety consists of a structure of Formula II-I:

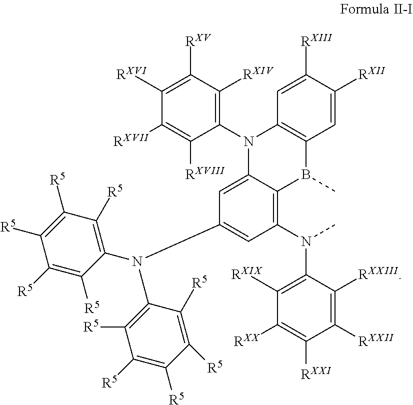

20. The organic molecule according to claim 16, wherein R^{Y} indicates the binding site of a single bond linking the first chemical moiety to the second moiety.

21. The organic molecule according to claim 16, wherein R^{a} is independently selected from the group consisting of:
hydrogen, Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph, A and
N(Ph)₂, which is optionally substituted with one or more substituents independently from each other selected from the group consisting of Me, ⁱPr, ^{t}Bu, F and Ph.

22. The organic molecule according to claim 16, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are independently selected from the group consisting of:
hydrogen, Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph, and
N(Ph)₂, which is optionally substituted with one or more substituents independently from each other selected from the group consisting of Me, ⁱPr, ^{t}Bu, F and Ph.

23. The organic molecule according to claim 16, wherein R_{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, R^{XVIII}, R^{XIX}, R^{XX}, R^{XXI}, R^{XXII}, and R^{XXII} are independently selected from the group consisting of:
hydrogen, Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph, and
triazinyl, which is optionally substituted with one or more substituents independently from each other selected from the group consisting of Me, ⁱPr, ^{t}Bu, CN, CF₃, F and Ph.

24. An optoelectronic device comprising the organic molecule according to claim 16 as a luminescent emitter.

25. The optoelectronic device according to claim 24, wherein the optoelectronic device is at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

26. A composition, comprising:
(a) the organic molecule according to claim 16 as a luminescent emitter and/or a host, and
(b) an emitter and/or a host material, which differ from the organic molecule, and
(c) optionally, a dye and/or a solvent.

27. An optoelectronic device, comprising the composition according to claim 11.

28. The optoelectronic device according to claim 27, wherein the optoelectronic device is at least one selected from the group consisting of organic light-emitting diodes (OLED), light-emitting electrochemical cells, OLED-sensors, organic diodes, organic solar cells, organic transistors, organic field-effect transistors, organic lasers, and down-conversion elements.

29. The optoelectronic device according to claim 24, comprising:
a substrate,
an anode, and
a cathode, wherein the anode or the cathode is disposed on the substrate, and
a light-emitting layer between the anode and the cathode and comprising the organic molecule.

30. A method for producing an optoelectronic device, the method comprising depositing the organic molecule according to claim 16 by a vacuum evaporation method and/or a solution deposition method.

31. A method for producing an optoelectronic device, the method comprising depositing the composition according to claim 26 by a vacuum evaporation method and/or a solution deposition method.

32. The optoelectronic device according to claim 27, comprising:
a substrate,
an anode, and
a cathode, wherein the anode or the cathode is on the substrate, and
a light-emitting layer between the anode and the cathode and comprising the composition.

33. An optoelectronic device, comprising a layer formed from the composition according to claim 26, wherein the optoelectronic device is at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

34. The optoelectronic device according to claim 33, comprising:
a substrate,
an anode, and
a cathode, wherein the anode or the cathode is on the substrate, and
a light-emitting layer between the anode and the cathode and comprising the layer formed from the composition.
